(19) United States
(12) Patent Application Publication
(10) Pub. No.: US 2026/0132331 A1
(43) Pub. Date: May 14, 2026

(54) METHOD FOR PREPARING QUANTUM DOT, QUANTUM DOT, OPTICAL MEMBER INCLUDING THE QUANTUM DOT, AND ELECTRONIC APPARATUS INCLUDING THE QUANTUM DOT

(71) Applicant: Samsung Display Co., Ltd., Yongin-si (KR)

(72) Inventors: Junehyuk Jung, Yongin-si (KR); Sungjae Kim, Yongin-si (KR); Youngsik Kim, Yongin-si (KR); Hongrae Kim, Yongin-si (KR); Seungwon Park, Yongin-si (KR); Bitna Yoon, Yongin-si (KR); Taekjoon Lee, Yongin-si (KR)

(73) Assignee: Samsung Display Co., Ltd., Yongin-si (KR)

(21) Appl. No.: 19/382,449

(22) Filed: Nov. 7, 2025

(30) Foreign Application Priority Data
Nov. 12, 2024 (KR) 10-2024-0160489

(51) Int. Cl. C09K 11/58; H10H 20/01; H10H 20/851; H10K 59/38

(52) U.S. Cl. CPC C09K 11/584; H10H 20/0363; H10H 20/8512; H10K 59/38

(57) ABSTRACT

Embodiments provide a method of preparing a quantum dot, a quantum dot, an optical member including the quantum dot, and an electronic apparatus including the quantum dot. The method of preparing a quantum dot includes preparing a core including copper (Cu), a Group III element, and a Group VI element, and preparing a first shell covering the core and including a Group II element and a Group VI element, wherein the preparation of the first shell includes preparing a first composition for forming the first shell by mixing the core with a Group VI element-containing precursor, and preparing a second composition for preparing the first shell, by adding a Group II element-containing precursor to the first composition for forming the first shell.

### CROSS-REFERENCE TO RELATED APPLICATION(S)

This application claims priority to and benefits of Korean Patent Application No. 10-2024-0160489 under 35 U.S.C. § 119, filed on Nov. 12, 2024, in the Korean Intellectual Property Office, the entire contents of which are incorporated herein by reference.

### BACKGROUND

### 1. Technical Field

Embodiments relate to a method of preparing a quantum dot, a quantum dot, an optical member including the quantum dot, and an electronic apparatus including the quantum dot.

### 2. Description of the Related Art

Quantum dots may be used as a material that performs various optical functions (for example, light conversion function, light emission function, etc.) in optical members and various electronic apparatuses. A quantum dot is a nano-sized semiconductor nanocrystal that exhibits a quantum confinement effect, and by controlling the size, composition, etc. of the nanocrystal, the quantum dot may have different energy band gaps and, accordingly, may emit light with various emission wavelengths.

An optical member including such a quantum dot may take the form of a thin film, for example, a thin film patterned for each sub-pixel. Such an optical member may also be used as a color conversion member in an apparatus including various light sources.

The quantum dot may be used for various purposes in various electronic apparatuses. For example, the quantum dot may also be used as an emitter. As an example, the quantum dot may be included in an emission layer of a light-emitting element including a pair of electrodes and an emission layer and may serve as an emitter.

Currently, to realize high-quality optical members and electronic apparatuses, there is a demand for the development of a quantum dot that has excellent quantum yield (QY) and does not include cadmium, a toxic element.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a method of preparing a quantum dot, the quantum dot, an optical member including the quantum dot, and an electronic apparatus including the quantum dot.

Additional aspects will be set forth in part in the description which follows and, in part, will be apparent from the description, or may be learned by practice of the embodiments of the disclosure.

According to embodiments, a method of preparing a quantum dot may include:
preparing a core including copper (Cu), a Group III element, and a Group VI element; and
preparing a first shell covering the core and including a Group II element and a Group VI element, wherein
the preparation of the first shell may include:
preparing a first composition for forming the first shell by mixing the core with a Group VI element-containing precursor; and
preparing a second composition for forming the first shell by adding a Group II element-containing precursor into the first composition for forming the first shell.

In an embodiment, in the preparing of the first composition for forming the first shell by mixing the core and the Group VI element-containing precursor, the core and the Group VI element-containing precursor may each be mixed at a temperature less than or equal to about 100° C.

In an embodiment, the method may further include, after the preparing of the second composition for forming the first shell: heat-treating the second composition for forming the first shell.

In an embodiment, the Group VI element included in the core may include B¹, the Group VI element included in the first shell may include B², the Group VI element-containing precursor may be a B²-containing precursor, the B²-containing precursor may include B² and an amine-based compound, and B¹ and B² may each independently be a Group VI element.

In an embodiment, the Group III element may be aluminum (Al), gallium (Ga), indium (In), thallium (TI), nihonium (Nh), or any combination thereof.

In an embodiment, the Group VI element may be oxygen (O), sulfur (S), selenium (Se), tellurium (Te), or any combination thereof.

In an embodiment, the Group II element may be magnesium (Mg), calcium (Ca), zinc (Zn), cadmium (Cd), mercury (Hg), or any combination thereof.

In an embodiment, the core may include copper (Cu), indium (In), gallium (Ga), and sulfur (S).

In an embodiment, the first shell may include a Group II-VI semiconductor compound, a Group III-VI semiconductor compound, a Group III-V semiconductor compound, or any combination thereof.

In an embodiment, the Group II-VI semiconductor compound may be CdS, CdSe, CdTe, ZnS, ZnSe, ZnTe, ZnO, ZnMg, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or any combination thereof.

In an embodiment, the Group III-VI semiconductor compound may be GaS, GaSe, Ga₂Se₃, GaTe, InS, InSe, In₂S₃, In₂Se₃, InTe, InGaS₃, InGaSe₃, or any combination thereof.

In an embodiment, the Group III-V semiconductor compound may be GaN, GaP, GaAs, GaSb, AlN, AIP, AIAs, AISb, InN, InP, InAs, InSb, GaNP, GaNAs, GaNSb, GaPAs, GaPSb, AlNP, AlNAs, AlNSb, AIPAs, AIPSb, InGaP, InNP, InAIP, InNAs, InNSb, InPAs, InPSb, GaAINP, GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb, or any combination thereof.

In an embodiment, the first shell may include zinc (Zn) and sulfur (S).

In an embodiment, a quantum dot, prepared by the method, may include, based on a total of 100 weight percent (wt %) of the quantum dot: an amount of copper (Cu) in a range of about 5 wt % to about 15 wt %, an amount of a Group III element in a range of about 10 wt % to about 20 wt %, an amount of a Group VI element in a range of about 40 wt % to about 50 wt %, and an amount of a Group II element in a range of about 25 wt % to about 35 wt %.

In an embodiment, the quantum dot may emit light with a peak emission wavelength in a range of about 500 nm to about 650 nm.

In an embodiment, a quantum yield (QY) of the quantum dot may be in a range of about 70% to about 98%.

In an embodiment, a full width at half maximum (FWHM) of an emission wavelength spectrum of the quantum dot may be less than or equal to about 55 nm.

According to embodiments, an optical member may include the quantum dot.

According to embodiments, an electronic apparatus may include the quantum dot.

In an embodiment, the electronic apparatus may include a light source, and a color conversion member disposed in a path of light emitted from the light source, wherein the color conversion member may include the quantum dot.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic cross-sectional view of a quantum dot according to an embodiment;

FIG. 2 is a schematic cross-sectional view of an electronic apparatus according to an embodiment;

FIG. 3 is a schematic cross-sectional view of an electronic apparatus according to another embodiment;

FIG. 4 is a schematic perspective view of an electronic device according to an embodiment;

FIG. 5 is a schematic perspective view of an exterior of a vehicle as an electronic device according to an embodiment;

FIG. 6A to FIG. 6C are each a schematic diagram of an interior of a vehicle according to embodiments; and

FIG. 7 is a graph of photoluminescence (PL) spectra of quantum dots according to an Example and a Comparative Example; and

FIG. 8 is a graphs of light resistance characteristics of quantum dots according to an Example and a Comparative Example.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on”, “directly connected to”, or “directly coupled to” another element, there are no intervening elements present. For example, “directly on” may mean that two layers or two elements are disposed without an additional element such as an adhesion element therebetween.

In the specification, the expressions used in the singular such as “a”, “an”, and “the” are intended to include the plural forms as well, unless the context clearly indicates otherwise.

In the specification, the term “and/or” includes any and all combinations of one or more of the associated listed items. For example, “A and/or B” may be understood to mean “A, B, or A and B”. The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of”, modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises”, “comprising”, “includes”, “including”, “have”, “having”, “contains”, “containing”, and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

As used herein, the term “Group I” may encompass Group IA elements and Group IB elements on the IUPAC periodic table. Examples of Group I elements may include silver (Ag) and copper (Cu), etc.

As used herein, the term “Group II” may encompass Group IIA elements and Group IIB elements on the IUPAC periodic table, Examples of Group II elements may include magnesium (Mg), calcium (Ca), zinc (Zn), cadmium (Cd), and mercury (Hg), etc.

As used herein, the term “Group III” may encompass Group IIIA elements and Group IIIB elements on the IUPAC periodic table. Examples of Group III elements may include aluminum (Al), gallium (Ga), indium (In), thallium (TI), and nihonium (Nh), etc.

As used herein, the term “Group VI” may encompass Group VIA elements and Group VIB elements on the IUPAC periodic table. Examples of Group VI element may include oxygen (O), sulfur (S), selenium (Se), and tellurium (Te), etc.

As used herein, the terms “quantum yield” and “luminescence efficiency” may be used with substantially the same meaning.

Hereinafter, a method of preparing a quantum dot according to an embodiment will be described.

### [Method of Preparing Quantum Dot]

According to embodiments, a method of preparing a quantum dot may include: preparing a core including copper (Cu), a Group III element, and a Group VI element; and preparing a first shell covering the core and including a Group II element and a Group VI element. The preparation of the first shell may include: preparing a first shell by mixing the core with a Group VI element-containing precursor; and preparing a second composition for forming the first shell by adding a Group II element-containing precursor to the first composition for forming the first shell.

According to an embodiment, preparing the core may include preparing the core by using a composition for forming the core that includes a copper precursor, a Group III element-containing precursor, and the Group VI element-containing precursor.

According to an embodiment, preparing the core may include heat-treating the composition for forming the core.

According to an embodiment, in the preparing of the first composition for forming the first shell by mixing the core with the Group VI element-containing precursor, the core and the Group VI element-containing precursor may each be mixed at a temperature less than or equal to about 100° C.

For example, the core and the Group VI element-containing precursor may each be mixed at a temperature of about 30° C. to about 100° C. For example, the core and the Group VI element-containing precursor may each be mixed at a temperature of about 35° C. to about 100° C. For example, the core and the Group VI element-containing precursor may each be mixed at a temperature of about 40° C. to about 100° C. For example, the core and the Group VI element-containing precursor may each be mixed at a temperature of about 45° C. to about 100° C. For example, the core and the Group VI element-containing precursor may each be mixed at a temperature of about 50° C. to about 100° C. For example, the core and the Group VI element-containing precursor may each be mixed at a temperature of about 55° C. to about 100° C. For example, the core and the Group VI element-containing precursor may each be mixed at a temperature of about 60° C. to about 100° C. For example, the core and the Group VI element-containing precursor may each be mixed at a temperature of about 65° C. to about 100° C. For example, the core and the Group VI element-containing precursor may each be mixed at a temperature of about 70° C. to about 100° C. For example, the core and the Group VI element-containing precursor may each be mixed at a temperature of about 75° C. to about 100° C. For example, the core and the Group VI element-containing precursor may each be mixed at a temperature of about 80° C. to about 100° C. For example, the core and the Group VI element-containing precursor may each be mixed at a temperature of about 85° C. to about 100° C. For example, the core and the Group VI element-containing precursor may each be mixed at a temperature of about 90° C. to about 100° C. For example, the core and the Group VI element-containing precursor may each be mixed at a temperature of about 95° C. to about 100° C. For example, the core and the Group VI element-containing precursor may each be mixed at a temperature of about 30° C. to about 80° C. For example, the core and the Group VI element-containing precursor may each be mixed at a temperature of about 35° C. to about 80° C. For example, the core and the Group VI element-containing precursor may each be mixed at a temperature of about 40° C. to about 80° C. For example, the core and the Group VI element-containing precursor may each be mixed at a temperature of about 45° C. to about 80° C. For example, the core and the Group VI element-containing precursor may each be mixed at a temperature of about 50° C. to about 80° C. For example, the core and the Group VI element-containing precursor may each be mixed at a temperature of about 55° C. to about 80° C. For example, the core and the Group VI element-containing precursor may each be mixed at a temperature of about 60° C. to about 80° C. For example, the core and the Group VI element-containing precursor may each be mixed at a temperature of about 65° C. to about 80° C. For example, the core and the Group VI element-containing precursor may each be mixed at a temperature of about 70° C. to about 80° C. For example, the core and the Group VI element-containing precursor may each be mixed at a temperature of about 75° C. to about 80° C. For example, the core and the Group VI element-containing precursor may each be mixed at a temperature of about 30° C. to about 60° C. For example, the core and the Group VI element-containing precursor may each be mixed at a temperature of about 35° C. to about 60° C. For example, the core and the Group VI element-containing precursor may each be mixed at a temperature of about 40° C. to about 60° C. For example, the core and the Group VI element-containing precursor may each be mixed at a temperature of about 45° C. to about 60° C. For example, the core and the Group VI element-containing precursor may each be mixed at a temperature of about 50° C. to about 60° C. For example, the core and the Group VI element-containing precursor may each be mixed at a temperature of about 55° C. to about 60° C.

According to an embodiment, in the preparing of the first composition for forming the first shell by mixing the core with the Group VI element-containing precursor, the core may be mixed at a temperature in a range of about 70° C. to about 80° C., and the Group VI element-containing precursor may be mixed at a temperature in a range of about 50° C. to about 60° C.

Preparing the first shell may include preparing the first composition for forming the first shell by mixing the core and the group VI element-containing precursor, which may suppress and prevent an increase in full width at half maximum of an emission spectrum as the content of the Group VI element in the core decreases.

By mixing the core and the Group VI element-containing precursor at a low temperature, a decrease in full width at half maximum of an emission spectrum caused by heat treatment of the core at high temperature may be minimized.

According to an embodiment, the Group II element-containing precursor included in the second composition for forming the first shell may include the Group II element and an amine-based compound.

For example, the Group II element-containing precursor may be a Group II element-containing amine-based compound. For example, the Group II element-containing precursor may be Zn-oleylamine.

According to an embodiment, the method of preparing a quantum dot, after the preparing of the second composition for forming the first shell, may further include: heat-treating the second composition for forming the first shell.

For example, the heat treatment may be performed at a temperature greater than or equal to about 200° C.

According to an embodiment, the Group VI element included in the core may include B¹, the Group VI element included in the first shell may include B², and B¹ and B² may each independently be a Group VI element.

According to an embodiment, B¹ and B² may be the same as or different from each other.

According to an embodiment, the Group VI element-containing precursor included in the core may be a B¹-containing precursor.

According to an embodiment, the Group VI element-containing precursor included in the first composition for forming the first shell may be a B²-containing precursor.

In an embodiment, the B¹-containing precursor and the B²-containing precursor may be the same as or different from each other.

According to an embodiment, the B²-containing precursor may include B² and an amine-based compound.

In an embodiment, the B²-containing precursor may include S-oleylamine.

By including B² and an amine-based compound, the B²-containing precursor may enhance the synthetic reactivity as the products formed during the reaction of B² and the amine-based compound react with the metal and precursors of the core.

In an embodiment, preparing the first shell of the disclosure may include reacting the B²-containing precursor with the core, thereby minimizing an increase in full width at half maximum through stabilization of the core, thereby providing quantum dots with excellent quantum yield and enhanced light resistance.

According to an embodiment, after preparing the first shell, the method may further include forming a second shell using a composition for forming the second shell.

In an embodiment, the composition for forming the second shell may include a Group II element-containing precursor and a Group VI element-containing precursor.

According to an embodiment, the Group VI element-containing precursor in the composition for forming the core and the Group VI element-containing precursor in the composition for forming the first shell may be the same as or different from each other.

According to an embodiment, the Group II element-containing precursor in the composition for forming the first shell and the Group II element-containing precursor in the composition for forming the second shell may be the same as or different from each other.

According to an embodiment, the Group VI element-containing precursor in the composition for forming the first shell and the Group VI element-containing precursor in the composition for forming the second shell may be the same as or different from each other.

According to an embodiment, the copper precursor may be copper or a copper compound.

For example, the copper precursor may be copper iodide, copper bromide, copper chloride, copper acetylacetonate, or any combination thereof.

According to an embodiment, the Group II element-containing precursor may be, in addition to the aforementioned, zinc or a zinc compound, cadmium or a cadmium compound, or mercury or a mercury compound.

For example, the Group II element-containing precursor may be zinc acetate, dimethyl zinc, diethyl zinc, zinc carboxylate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, cadmium oxide, dimethyl cadmium, diethyl cadmium, cadmium carbonate, cadmium acetate dihydrate, cadmium acetylacetonate, cadmium fluoride, cadmium chloride, cadmium iodide, cadmium bromide, cadmium perchlorate, cadmium phosphide, cadmium nitrate, cadmium sulfate, cadmium carboxylate, mercury iodide, mercury bromide, mercury fluoride, mercury cyanide, mercury nitrate, mercury perchlorate, mercury sulfate, mercury oxide, mercury carbonate, mercury carboxylate, etc.

According to an embodiment, the Group III element-containing precursor may be aluminum or an aluminum compound, gallium or a gallium compound, indium or an indium compound, or thallium or a thallium compound.

For example, the Group III element-containing precursor may be aluminum phosphate, aluminum acetyl acetonate, aluminum chloride, aluminum fluoride, aluminum oxide, aluminum nitrate, aluminum sulfate, gallium acetylacetonate, gallium chloride, gallium fluoride, gallium oxide, gallium nitrate, gallium sulfate, indium acetate, indium chloride, indium oxide, indium nitrate, indium sulfate, indium carboxylate, thallium acetate, thallium chloride, thallium oxide, thallium nitrate, thallium sulfate, thallium carboxylate, etc.

According to an embodiment, the Group VI element-containing precursor may be, in addition to the above, sulfur or a sulfur compound, selenium or a selenium compound, or tellurium or a tellurium compound.

For example, the Group VI element-containing precursor may be sulfur, sulfur-containing oleylamine, phosphine sulfide, trioctylphosphine sulfide, trialkylphosphine sulfide, trialkenylphosphine sulfide, alkylamino sulfide, alkenylamino sulfide, alkylthiol, selenium, trialkylphosphine selenide, trialkenylphosphine selenide, alkylamino selenide, alkenylamino selenide, trialkylphosphine telluride, trialkenylphosphine telluride, alkylamino telluride, alkenylamino telluride, etc.

According to an embodiment, the Group III element-containing precursor during the formation of the core may be gallium chloride, indium chloride, and any combination thereof.

According to an embodiment, the Group VI element-containing precursor during the formation of the core may be S(sulfur)-oleylamine.

According to an embodiment, the Group II element-containing precursor during the formation of the first shell may be Zn (zinc)-oleylamine, and the Group VI element-containing precursor may be S (sulfur)-oleylamine.

According to an embodiment, the composition for forming the core and the composition for forming the first shell may each further include a solvent.

According to an embodiment, the solvent may be an organic solvent. For example, the solvent may include 1-octadecene (ODE), trioctylamine (TOA), trioctylphosphine (TOP), oleylamine, or any combination thereof.

According to an embodiment, the method of preparing the quantum dot may further include surface-treating the surface of the first shell or second shell with an organic ligand or a metal halide.

According to an embodiment, the organic ligand may include a C₄-C₃₀ fatty acid.

For example, the organic ligand may include palmitic acid, palmitoleic acid, stearic acid, oleic acid, trioctylphosphine, trioctylphosphine oxide, oleylamine, octylamine, trioctyl amine, hexadecylamine, octanethiol, dodecanethiol, hexylphosphonic acid, tetradecylphosphonic acid, octylphosphonic acid, etc.

The method of preparing the quantum dot according to an embodiment may include preparing the first shell including preparing the first composition for forming the first shell by mixing the core and a Group VI element-containing precursor, thereby suppressing and preventing an increase in the full width at half maximum as the content of the group VI element of the core decreases.

By mixing the core and the group VI element-containing precursor at a low temperature, a decrease in full width at half maximum of the emission spectrum caused by heat treatment of the core at high temperature may be minimized.

By including a Group VI element-containing precursor and an amine-based compound, the product generated during the reaction of the Group VI element and the amine-based compound may further enhance the synthetic reactivity by reacting with the metal of the core and the precursor.

In an embodiment, preparing the first shell may include reacting the Group VI element-containing precursor with the core, thereby minimizing an increase in full width at half maximum through stabilization of the core, thereby providing quantum dots with excellent quantum yield and enhanced light resistance.

Accordingly, the quantum dot according to an embodiment may provide a quantum dot with enhanced chemical stability and PL characteristics by achieving excellent quantum yield (QY) and high light resistance characteristics based on a full width at half maximum.

Therefore, a high-quality optical member and an electronic apparatus may be provided using the quantum dot.

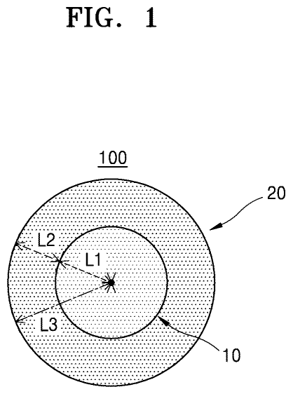

Hereinafter, with reference to FIG. 1, a quantum dot 100 according to an embodiment will be described. The description of the quantum dot 100 below may also apply to the method of preparing quantum dots.

### [Description of FIG. 1]

FIG. 1 is a schematic cross-sectional view of a quantum dot 100 according to an embodiment. The quantum dot 100 includes a core 10 and a first shell 20.

### [Quantum Dot 100]

The quantum dot 100 of FIG. 1 may include a core 10 including copper (Cu), the Group III element, and the Group VI element; and the first shell 20 covering the core.

According to an embodiment, the core 10 may include a Group I-III-VI semiconductor compound.

According to an embodiment, a full width at half maximum (FWHM) of the emission wavelength spectrum of the core 10 may be in a range of, for example, about 15 nm to about 50 nm. For example, the FWHM of the emission wavelength spectrum of the core 10 may be in a range of about 20 nm to about 50 nm. For example, the FWHM of the emission wavelength spectrum of the core 10 may be in a range of about 25 nm to about 50 nm. For example, the FWHM of the emission wavelength spectrum of the core 10 may be in a range of about 30 nm to about 50 nm. For example, the FWHM of the emission wavelength spectrum of the core 10 may be in a range of about 35 nm to about 50 nm. For example, the FWHM of the emission wavelength spectrum of the core 10 may be in a range of about 40 nm to about 50 nm. For example, the FWHM of the emission wavelength spectrum of the core 10 may be in a range of about 15 nm to about 45 nm. For example, the FWHM of the emission wavelength spectrum of the core 10 may be in a range of about 20 nm to about 45 nm. For example, the FWHM of the emission wavelength spectrum of the core 10 may be in a range of about 25 nm to about 45 nm. For example, the FWHM of the emission wavelength spectrum of the core 10 may be in a range of about 30 nm to about 45 nm. For example, the FWHM of the emission wavelength spectrum of the core 10 may be in a range of about 35 nm to about 45 nm. For example, the FWHM of the emission wavelength spectrum of the core 10 may be in a range of about 40 nm to about 45 nm. For example, the FWHM of the emission wavelength spectrum of the core 10 may be in a range of about 15 nm to about 35 nm. For example, the FWHM of the emission wavelength spectrum of the core 10 may be in a range of about 20 nm to about 35 nm. For example, the FWHM of the emission wavelength spectrum of the core 10 may be in a range of about 25 nm to about 35 nm. For example, the FWHM of the emission wavelength spectrum of the core 10 may be in a range of about 30 nm to about 35 nm. For example, the FWHM of the emission wavelength spectrum of the core 10 may be in a range of about 15 nm to about 30 nm. For example, the FWHM of the emission wavelength spectrum of the core 10 may be in a range of about 20 nm to about 30 nm. For example, the FWHM of the emission wavelength spectrum of the core 10 may be in a range of about 25 nm to about 30 nm. For example, the FWHM of the emission wavelength spectrum of the core 10 may be in a range of about 15 nm to about 25 nm. For example, the FWHM of the emission wavelength spectrum of the core 10 may be in a range of about 20 nm to about 25 nm. For example, the FWHM of the emission wavelength spectrum of the core 10 may be in a range of about 15 nm to about 20 nm. When the full width at half maximum of the core of the above quantum dot satisfies the above-mentioned range, the color purity and color reproducibility may be excellent, the optical viewing angle may be enhanced, and quantum yield (QY) may be enhanced.

According to an embodiment, an amount of copper (Cu) may be included at an atomic ratio in a range of about 10 wt % to about 25 wt %, based on a total of 100 wt % of the core 10.

For example, based on a total of 100 wt % of the core 10, an amount of copper (Cu) may be included in a range of about 10 wt % to about 25 wt %, about 11 wt % to about 25 wt %, about 12 wt % to about 25 wt %, about 13 wt % to about 25 wt %, about 14 wt % to about 25 wt %, about 15 wt % to about 25 wt %, about 16 wt % to about 25 wt %, about 17 wt % to about 25 wt %, about 18 wt % to about 25 wt %, about 19 wt % to about 25 wt %, about 20 wt % to about 25 wt %, about 21 wt % to about 25 wt %, about 22 wt % to about 25 wt %, about 23 wt % to about 25 wt %, about 24 wt % to about 25 wt %, about 10 wt % to about 24 wt %, about 11 wt % to about 24 wt %, about 12 wt % to about 24 wt %, about 13 wt % to about 24 wt %, about 14 wt % to about 24 wt %, about 15 wt % to about 24 wt %, about 16 wt % to about 24 wt %, about 17 wt % to about 24 wt %, about 18 wt % to about 24 wt %, about 19 wt % to about 24 wt %, about 20 wt % to about 24 wt %, about 21 wt % to about 24 wt %, about 22 wt % to about 24 wt %, about 23 wt % to about 24 wt %, about 10 wt % to about 23 wt %, about 11 wt % to about 23 wt %, about 12 wt % to about 23 wt %, about 13 wt % to about 23 wt %, about 14 wt % to about 23 wt %, about 15 wt % to about 23 wt %, about 16 wt % to about 23 wt %, about 17 wt % to about 23 wt %, about 18 wt % to about 23 wt %, about 19 wt % to about 23 wt %, about 20 wt % to about 23 wt %, about 21 wt % to about 23 wt %, about 22 wt % to about 23 wt %, about 11 wt % to about 22 wt %, about 13 wt % to about 22 wt %, about 15 wt % to about 22 wt %, about 17 wt % to about 22 wt %, about 19 wt % to about 22 wt %, about 21 wt % to about 22 wt %, about 10 wt % to about 21 wt %, about 12 wt % to about 21 wt %, about 14 wt % to about 21 wt %, about 16 wt % to about 21 wt %, about 18 wt % to about 21 wt %, about 20 wt % to about 21 wt %, about 11 wt % to about 20 wt %, about 13 wt % to about 20 wt %, about 15 wt % to about 20 wt %, about 17 wt % to about 20 wt %, or about 19 wt % to about 20 wt %.

According to an embodiment, an amount of a Group III element may be included in a range of about 10 wt % to about 30 wt %, based on a total of 100 wt % of the core 10.

For example, when at least two or more Group III elements are present, a combined amount of the two or more Group III elements may be included in a range of about 10 wt % to about 30 wt %, based on a total of 100 wt % of the core 10.

According to an embodiment, an amount of a Group VI element may be included in a range of about 40 wt % to about 60 wt %, based on a total of 100 wt % of the core 10.

For example, when at least two or more Group VI elements are present, a combined amount of the two or more Group VI elements may be included in a range of about 40 wt % to about 60 wt %, based on a total of 100 wt % of the core 10.

According to an embodiment, the Group III element may be aluminum (Al), gallium (Ga), indium (In), thallium (TI), nihonium (Nh), or any combination thereof.

For example, the Group III element included in the core 10 may be aluminum (Al), gallium (Ga), indium (In), or any combination thereof; may be gallium (Ga), indium (In), or any combination thereof; or may be gallium (Ga) and indium (In).

For example, when the Group III elements included in the core 10 are gallium (Ga) and indium (In), an amount of gallium may be included in in a range of about 5 wt % to about 20 wt %, based on a total of 100 wt % of the core 10, and an amount of indium may be included in a range of about 10 wt % to about 20 wt %, based on a total of 100 wt % of the core 10.

For example, when the Group III elements included in the core 10 are gallium (Ga) and indium (In), a weight ratio of gallium may be greater than a weight ratio of indium.

According to an embodiment, a Group VI element may be oxygen (O), sulfur (S), selenium (Se), tellurium (Te), or any combination thereof.

For example, the Group VI element included in the core 10 may be sulfur (S), selenium (Se), or any combination thereof.

According to an embodiment, the 10 core may include copper (Cu), indium (In), gallium (Ga), and sulfur (S).

For example, the core 10 may be a Cu—In—Ga—S(CIGS) quantum dot core consisting of copper (Cu), indium (In), gallium (Ga), and sulfur (S).

According to an embodiment, based on a total of 100 wt % of the core 10, the core 10 may include an amount of copper (Cu) in a range of about 10 wt % to about 25 wt %, an amount of indium (In) in a range of about 10 wt % to about 20 wt %, an amount of gallium (Ga) in a range of about 10 wt % to about 20 wt %, and an amount of sulfur (S) in a range of about 40 wt % to about 60 wt %.

According to an embodiment, the first shell 20 may include a Group II-VI semiconductor compound, a Group III-VI semiconductor compound, a Group III-V semiconductor compound, or any combination thereof.

According to an embodiment, the quantum dot 100 may further include a second shell (not shown) covering the first shell 20.

According to an embodiment, the second shell may include a Group II-VI semiconductor compound, a Group III-VI semiconductor compound, a Group III-V semiconductor compound, or any combination thereof.

According to an embodiment, the Group II element may be magnesium (Mg), calcium (Ca), zinc (Zn), cadmium (Cd), mercury (Hg), or any combination thereof. For example, the Group II element may be zinc (Zn) or magnesium (Mg).

According to an embodiment, the Group II-VI semiconductor compound may be CdS, CdSe, CdTe, ZnS, ZnSe, ZnTe, ZnO, ZnMg, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or any combination thereof.

According to an embodiment, the Group III-VI semiconductor compound may be GaS, GaSe, Ga₂Se₃, GaTe, InS, InSe, In₂S₃, In₂Se₃, InTe, InGaS₃, InGaSe₃ or any combination thereof.

According to an embodiment, the Group III-V semiconductor compound may be GaN, GaP, GaAs, GaSb, AlN, AIP, AIAs, AISb, InN, InP, InAs, InSb, GaNP, GaNAs, GaNSb, GaPAs, GaPSb, AlNP, AlNAs, AlNSb, AIPAs, AIPSb, InGaP, InNP, InAIP, InNAs, InNSb, InPAs, InPSb, GaAINP, GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb and any combination thereof.

According to an embodiment, the first shell may include zinc (Zn) and sulfur (S). For example, the first shell may include ZnS.

According to an embodiment, the quantum dot may further include an intermediate shell layer disposed between the first shell layer and the second shell layer, and the intermediate shell layer may include a material identical to a material of the first shell and a material identical to a material of the second shell.

According to an embodiment, Cu within the core 10 may be present at a uniform concentration or at a non-uniform concentration.

According to an embodiment, the Group III element within the core 10 may be present at a uniform concentration or at a non-uniform concentration.

According to an embodiment, the Group VI element within the core 10 may be present at a uniform concentration or at a non-uniform concentration.

According to an embodiment, the elements within the first shell 20 may be present at a uniform concentration or at a non-uniform concentration.

According to an embodiment, the elements within the second shell may be present at a uniform concentration or at a non-uniform concentration.

According to an embodiment, the concentration of elements included in the first shell and the second shell may form a concentration gradient that varies based on a distance from the core.

According to an embodiment, a radius L1 of the core 10 of the quantum dot 100 may be greater than or equal to about 4 nm. For example, the radius of the core 10 may be in a range of about 4 nm to about 8 nm. For example, the radius of the core 10 may be in a range of about 4 nm to about 7.5 nm. For example, the radius of the core 10 may be in a range of about 4 nm to about 7 nm. For example, the radius of the core 10 may be in a range of about 4 nm to 6 nm.

According to an embodiment, a thickness L2 of the first shell 20 of the quantum dot 100 may be in a range of about 0.5 nm to about 3 nm. For example, the thickness L2 of the first shell 20 may be in a range of about 0.5 nm to about 3 nm. For example, the thickness L2 of the first shell 20 may be in a range of about 0.5 nm to about 2 nm. For example, the thickness L2 of the first shell 20 may be in a range of about 0.5 nm to about 1 nm.

According to an embodiment, a thickness of the second shell of the quantum dot 100 may be in a range of about 0.5 nm to about 3 nm. For example, the thickness of the second shell may be in a range of about 0.5 nm to about 3 nm. For example, the thickness of the second shell may be in a range of about 1 nm to about 3 nm. For example, the thickness of the second shell may be in a range of about 2 nm to about 3 nm.

According to an embodiment, a sum of the thickness L2 of the first shell and the thickness of the second shell may be in a range of about 1 nm to about 4 nm.

For example, a sum of the thicknesses may be in a range of about 1 nm to about 4 nm. For example, the sum of the thicknesses may be in a range of about 1 nm to about 3 nm.

In the specification the “radius L1 of the core” may be a distance from the center of the quantum dot to the interface between the core and the first shell.

In the specification, a “thickness L2 of the first shell” may be a distance from the interface between the core 10 and the first shell 20 to the outer surface of the first shell 20, which corresponds to a value obtained by subtracting the radius L1 of the core from the distance L3 from the center of the quantum dot to the outer surface of the first shell.

According to an embodiment, a cation amount of the first shell may be about 10 parts by weight to about 50 parts by weight, based on a total weight of the first shell 20.

According to an embodiment, a shape of the quantum dot 100 may be spherical, pyramidal, multi-arm, or cubic nanoparticles, nano-tubes, nano-wires, nano-fibers, nano-platelets, etc.

According to an embodiment, the quantum dot 100 may be spherical.

According to an embodiment, the quantum dot 100 may emit blue light, green light, or red light. For example, the quantum dot 100 may emit red light.

According to an embodiment, the quantum dot 100 may emit light with a maximum emission wavelength in a range of about 500 nm to about 650 nm.

According to an embodiment, a quantum yield (QY) of the quantum dot 100 may be in a range of about 70% to about 98%. For example, a QY of the quantum dot 100 may be in a range of about 75% to about 97%. For example, a QY of the quantum dot 100 may be in a range of about 85% to about 95%.

According to an embodiment, the quantum dot 100 may have a full width at half maximum (FWHM) of an emission wavelength spectrum less than or equal to about 60 nm. For example, the quantum dot 100 may have a FWHM of an emission wavelength spectrum less than or equal to about 58 nm. the quantum dot 100 may have a full width at half maximum (FWHM) of an emission wavelength spectrum less than or equal to about 55 nm. When the FWHM is within any of these ranges, color purity or color reproducibility may be enhanced. Light emitted through these quantum dots may be emitted in all directions, which may enhance a viewing angle.

According to an embodiment, based on a total of 100 wt % of the quantum dot 100, the quantum dot 100 may include: an amount of copper (Cu) in a or of about 5 wt % to about 15 wt %; an amount of the Group III element in a range of about 10 wt % to about 20 wt %; an amount of the Group IV element in a range of about 40 wt % to about 50 wt %; and an amount of the Group II element in a range of about 25 wt % to about 35 wt %.

According to an embodiment, based on a total of 100 wt % of the quantum dot 100, the quantum dot 100 may include: an amount of copper (Cu) in a range of about 5 wt % to about 15 wt %; an amount of indium (In) in a range of about 5 wt % to about 10 wt %; an amount of gallium (Ga) in a range of about 5 wt % to about 10 wt %; an amount of sulfur (S) in a range of about 40 wt % to about 50 wt %; and an amount of zinc (Zn) in a range of about 25 wt % to about 35 wt %.

According to an embodiment, the amount of gallium (Ga) included in the quantum dot 100 may be greater than the amount of indium (In), on the basis of weight.

As used herein, the quantum dot 100 may be a crystal of a semiconductor compound and may include any material that may emit light of various emission wavelengths depending on the size of the crystal. The quantum dot 100 may emit light of various emission wavelengths by controlling an elemental ratio in the quantum dot 100 compound.

A diameter of the quantum dot 100 may be, for example, in a range of about 1 nm to about 10 nm.

According to an embodiment, the quantum dot 100 may be prepared by a method of preparing a quantum dot described herein.

The quantum dot 100 may be synthesized by a wet chemical process, metal organic chemical vapor deposition process, molecular beam epitaxy process, or similar processes.

The wet chemical process is a method of growing a quantum dot particle crystal by mixing an organic solvent and a precursor material. During crystal growth, the organic solvent naturally serves as a dispersing agent that is coordinated to the surface of the quantum dot crystal and controls the growth of the crystal, so the growth of the quantum dot particle may be controlled through a process that costs less than and may be more readily performed than vapor deposition methods such as metal organic chemical vapor deposition (MOCVD) or molecular beam epitaxy (MBE), etc.

The quantum dot 100 may further include, in addition to the above-described Group II-VI semiconductor compound, a separate Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of a Group II-VI semiconductor compound may include: a binary compound such as CdS, CdSe, CdTe, ZnS, ZnSe, ZnTe, ZnO, HgS, HgSe, HgTe, MgSe, MgS, etc.; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, etc.; a quaternary compound such as CdZnSeS, CdZnSeTe, CdZnSTe, CdHgSeS, CdHgSeTe, CdHgSTe, HgZnSeS, HgZnSeTe, HgZnSTe, etc.; and any combination thereof.

Examples of a Group III-V semiconductor compound may include: a binary compound such as GaN, GaP, GaAs, GaSb, AlN, AIP, AIAs, AISb, InN, InP, InAs, InSb, etc.; a ternary compound such as GaNP, GaNAs, GaNSb, GaPAs, GaPSb, AlNP, AlNAs, AlNSb, AIPAs, AIPSb, InGaP, InNP, InAIP, InNAs, InNSb, InPAs, InPSb, GaAINP, etc.; or a quaternary compound such as GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb, etc.; and any combination thereof. In an embodiment, the Group III-V semiconductor compound may further include a Group II element. Examples of a Group III-V semiconductor compound further including the Group II element may include InZnP, InGaZnP, InAIZnP, etc.

Examples of a Group III-VI semiconductor compound may include: a binary compound such as GaS, GaSe, Ga₂Se₃, GaTe, InS, InSe, In₂S₃, In₂Se₃, InTe, etc.; a ternary compound such as InGaS₃, InGaSe₃, etc.; and any combination thereof.

Examples of a Group I-III-VI semiconductor compound may include: a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAIO₂, etc.; a quaternary compound such as AgInGaS₂, AgInGaSe₂, etc.; and any combination thereof.

Examples of a Group IV-VI semiconductor compound may include: a binary compound such as SnS, SnSe, SnTe, PbS, PbSe, PbTe, etc.; a ternary compound such as SnSeS, SnSeTe, SnSTe, PbSeS, PbSeTe, PbSTe, SnPbS, SnPbSe, SnPbTe, etc.; a quaternary compound such as SnPbSSe, SnPbSeTe, SnPbSTe, etc.; and any combination thereof.

Examples of a Group IV element or compound may include a single-element material such as Si, Ge, etc.; a binary compound such as SiC, SiGe, etc.; and any combination thereof.

Each element included in a compound, such as a binary compound, a ternary compound, or a quaternary compound, may be present within the particle at a uniform concentration or at a non-uniform concentration. For example, a formula may indicate the elements that are included in a compound, but an elemental ratio of the compound may vary. For example, AgInGaS₂ may refer to AgInₓGa₁₋ₓS₂ (where x is a real number between 0 and 1).

The shell 20 of the quantum dot may serve as a protective layer to maintain semiconductor properties by preventing chemical modification of the core and/or may serve as a charging layer to impart electrophoretic properties to the quantum dot. The shell 20 may be single-layered or multi-layered. An interface between the core and the shell may have a concentration gradient in which the concentration of a material that is present in the shell decreases toward the core.

The shell 20 of the quantum dot may further include a metal oxide, a metalloid oxide, a non-metal oxide, a semiconductor compound, and any combinations thereof, etc. Examples of a metal oxide, a metalloid oxide, or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, etc.; a ternary compound such as MgAl₂O₄, CoFe₂O₄, NiFe₂O₄, CoMn₂O₄, etc.; and any combination thereof.

Examples of a semiconductor compound may include a Group II-VI semiconductor compound, a Group III-V semiconductor compound, a Group III-VI semiconductor compound, a Group I-III-VI semiconductor compound, a Group IV-VI semiconductor compound, and any combination thereof, as disclosed herein. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AIAs, AIP, AISb, and any combination thereof.

By adjusting the size of the quantum dot, the energy band gap may be controlled, so that light of various wavelengths may be obtained from the quantum dot emission layer. Therefore, by using the quantum dot of different sizes, light-emitting element that emit light of different wavelengths may be implemented. In an embodiment, the size of the quantum dot or the elemental ratio within the quantum dot compound may be selected to emit red light, green light, and/or blue light. In an embodiment, the quantum dot may be configured such that light of various colors is combined to emit white light.

### [Apparatus]

The quantum dot may be used in various electronic apparatuses. Therefore, according to another embodiment, an electronic apparatus may include the quantum dot.

According to an embodiment, the electronic apparatus may include a light source, and a color conversion member disposed in the path of light emitted from the light source, wherein the color conversion member may include the quantum dot.

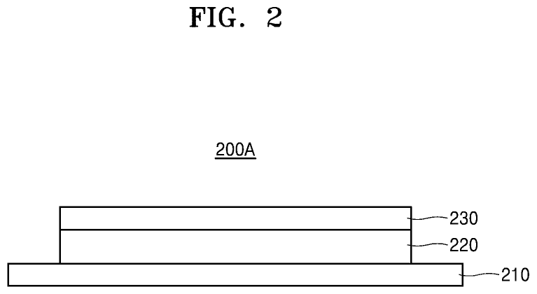

### [Description of FIG. 2]

FIG. 2 is a schematic cross-sectional view of an electronic apparatus 200A according to an embodiment. The electronic apparatus 200A of FIG. 2 includes a substrate 210, a light source 220 disposed on the substrate, and a color conversion member 230 disposed on the light source 220.

For example, the light source 220 may be a back light unit (BLU) used in a liquid crystal display (LCD), a fluorescent lamp, a light-emitting element, an organic light-emitting element, or a quantum dot light-emitting element (QLED), or any combination thereof. The color conversion member 230 may be disposed in at least one propagation direction of the light emitted from the light source 220.

At least one region of the color conversion member 230 of the electronic apparatus 200A may include a quantum dot, and the region may absorb light emitted from the light source and may emit red light with a maximum emission wavelength in a range of about 600 nm to about 700 nm, or may emit blue light with a maximum emission wavelength in a range of about 430 nm to about 480 nm.

While the color conversion member 230 may be disposed on at least one propagation direction of light emitted from the light source 220, embodiments do not exclude cases where other elements may be further included between the color conversion member 230 and the light source 220.

For example, a polarizer, a liquid crystal layer, a light guide plate, a diffusion plate, a prism sheet, a microlens sheet, a brightness enhancement sheet, a reflective film, a color filter, or any combination thereof may be further included between the light source 220 and the color conversion member 230.

In another example, a polarizer, a liquid crystal layer, a light guide plate, a diffusion plate, a prism sheet, a microlens sheet, a brightness enhancement sheet, a reflective film, a color filter, or any combination thereof may be further included on the color conversion member 230.

The electronic apparatus 200A shown in FIG. 2 may be an example of an apparatus according to an embodiment and may take various forms according to the related art, and may further include various configurations according to the related art.

In another embodiment, the electronic apparatus may include a structure in which a light source, a light guide plate, a color conversion member, a first polarizer, a liquid crystal layer, a color filter, and a second polarizer are disposed in this stated order, but embodiments are not limited thereto.

In another embodiment, the electronic apparatus may include a structure in which a light source, a light guide plate, a first polarizer, a liquid crystal layer, a second polarizer, and a color conversion member are disposed in this stated order, but embodiments are not limited thereto.

In the above described embodiments, the color filter may include a pigment or a dye. In the above described embodiments, one of the first polarizer and the second polarizer may be a vertical polarizer, and the other may be a horizontal polarizer.

### [Light-Emitting Element]

The quantum dot as disclosed herein may be used as an emitter. According to another embodiment, an electronic apparatus may include a light-emitting element including a first electrode; a second electrode facing the first electrode; and an intermediate layer disposed between the first electrode and the second electrode; wherein the quantum dot is included in the light-emitting element (for example, the emission layer of the light-emitting element). The light-emitting element may further include a hole transport region disposed between the first electrode and the emission layer, an electron transport region disposed between the emission layer and the second electrode, or any combination thereof.

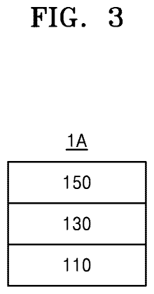

### [Description of FIG. 3]

FIG. 3 is a schematic cross-sectional view of a light-emitting element 1A according to an embodiment.

The light-emitting element 1A may include a first electrode 110, a second electrode 150 facing the first electrode 110, and an emission layer 130 disposed between the first electrode 110 and the second electrode 150, wherein the emission layer includes a quantum dot. The layers of the light-emitting element 1A will now be described.

In an embodiment, at least one of the quantum dots may be used in a light-emitting element (for example, an organic light-emitting element). Accordingly, embodiments provide a light-emitting element, which may include a first electrode, a second electrode facing the first electrode, an intermediate layer disposed between the first electrode and the second electrode and including an emission layer, and the quantum dot as disclosed herein.

According to an embodiment,
the first electrode of the light-emitting element may be an anode,
the second electrode of the light-emitting element may be a cathode,
the intermediate layer may further include a hole transport region disposed between the first electrode and the emission layer, and an electron transport region disposed between the emission layer and the second electrode,
the hole transport region may include a hole injection layer, a hole transport layer, an emission auxiliary layer, an electron blocking layer, or any combination thereof, and
the electron transport region may include a buffer layer, a hole blocking layer, an electron control layer, an electron transport layer, an electron injection layer, or any combination thereof.

According to another embodiment, the quantum dot may be disposed between the first electrode and the second electrode of the light-emitting element. Accordingly, the quantum dot may be included in an intermediate layer of the light-emitting element, for example, in the emission layer of the intermediate layer.

According to another embodiment, the emission layer in the intermediate layer of the light-emitting element may include a dopant and a host, and the host may include the quantum dot. For example, the quantum dot may serve as the host. The emission layer may emit red light, green light, blue light, and/or white light. For example, the emission layer may emit red light. The red light may have a maximum emission wavelength in a range of, for example, about 600 nm to about 700 nm.

According to another embodiment, the emission layer in the intermediate layer of the light-emitting element may include a dopant and a host, the host may include the quantum dot, and the dopant may emit blue light or red light. In an embodiment, the dopant may include a transition metal and m ligands, wherein m is an integer from 1 to 6. In an embodiment, the m ligands may be the same as or different from each other, at least one ligand among the m ligands and the transition metal may be connected to each other through a carbon-transition metal bond, and the carbon-transition metal bond may be a coordinate bond. For example, at least one ligand of the m ligands may be a carbene ligand (for example, Ir(pmp)₃, etc.). The transition metal may be, for example, iridium, platinum, osmium, palladium, rhodium, gold, etc. The emission layer and dopant may be the same as described herein.

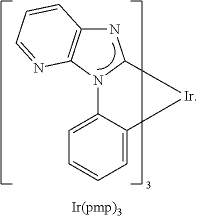

According to another embodiment, the light-emitting element may include a capping layer disposed on the outside of the first electrode or on the outside of the second electrode.

For example, the light-emitting element may further include at least one of a first capping layer disposed outside of the first electrode and a second capping layer disposed outside of the second electrode, wherein at least one of the first capping layer and the second capping layer may include the quantum dot. The first capping layer and/or the second capping layer may be the same as herein.

In an embodiment, the light-emitting element may include a first capping layer disposed outside of the first electrode and including the quantum dot.

In an embodiment, the light-emitting element may include a second capping layer disposed outside of the second electrode and including the quantum dot.

In an embodiment, the light-emitting element may further include both the first capping layer outside the first electrode and the second capping layer outside the second electrode.

In the specification, the expression, “(intermediate layer and/or capping layer) includes the quantum dot” may be interpreted such that the (intermediate layer and/or capping layer) may include the quantum dot or may include two or more different types of quantum dots.

In the specification, the expression, “intermediate layer” may refer to a single layer and/or multiple layers disposed between the first electrode and the second electrode in the light-emitting element.

According to embodiments, an electronic apparatus may include the quantum dot and/or light-emitting element as described above. The electronic apparatus may further include a thin-film transistor. For example, the electronic apparatus may further include a thin-film transistor including a source electrode and a drain electrode, wherein the first electrode of the light-emitting element may be electrically connected to the source electrode or the drain electrode. In an embodiment, the electronic apparatus may further include a color filter, a color conversion layer, a touch screen layer, a polarizing layer, or any combination thereof. The electronic apparatus may be the same as herein.

Hereinafter, with reference to FIG. 3, a structure and a preparation method of the light-emitting element 1A according to an embodiment will be described.

### [First Electrode 110]

In FIG. 1, a substrate may be further included below the first electrode 110 or on top the second electrode 150. In an embodiment, the substrate may be a glass substrate or a plastic substrate. In an embodiment, the substrate may be a flexible substrate, which may include a plastic with excellent heat resistance and durability, such as, for example, polyimide, polyethylene terephthalate (PET), polycarbonate, polyethylene naphthalate, polyarylate (PAR), polyetherimide, or any combination thereof.

The first electrode 110 may be formed, for example, by providing a first electrode material on an upper portion of the substrate using a deposition method or a sputtering method, etc. When the first electrode 110 is an anode, a high work function material facilitating hole injection may be used as the first electrode material.

The first electrode 110 may be a reflective electrode, a semi-transflective electrode, or a transflective electrode. In order to form the first electrode 110, which is a transflective electrode, indium tin oxide (ITO), indium zinc oxide (IZO), tin oxide Sn(O₂) zinc oxide (ZnO), or any combination thereof may be used as a material for the first electrode. In an embodiment, when the first electrode 110 is a semi-transflective electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be used as the material for the first electrode.

The first electrode 110 may have a structure consisting of a single layer or a structure including multiple layers. In an embodiment, the first electrode 110 may have a three-layer structure of ITO/Ag/ITO.

### [Intermediate Layer 130]

An intermediate layer 130 may be disposed on the first electrode 110. The intermediate layer 130 may include an emission layer.

The intermediate layer 130 may further include a hole transport region between the first electrode 110 and the emission layer, and an electron transport region between the emission layer and the second electrode 150.

The intermediate layer 130 may further include, in addition to various organic materials, metal-containing compounds such as organometallic compounds, and inorganic materials such as a quantum dot, etc.

The intermediate layer 130 may include two or more emitting units stacked between the first electrode 110 and the second electrode 150, and at least one charge generation layer, each disposed between adjacent emitting units among the two or more emitting units. When the intermediate layer 130 includes the two or more emitting units and the at least one charge generation layer as described above, the light-emitting element 1A may be a tandem light-emitting element.

[Hole Transport Region within Intermediate Layer 130]

The hole transport region may have a structure consisting of a layer consisting of a single material, a structure consisting of a layer including different materials, or a structure including multiple layers including different materials.

The hole transport region may include a hole injection layer, a hole transport layer, an emission auxiliary layer, an electron blocking layer, or any combination thereof.

In an embodiment, the hole transport region may have a multi-layered structure such as a hole injection layer/hole transport layer, a hole injection layer/hole transport layer/emission auxiliary layer, a hole injection layer/emission auxiliary layer, a hole transport layer/emission auxiliary layer, or a hole injection layer/hole transport layer/electron blocking layer, in which the layers of each structure may be stacked from the first electrode 110 in its respective stated order, but the structure of the hole transport region is not limited thereto.

In an embodiment, the hole transport region may include a compound represented by the Formula 201, a compound represented by the Formula 202, or any combination thereof:

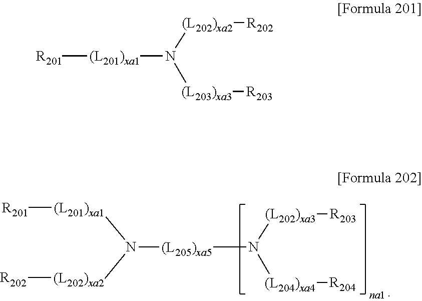

In Formulae 201 and 202,
L₂₀₁ to L₂₀₄ may each independently be, a C₃-C₆₀ carbocyclic group substituted or unsubstituted with at least one R₁₀ₐ, or a C₁-C₆₀ heterocyclic group substituted or unsubstituted with at least one R₁₀ₐ,
L₂₀₅ may be *—O—*′, *—S—*′, *—N(Q₂₀₁)-*′, a C₁-C₂₀ alkylene group substituted or unsubstituted with at least one R₁₀ₐ, a C₂-C₂₀ alkenylene group substituted or unsubstituted with at least one R₁₀ₐ, a C₃-C₆₀ carbocyclic group substituted or unsubstituted with at least one R₁₀ₐ, or a C₁-C₆₀ heterocyclic group substituted or unsubstituted with at least one R₁₀ₐ,
xa1 to xa4 may each independently be, an integer from 0 to 5,
xa5 may be an integer from 1 to 10,
R₂₀₁ to R₂₀₄ and Q₂₀₁ may each independently be a C₃-C₆₀ carbocyclic group substituted or unsubstituted with at least one R₁₀ₐ, or a C₁-C₆₀ heterocyclic group substituted or unsubstituted with at least one R₁₀ₐ,
R₂₀₁ and R₂₀₂ may optionally be linked to each other via a single bond, a C₁-C₅ alkylene group substituted or unsubstituted with at least one R₁₀ₐ, or a C₂-C₅ alkenylene group substituted or unsubstituted with at least one R₁₀ₐ, to form a C₈-C₆₀ polycyclic group (for example, a carbazole group, etc.) substituted or unsubstituted with at least one R₁₀ₐ (see, for example, Compound HT16, etc.).
R₂₀₃ and R₂₀₄ may optionally be linked to each other via a single bond, a C₁-C₅ alkylene group substituted or unsubstituted with at least one R₁₀ₐ, or a C₂-C₅ alkenylene group substituted or unsubstituted with at least one R₁₀ₐ, to form a C₈-C₆₀ polycyclic group substituted or unsubstituted with at least one R₁₀ₐ,
na1 may be an integer from 1 to 4.

In an embodiment, the compound represented by Formula 201 and the compound represented by Formula 202 may include at least one of groups represented by Formulae CY201 to CY217:

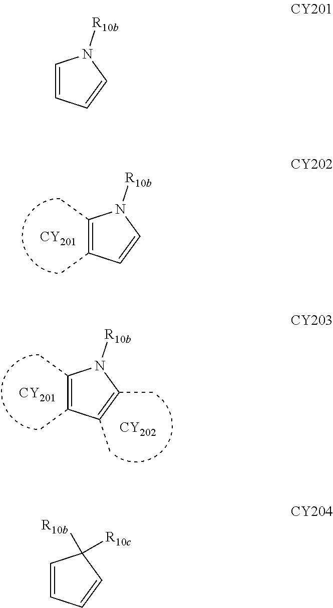

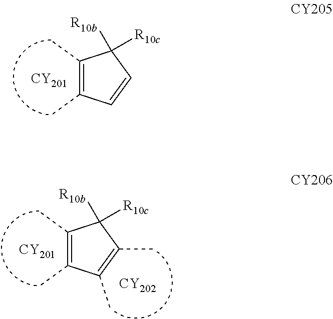

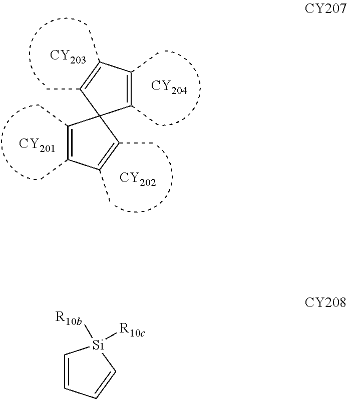

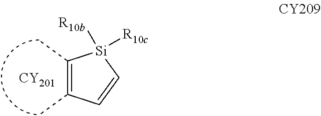

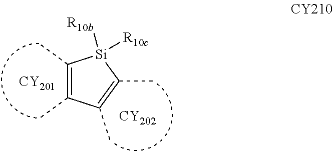

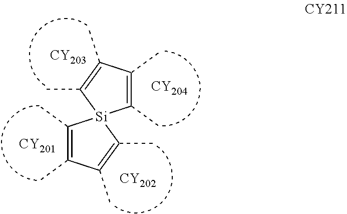

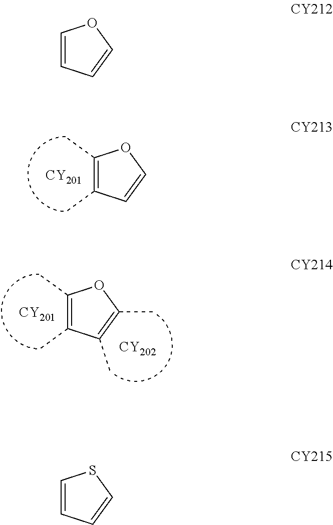

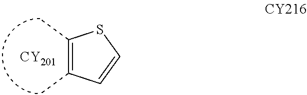

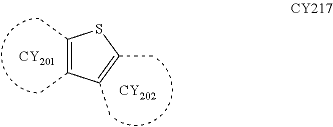

In Formulae CY201 to CY217, R_{10b} and R_{10c} may each independently be the same as described in connection with R₁₀ₐ, rings CY201 to CY204 may each independently be a C₃-C₂₀ carbocyclic group or a C₁-C₂₀ heterocyclic group, and at least one hydrogen in Formulae CY201 to CY217 may be or substituted or unsubstituted with R₁₀ₐ as disclosed herein.

According to an embodiment, in Formulae CY201 to CY217, rings CY201 to CY204 may each independently be a benzene group, a naphthalene group, a phenanthrene group, or an anthracene group.

According to another embodiment, the compound represented by Formula 201 and the compound represented by Formula 202 may each independently include at least one of groups represented by Formulae CY201 to CY203.

According to another embodiment, the compound represented by Formula 201 may include at least one of groups represented by Formulae CY201 to CY203 and at least one of groups represented by the Formulae CY204 to CY217, respectively.

According to another embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

According to another embodiment, the compound represented by Formula 201 and the compound represented by Formula 202 may each not include a group represented by Formulae CY201 to CY203.

According to another embodiment, the compound represented by Formula 201 and the compound represented by Formula 202 may each not include a group represented by Formulae CY201 to CY203 and may each independently include at least one of groups represented by Formulae CY204 to CY217.

In an embodiment, the compound represented by Formula 201 and the compound represented by Formula 202 may each not include a group represented by Formulae CY201 to CY217.

In an embodiment, the hole transport region may include one of Compounds HT1 to HT46, m-MTDATA, TDATA, 2-TNATA, NPB (NPD), β-NPB, TPD, Spiro-TPD, Spiro-NPB, methylated-NPB, TAPC, HMTPD, TCTA (4,4′,4″-tris(N-carbazolyl)triphenylamine), Pani/DBSA (Polyaniline/Dodecylbenzenesulfonic acid), PEDOT/PSS (Poly(3,4-ethylenedioxythiophene)/Poly(4-styrenesulfonate)), Pani/CSA (Polyaniline/Camphor sulfonic acid), PANI/PSS (Polyaniline/Poly(4-styrenesulfonate)), or any combination thereof:

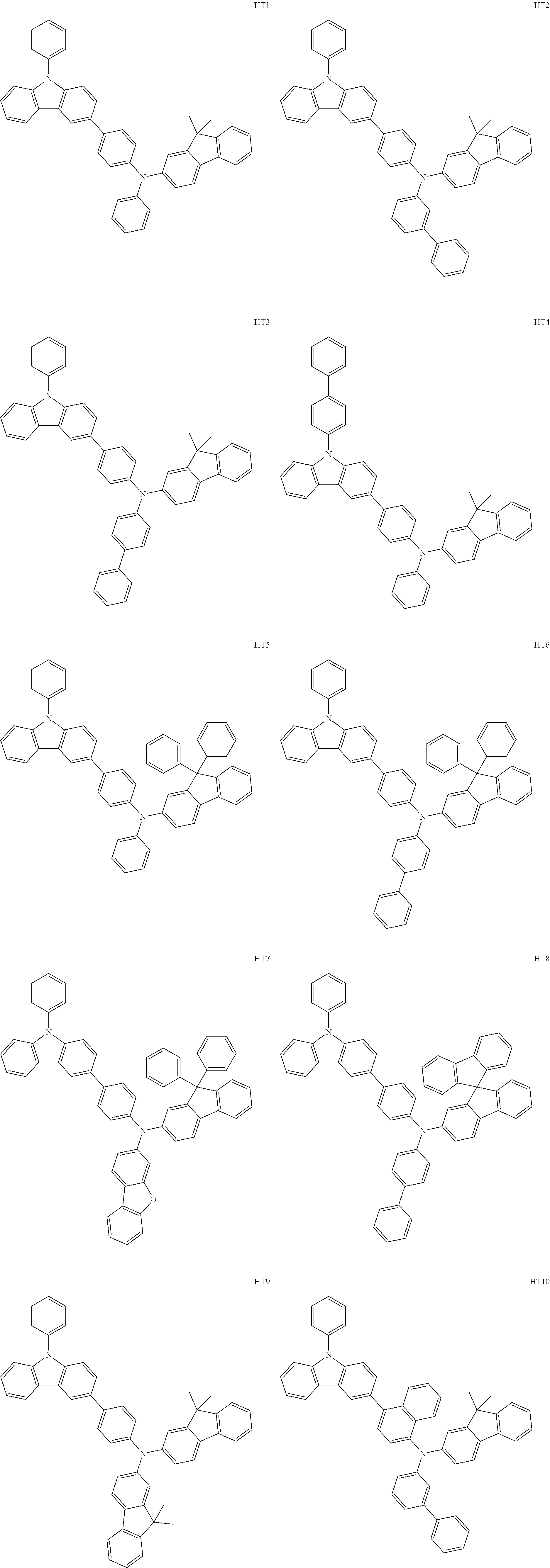

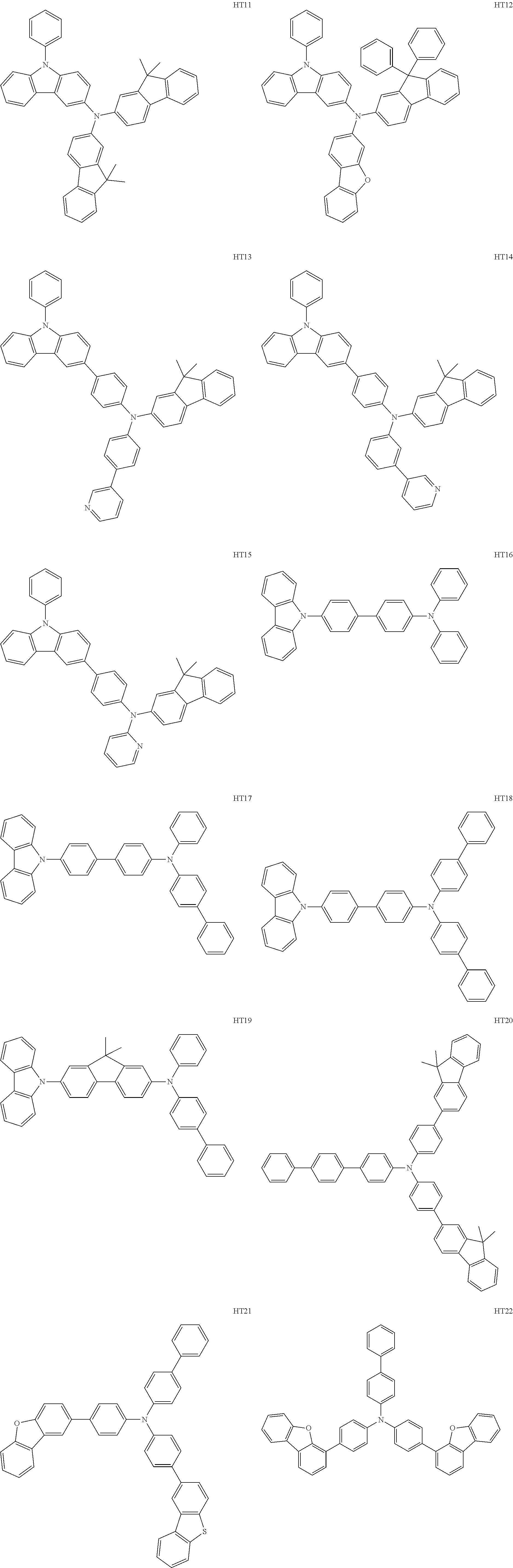

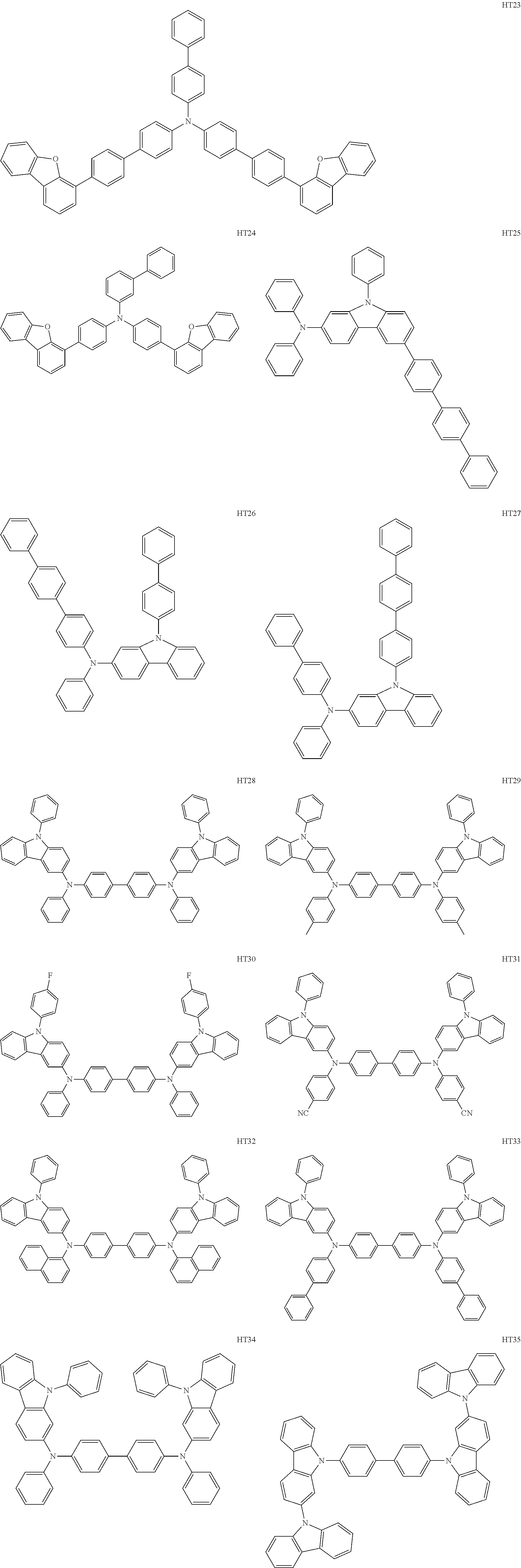

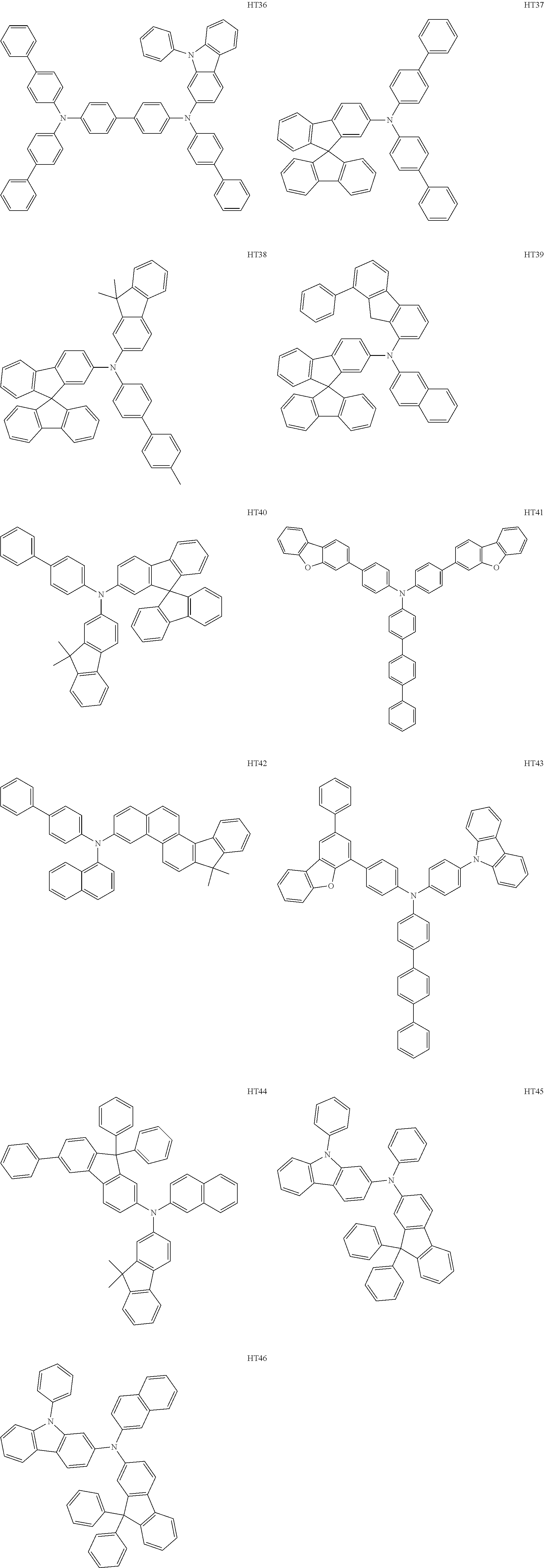

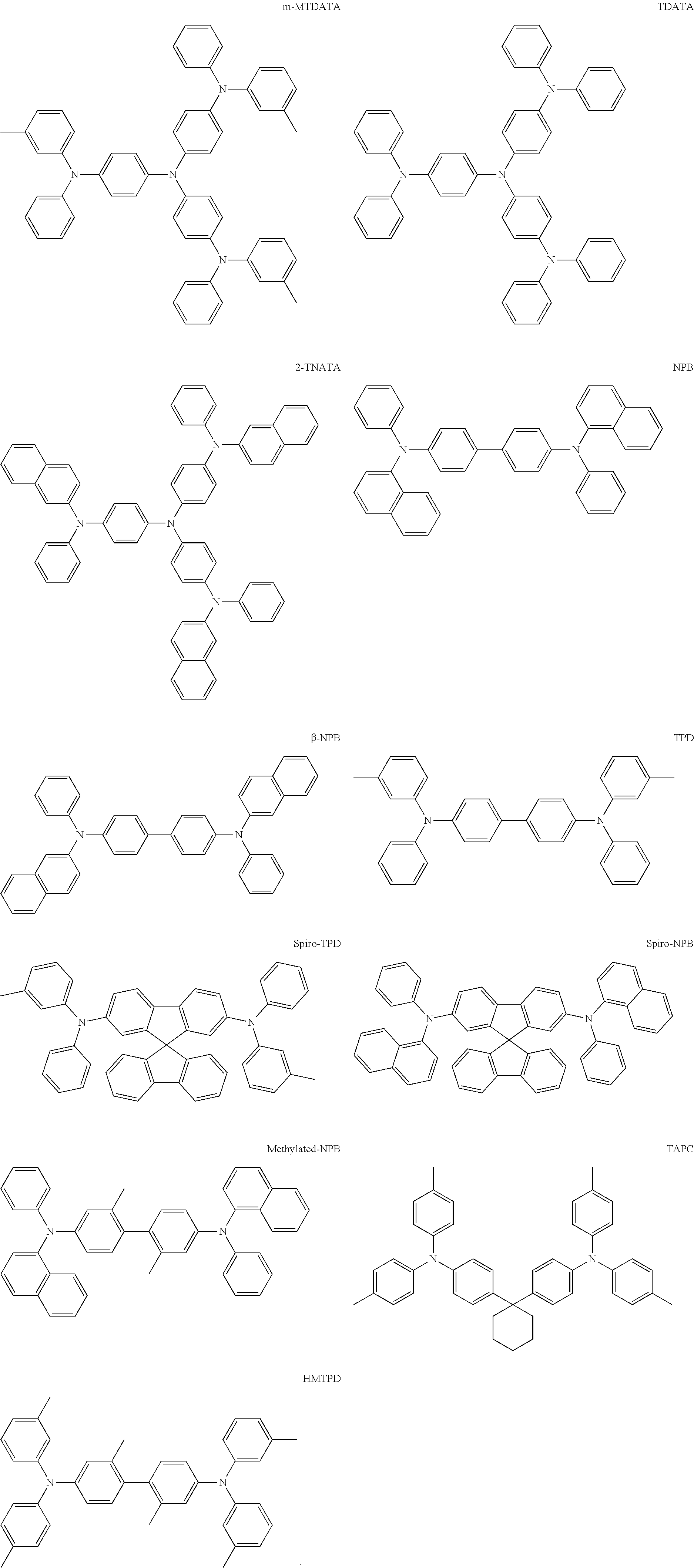

A thickness of the hole transport region may be in a range of about 50 Å to about 10,000 Å. For example, the thickness of the hole transport region may be in a range of about 100 Å to about 4,000 Å. When the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer satisfy the aforementioned ranges, satisfactory hole transport characteristics may be obtained without a substantial increase in driving voltage.

The emission auxiliary layer may increase light emission efficiency by compensating for an optical resonance distance according to a wavelength of light emitted from the emission layer, and the electron blocking layer may prevent electron leakage from the emission layer to the hole transport region. A material that may be included in the hole transport region described above may be included in the emission auxiliary layer and the electron blocking layer.

[p-Dopant]

The hole transport region may include a charge-generating material in addition to the materials described above to enhance conductivity. The charge-generating material may be uniformly or non-uniformly dispersed (for example, in a form of a single-layer consisting of the charge-generating material) within the hole transport region.

The charge-generating material may be, for example, a p-dopant.

In an embodiment, the lowest unoccupied molecular orbital (LUMO) energy level of the p-dopant may be less than or equal to about −3.5 eV.

According to an embodiment, the p-dopant may include a quinone derivative, a cyano group-containing compound, element EL1 and element EL2-containing compound, or any combination thereof.

Examples of a quinone derivative may include TCNQ, F4-TCNQ, etc.

Examples of a cyano group-containing compound may include HAT-CN, a compound represented by Formula 221, etc.

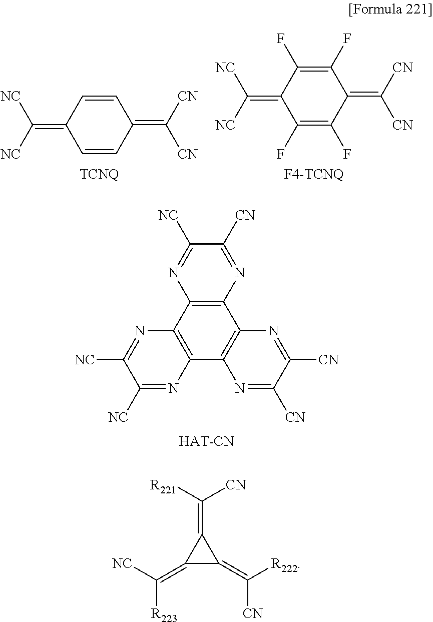

In Formula 221,
R₂₂₁ to R₂₂₃ may each independently be, a C₃-C₆₀ carbocyclic group substituted or unsubstituted with at least one R₁₀ₐ, or a C₁-C₆₀ heterocyclic group substituted or unsubstituted with at least one R₁₀ₐ,
and at least one of R₂₂₁ to R₂₂₃ may each independently be a C₃-C₆₀ carbocyclic group or a C₁-C₆₀ heterocyclic group substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); etc.

Examples of a metalloid may include silicon (Si), antimony (Sb), tellurium (Te), etc.

Examples of a non-metal may include oxygen (O), a halogen (for example, F, Cl, Br, I, etc.), etc.

Examples of a compound including element EL1 and element EL2 may include a metal oxide, a metal halide (for example, a metal fluoride, a metal chloride, a metal bromide, a metal iodide, etc.), a metalloid halide (for example, a metalloid fluoride, a metalloid chloride, a metalloid bromide, a metalloid iodide, etc.), a metal telluride, or any combination thereof.

Examples of a metal oxide may include a tungsten oxide (for example, WO, W₂O₃, WO₂, WO₃, W₂O₅, etc.), a vanadium oxide (for example, VO, V₂O₃, VO₂, V₂O₅, etc.), a molybdenum oxide (MoO, Mo₂O₃, MoO₂, MoO₃, Mo₂O₅, etc.), a rhenium oxide (for example, ReO₃, etc.), etc.

Examples of a metal halide may include an alkali metal halide, an alkaline earth metal halide, a transition metal halide, a post-transition metal halide, a lanthanide metal halide, etc.

Examples of an alkali metal halide may include LiF, NaF, KF, RbF, CsF, LiCI, NaCl, KCl, RbCl, CsCl, LiBr, NaBr, KBr, RbBr, CsBr, LiI, NaI, Kl, RbI, CsI, etc.

Examples of an alkaline earth metal halide may include BeF₂, MgF₂, CaF₂, SrF₂, BaF₂, BeCl₂, MgCl₂, CaCl₂), SrCl₂, BaCI₂, BeBr₂, MgBr₂, CaBr₂, SrBr₂, BaBr₂, Be₁₂, Mg₁₂, Cal₂, Sr₁₂, Bal₂, etc.

Examples of a transition metal halide may include a titanium halide (for example, TiF₄, TiCl₄, TiBr₄, Til₄, etc.), a zirconium halide (for example, ZrF₄, ZrC₁₄, ZrBr₄, Zr₁₄, etc.), a hafnium halide (for example, HfF₄, HfC₁₄, HfBr₄, Hfl₄, etc.), a vanadium halide (for example, VF₃, VCl₃, VBr₃, V₁₃, etc.), a niobium halide (for example, NbF₃, NbCl₃, NbBr₃, NbI₃, etc.), a tantalum halide (for example, TaF₃, TaCl₃, TaBr₃, Talb, etc.), a chromium halide (for example, CrF₃, CrCl₃, CrBr₃, Cr₁₃, etc.), a molybdenum halide (for example, MoF₃, MoCI₃, MoBr₃, MoI₃, etc.), a tungsten halide (for example, WF₃, WCl₃, WBr₃, W₁₃, etc.), a manganese halide (for example, MnF₂, MnCl₂, MnBr₂, MnI₂, etc.), a technetium halide (for example, TcF₂, TcCl₂, TcBr₂, TcI₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, Rul₂, etc.), an osmium halide (for example, OsF₂, OsCl₂, OsBr₂, OS₁₂, etc.), a cobalt halide (for example, CoF₂, CoCl₂, CoBr₂, Col₂, etc.), a rhodium halide (for example, RhF₂, RhCl₂, RhBr₂, Rh₁₂, etc.), an iridium halide (for example, IrF₂, IrCl₂, IrBr₂, Ir₁₂, etc.), a nickel halide (for example, NiF₂, NiCl₂, NiBr₂, Nil₂, etc.), a palladium halide (for example, PdF₂, PdCI₂, PdBr₂, Pd₁₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCI, AgBr, AgI, etc.), a gold halide (for example, AuF, AuCI, AuBr, AuI, etc.), etc.

Examples of a post-transition metal halide may include a zinc halide (for example, ZnF₂, ZnCl₂, ZnBr₂, Zn₁₂, etc.), an indium halide (for example, InIs, etc.), a tin halide (for example, SnI₂, etc.), etc.

Examples of a lanthanide metal halide may include YbF, YbF₂, YbF₃, SmF₃, YbCI, YbCl₂, YbCI₃, SmCl₃, YbBr, YbBr₂, YbBr₃, SmBr₃, YbI, YbI₂, YbI₃, SmI₃, etc.

Examples of a metalloid halide may include an antimony halide (for example, SbCl₅, etc.), etc.

Examples of a metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), a lanthanide metal telluride (for example, LaTe, CeTe, PrTe, NdTe, PmTe, EuTe, GdTe, TbTe, DyTe, HoTe, ErTe, TmTe, YbTe, LuTe, etc.), etc.

### [Emission Layer in Intermediate Layer 130]

When the light-emitting element 1A is a full-color light-emitting element, the emission layer may be patterned into a red emission layer, a green emission layer, and/or a blue emission layer for each individual subpixel. In an embodiment, the emission layer may have a structure in which two or more layers of a red emission layer, a green emission layer, and a blue emission layer may contact each other or may be spaced apart from each other, or the emission layer may have a structure in which two or more materials of a red light-emitting material, a green light-emitting material, and a blue light-emitting material may be mixed together in a layer to emit white light.

The emission layer may include a quantum dot.

In embodiments, the quantum dot may be a crystal of a semiconductor compound and may include any material that may emit light of various emission wavelengths depending on a size of the crystal. The quantum dot may emit light of various emission wavelengths by controlling an elemental ratio in the quantum dot compound.

The diameter of the quantum dot may be, for example, in a range of about 1 nm to about 10 nm.

The quantum dot may be synthesized by a wet chemical process, a metal organic chemical vapor deposition process, a molecular beam epitaxy process, or a similar process.

The wet chemical process is a method of growing a quantum dot particle crystal by mixing an organic solvent and a precursor material. During crystal growth, the organic solvent naturally serves as a dispersing agent that is coordinated on the surface of the quantum dot crystal and controls the growth of the crystal, so that the growth of the quantum dot particle may be controlled through a process that is more readily performed and less expensive than vapor deposition methods such as metal organic chemical vapor deposition (MOCVD) or molecular beam epitaxy (MBE), etc.

A quantum dot may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of a Group II-VI semiconductor compound may include: a binary compound such as CdS, CdSe, CdTe, ZnS, ZnSe, ZnTe, ZnO, HgS, HgSe, HgTe, MgSe, MgS, etc.; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, etc.; a quaternary compound such as CdZnSeS, CdZnSeTe, CdZnSTe, CdHgSeS, CdHgSeTe, CdHgSTe, HgZnSeS, HgZnSeTe, HgZnSTe, etc.; and any combination thereof.

Examples of a Group III-V semiconductor compound may include: a binary compound such as GaN, GaP, GaAs, GaSb, AlN, AIP, AIAs, AISb, InN, InP, InAs, InSb, etc.; a ternary compound such as GaNP, GaNAs, GaNSb, GaPAs, GaPSb, AlNP, AlNAs, AlNSb, AIPAs, AIPSb, InGaP, InNP, InAIP, InNAs, InNSb, InPAs, InPSb, GaAINP, etc.; or a quaternary compound such as GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb, etc.; and any combination thereof. In an embodiment, a Group III-V semiconductor compound may further include a Group II element.

Examples of a Group III-V semiconductor compound further including a Group II element may include InZnP, InGaZnP, InAIZnP, etc.

Examples of a Group III-VI semiconductor compound may include: a binary compound such as GaS, GaSe, Ga₂Se₃, GaTe, InS, InSe, In₂S₃, In₂Se₃, InTe, etc.; a ternary compound such as InGaS₃, InGaSe₃, etc.; and any combination thereof.

Examples of a Group I-III-VI semiconductor compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAIO₂, etc.; a quaternary compound such as AgInGaS₂, AgInGaSe₂, etc.; and any combination thereof.

Examples of a Group IV-VI semiconductor compound may: include a binary compound such as SnS, SnSe, SnTe, PbS, PbSe, PbTe, etc.; a ternary compound such as SnSeS, SnSeTe, SnSTe, PbSeS, PbSeTe, PbSTe, SnPbS, SnPbSe, SnPbTe, etc.; a quaternary compound such as SnPbSSe, SnPbSeTe, SnPbSTe, etc.; and any combination thereof.

Examples of a Group IV element or compound may include a single-element material such as Si, Ge, etc.; a binary compound such as SiC, SiGe, etc.; and any combination thereof.

Each element included in a compound, such as a binary compound, a ternary compound, or a quaternary compound, may be present in a particle at a uniform concentration or at a non-uniform concentration. The formula for quantum dot compounds as described above may each refer to the type of elements that are included in a compound, wherein an element ratio of a compound may vary. For example, AgInGaS₂ may indicate AgInₓGa₁₋ₓS₂ (wherein x is a real number between 0 and 1).

In an embodiment, a quantum dot may have a single structure in which the concentration of each element included in the corresponding quantum dot is uniform, or the quantum dot may have a core-shell structure. In an embodiment, in case that the quantum dot has a core-shell structure, a material included in the core and a material included in the shell may be different from each other.

The shell of the quantum dot may serve as a protective layer to maintain semiconductor properties by preventing chemical modification of the core and/or may serve as a charging layer to impart electrophoretic properties to the quantum dot. The layer may be single-layered or multi-layered. An interface between the core and the shell may have a concentration gradient in which the concentration of a material that is present in the shell decreases toward the core.

Examples of a shell of the quantum dot may include a metal oxide, a non-metal oxide, a semiconductor compound, or combinations thereof, etc. Examples of a metal oxide, or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, etc.; a ternary compound such as MgAl₂O₄, CoFe₂O₄, NiFe₂O₄, CoMn₂O₄, etc.; and any combination thereof.

Examples of a semiconductor compound may include a Group II-VI semiconductor compound, a Group III-V semiconductor compound, a Group III-VI semiconductor compound, a Group I-III-VI semiconductor compound, the Group IV-VI semiconductor compound, and any combination thereof, as disclosed herein. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AIP, AISb, or any combination thereof.

The quantum dot may have a full width at half maximum (FWHM) of an emission wavelength spectrum less than or equal to about 45 nm. For example, the quantum dot may have a FWHM of an emission wavelength spectrum less than or equal to about 40 nm. For example, the quantum dot may have a FWHM of an emission wavelength spectrum less than or equal to about 30 nm. Color purity or color reproduction may be enhanced in any of these ranges. Light emitted through these quantum dots may be emitted in all directions, which may enhance a viewing angle.

In an embodiment, the quantum dot may be in a spherical form, a pyramidal form, a multi-arm form, or a cubic form, or the quantum dot may be in the form of nanoparticles, nano-tubes, nano-wires, nano-fibers, nano-platelets, etc.

By adjusting a size of the quantum dot, the energy band gap may be controlled, so that light of various wavelengths may be obtained from the quantum dot emission layer. Therefore, by using quantum dots of different sizes, light-emitting elements that emit light of different wavelengths may be implemented. In an embodiment the size of the quantum dot or the elemental ratio of the quantum dot compound may be adjusted to emit red light, green light and/or blue light. The quantum dot may be configured to emit white light by combining light of various colors.

The emission layer may be formed by applying an ink composition onto the hole transport region and volatilizing one or more portions of a solvent included in the ink composition.

The ink composition may be applied using an ink jet printing method, a spin coat method, a casting method, a micro gravure coat method, a gravure coat method, a bar coat method, a roll coat method, a wire bar coat method, a dip coat method, a spray coat method, a screen printing method, a flexographic printing method, an offset printing method, etc.

In an embodiment, the emission layer may further include a host and a dopant in addition to the quantum dot. The dopant may include a phosphorescent dopant, a fluorescent dopant, or any combination thereof.

An amount of the dopant in the emission layer may be in a range of about 0.01 parts by weight to about 15 parts by weight, based on 100 parts by weight of the host.

In an embodiment, the emission layer may include a delayed fluorescent material. The delayed fluorescent material may serve as a host or as a dopant in the emission layer.

A thickness of the emission layer may be in a range of about 100 Å to about 1000 Å. For example, the thickness of the emission layer may be in a range of about 200 Å to about 600 Å. When the thickness of the emission layer satisfies any of the aforementioned ranges, excellent light-emitting characteristics may be exhibited without a substantial increase in driving voltage.

### [Host]

The host may include a compound represented by Formula 301:

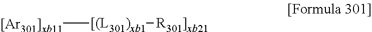

In Formula 301,
Ar₃₀₁ to L₃₀₁ may each independently be a C₃-C₆₀ carbocyclic group substituted or unsubstituted with at least one R₁₀ₐ or a C₁-C₆₀ heterocyclic group substituted or unsubstituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group substituted or unsubstituted with at least one R₁₀ₐ, a C₂-C₆₀ alkenyl group substituted or unsubstituted with at least one R₁₀ₐ, a C₂-C₆₀ alkynyl group substituted or unsubstituted with at least one R₁₀ₐ, a C₁-C₆₀ alkoxy group substituted or unsubstituted with at least one R₁₀ₐ, a C₃-C₆₀ carbocyclic group substituted or unsubstituted with at least one R₁₀ₐ, a C₁-C₆₀ heterocyclic group substituted or unsubstituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5,
Q₃₀₁ to Q₃₀₃ may each independently be the same as described in connection with Q₁.

In an embodiment, in Formula 301, when xb11 is two or more, two or more Ar₃₀₁ may be connected to each other through a single bond.

In an embodiment, the host may include a compound represented by Formula 301-1, a compound represented by Formula 301-2, or any combination thereof:

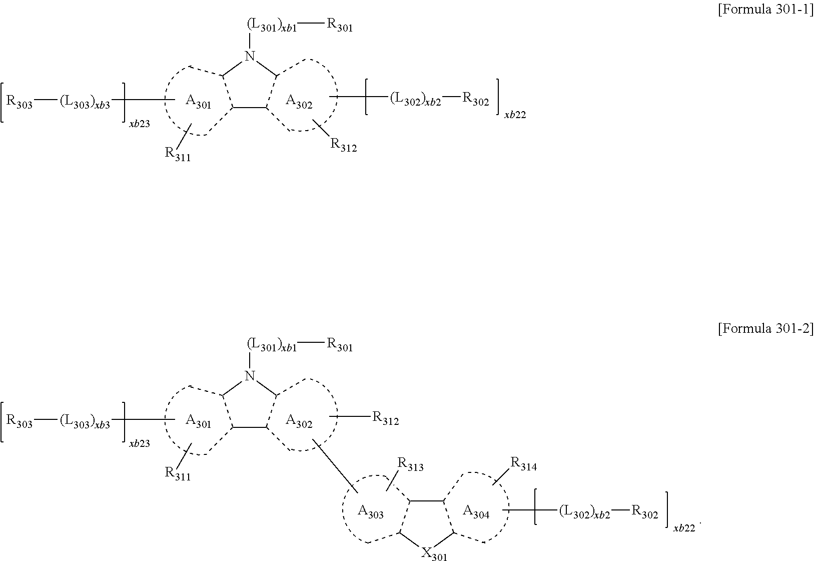

In Formulae 301-1 and 301-2,
ring A₃₀₁ to ring A₃₀₄ may each independently be a C₃-C₆₀ carbocyclic group substituted or unsubstituted with at least one R₁₀ₐ or a C₁-C₆₀ heterocyclic group substituted or unsubstituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In an embodiment, the host may include an alkaline earth metal complex, a post-transition metal complex, or any combination thereof. For example, the host may include a Be complex (for example, compound H55), an Mg complex, a Zn complex, or any combination thereof.

In an embodiment, the host may include one of Compounds H1 to H128, ADN (9,10-Di(2-naphthyl)anthracene), MADN (2-Methyl-9,10-bis(naphthalen-2-yl)anthracene), TBADN (9,10-di-(2-naphthyl)-2-t-butyl-anthracene), CBP (4,4′-bis(N-carbazolyl)-1,1′-biphenyl), mCP (1,3-di-9-carbazolylbenzene), TCP (1,3,5-tri(carbazol-9-yl)benzene), or any combination thereof:

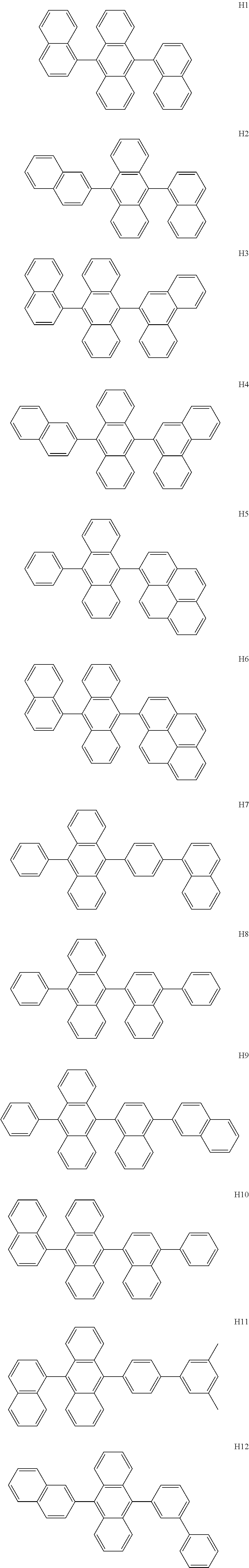

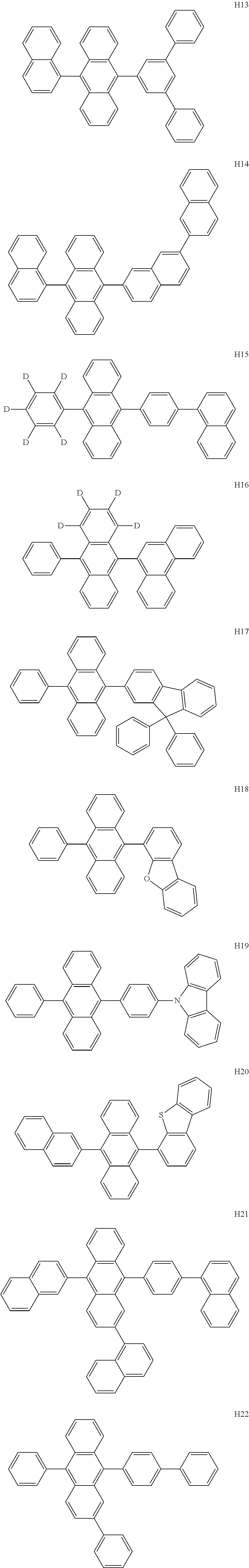

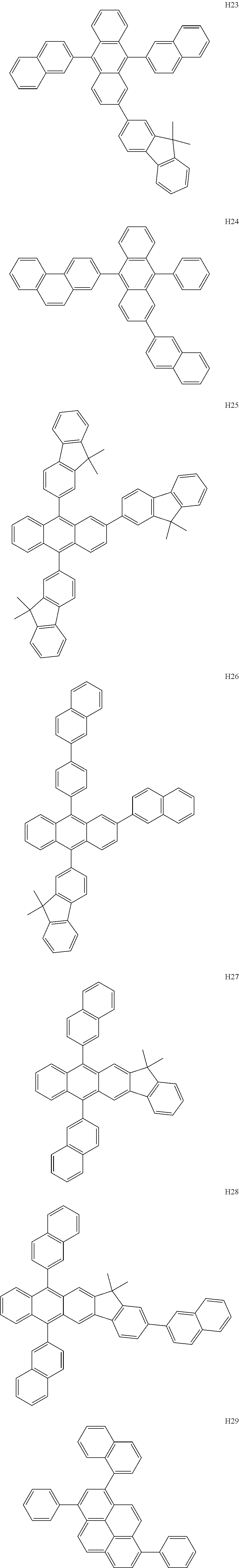

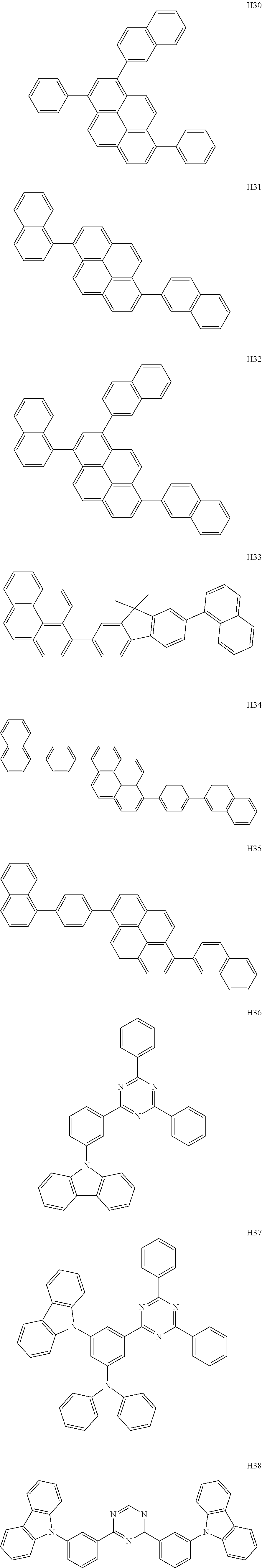

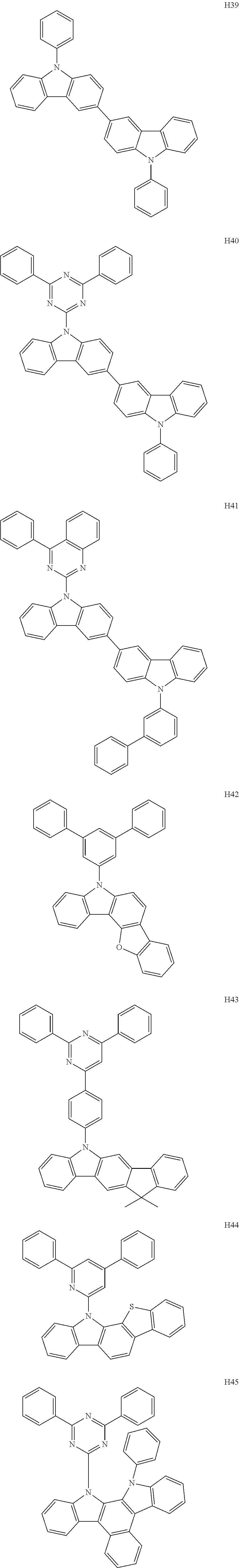

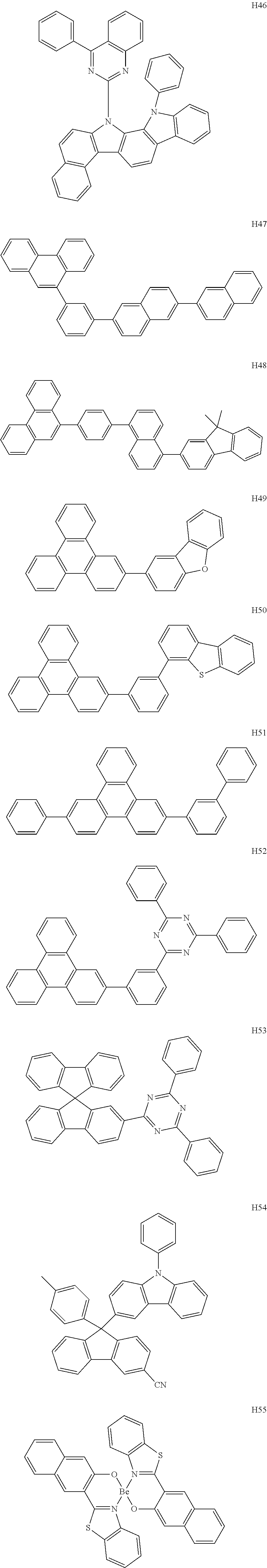

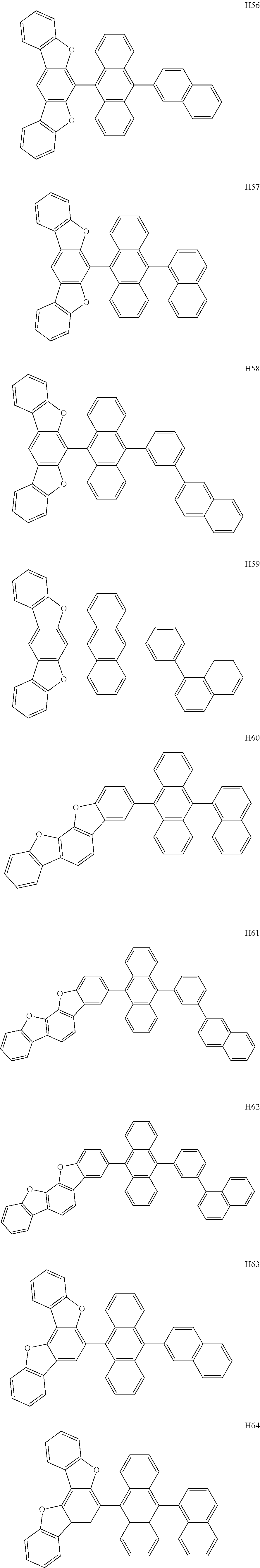

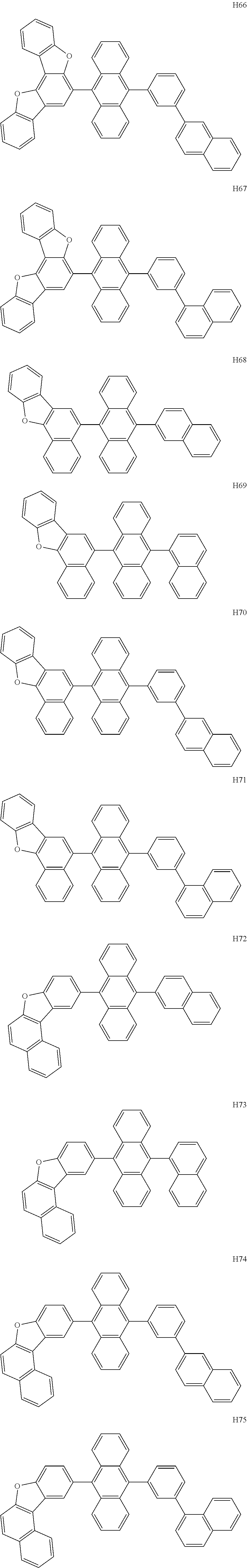

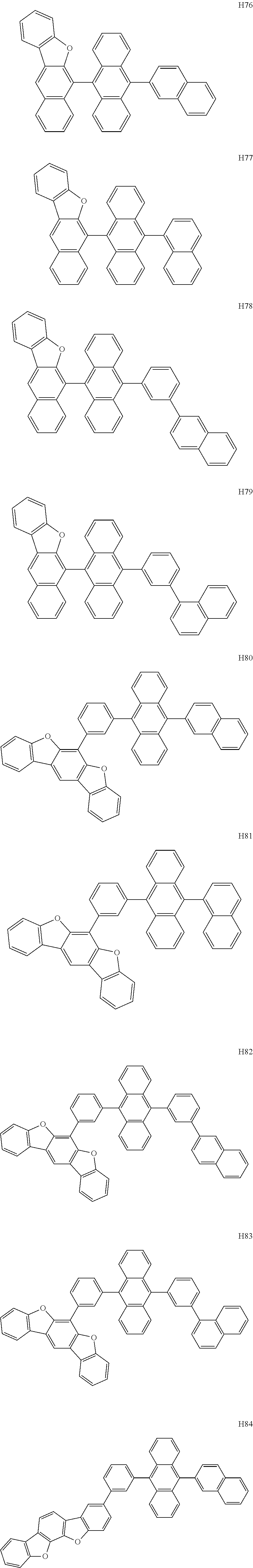

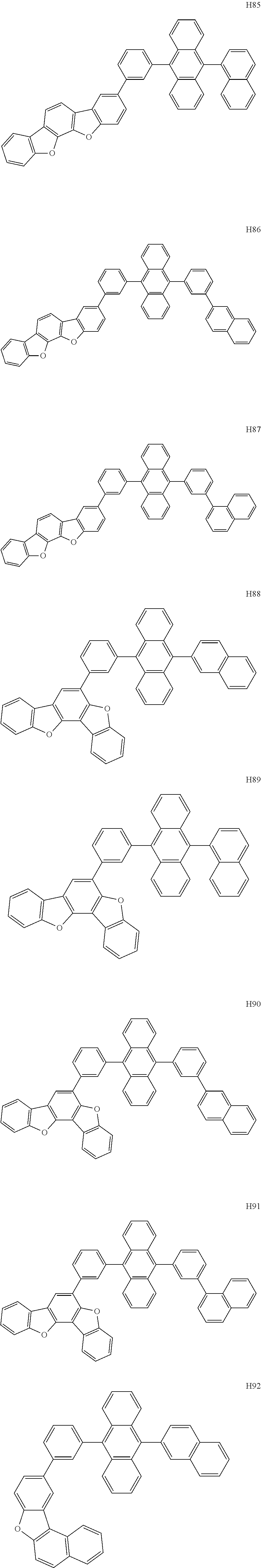

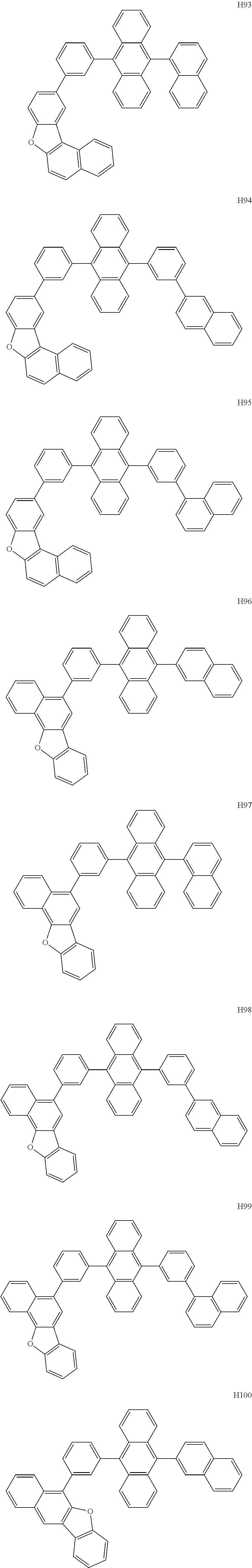

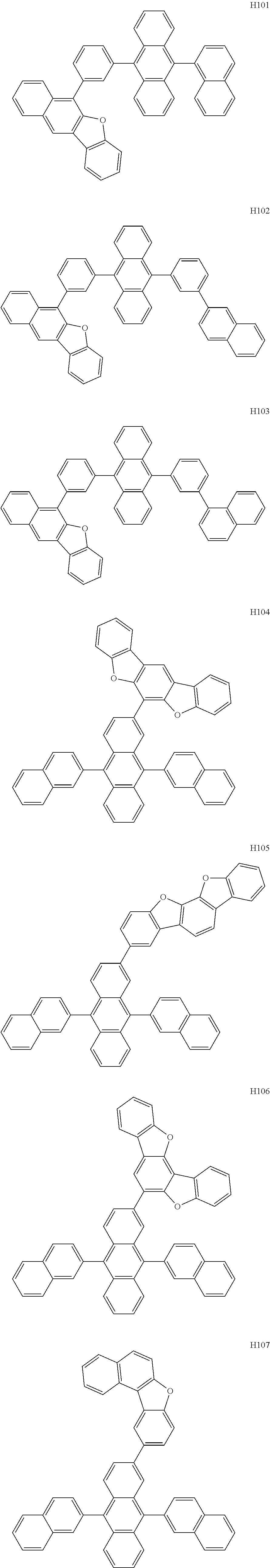

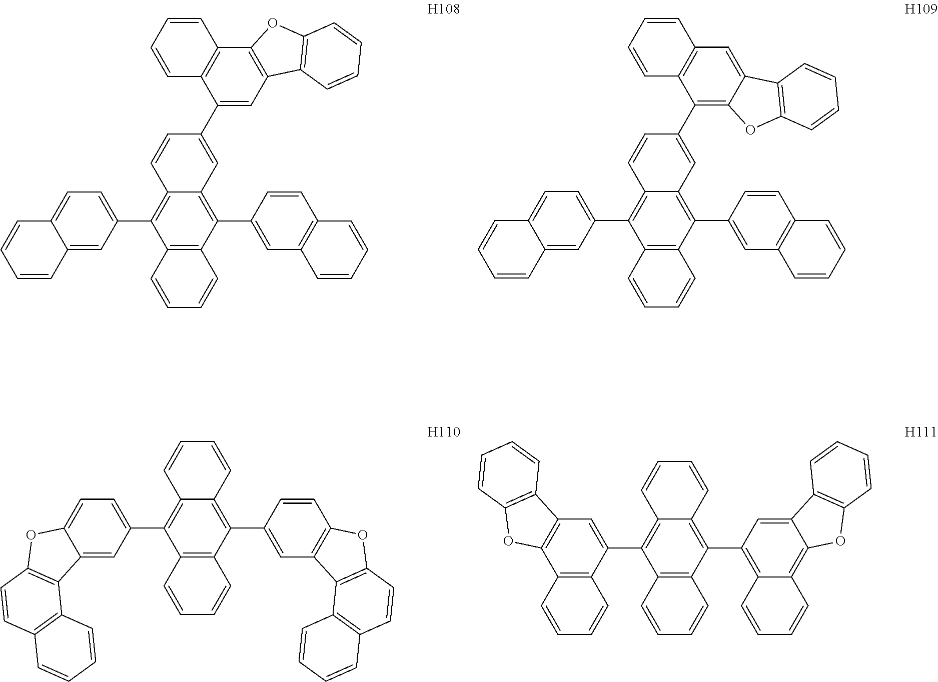 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

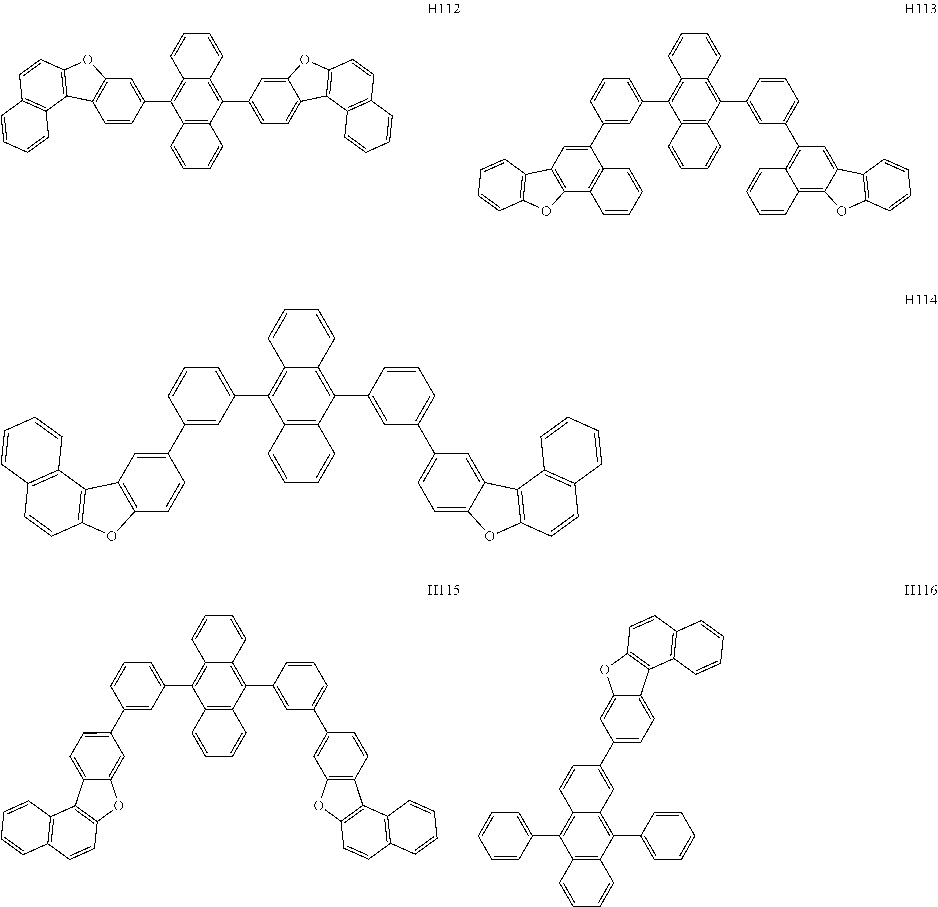 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

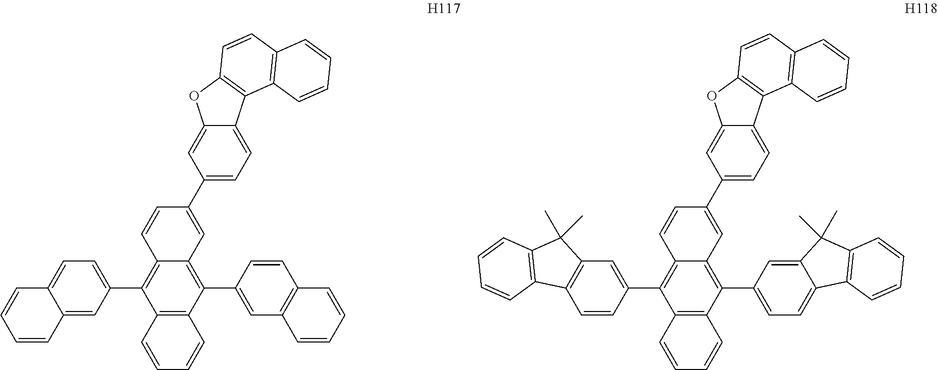 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

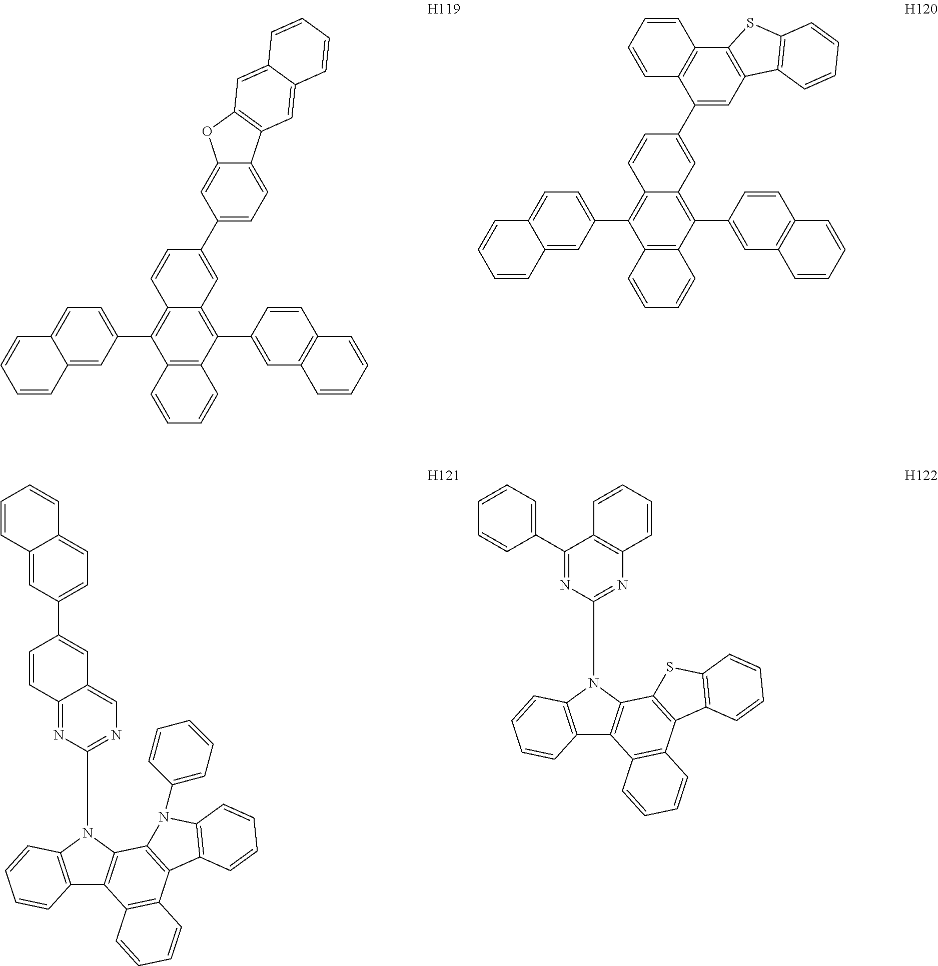 [SMILES: c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1]

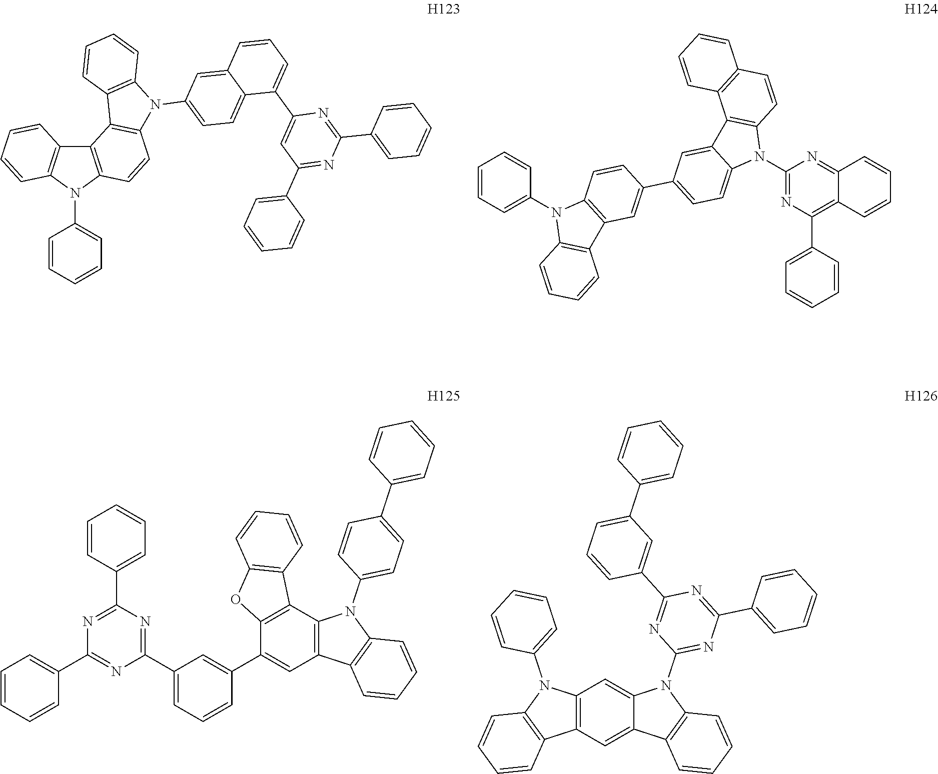 [SMILES: c1ccc(-c2cc(-c3cccc4cc(-n5c6ccccc6c6c7c8ccccc8n(-c8ccccc8)c7ccc65)ccc34)nc(-c3ccccc3)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1]

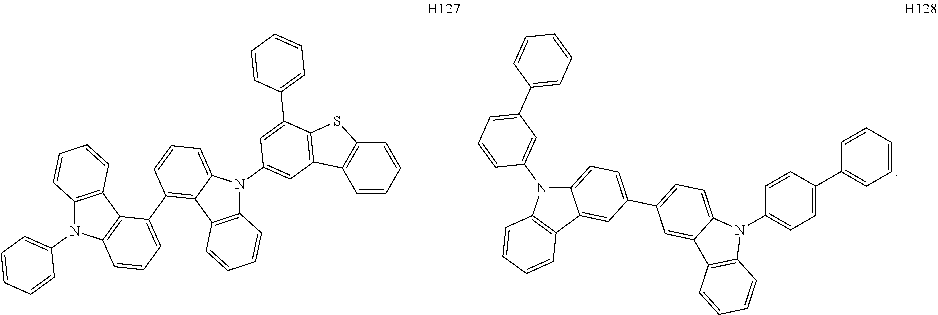 [SMILES: c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

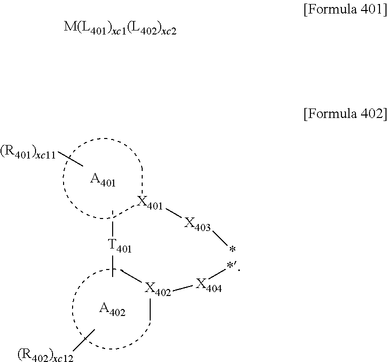

In Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2 or 3, wherein when xc1 is two or more, two or more L₄₀₁ may be the same as or different from each other,
L₄₀₂ may be an organic ligand, and xc2 may be 0, 1, 2, 3, or 4, wherein when xc2 is two or more, two or more L₄₀₂ may be the same as or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)═*′ or *═C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group substituted or unsubstituted with at least one R₁₀ₐ, a C₁-C₂₀ alkoxy group substituted or unsubstituted with at least one R₁₀ₐ, a C₃-C₆₀ carbocyclic group substituted or unsubstituted with at least one R₁₀ₐ, a C₁-C₆₀ heterocyclic group substituted or unsubstituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described in connection with Q₁,
xc11 and xc12 may each independently be an integer from 0 to 10, and
in Formula 402, * and *′ each indicate a binding site to M in Formula 401.

In an embodiment, in Formula 402 X₄₀₁ may be nitrogen and X₄₀₂ may be carbon, or X₄₀₁ and X₄₀₂ may each be nitrogen.

In an embodiment, in Formula 401, when xc1 is two or more, two ring A₄₀₁ among two or more L₄₀₁ may be optionally connected to each other via a linking group T₄₀₂, or two ring A₄₀₂ may be optionally connected to each other via a linking group T₄₀₃ (see compounds PD1 to PD4 and PD7). T₄₀₂ and T₄₀₃ may each independently be the same as described in connection with T₄₀₁.

In Formula 401, L₄₀₂ may be any organic ligand. For example, the L₄₀₂ may include a halogen group, a diketone group (for example, an acetylacetonate group), a carboxylic acid group (for example, a picolinate group), —C(═O), an isonitrile group, —CN group, a phosphorus group (for example, a phosphine group, a phosphite group, etc.), or any combination thereof.

In an embodiment, the phosphorescent dopant may include, for example, one of Compounds PD1 to PD39, or any combination thereof:

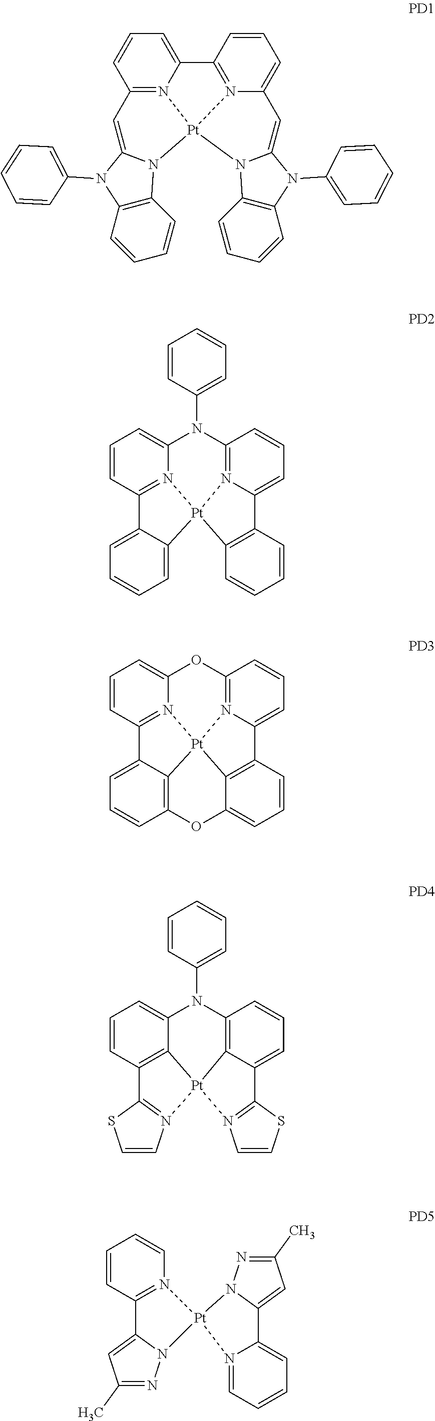

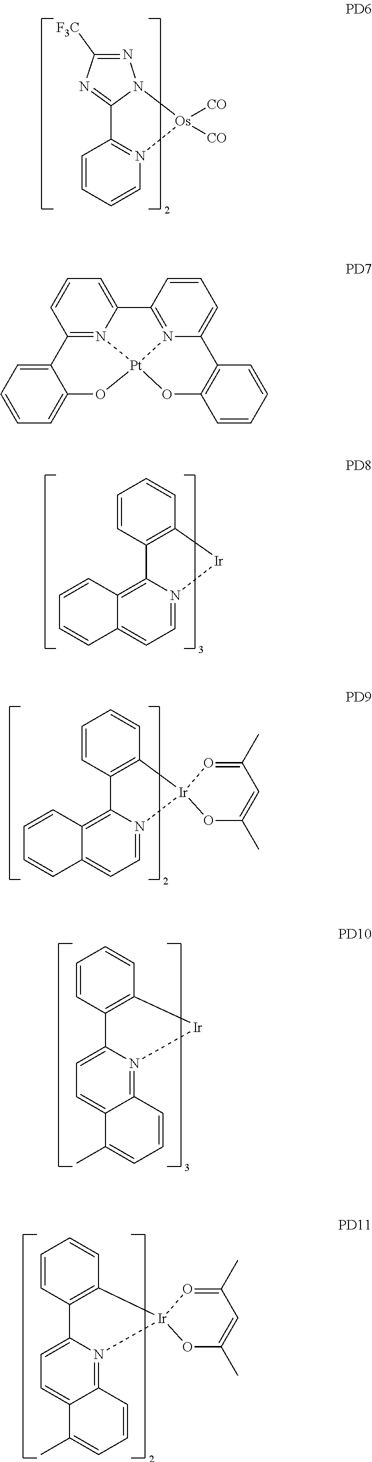

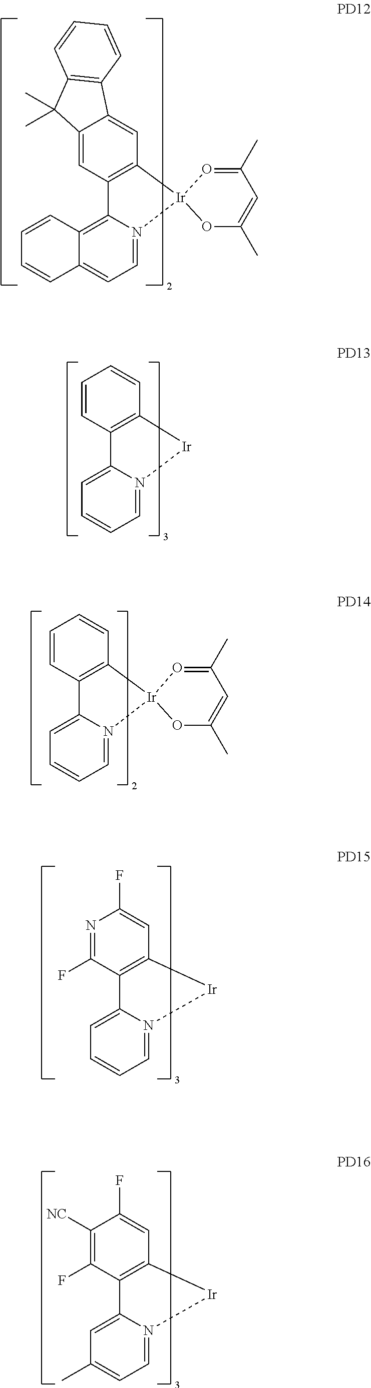

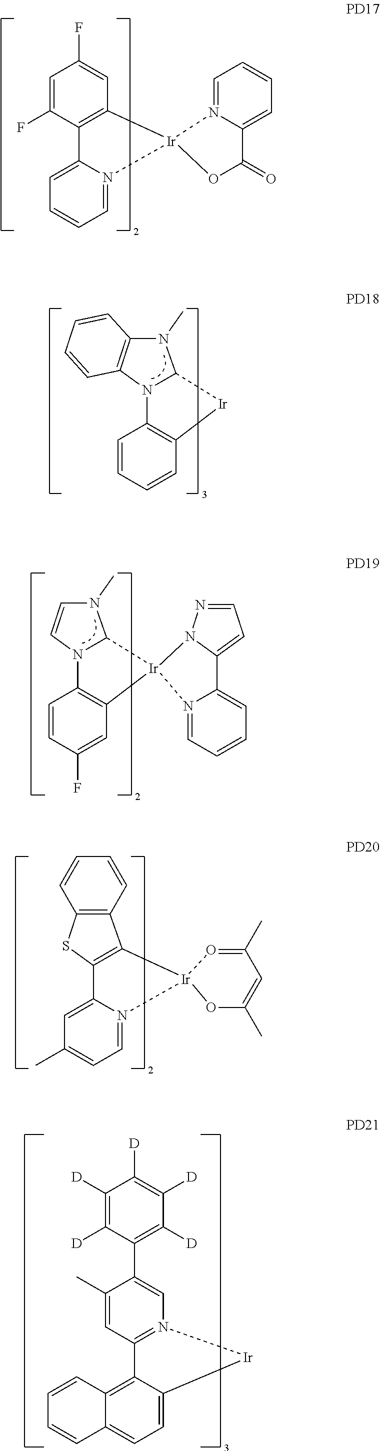

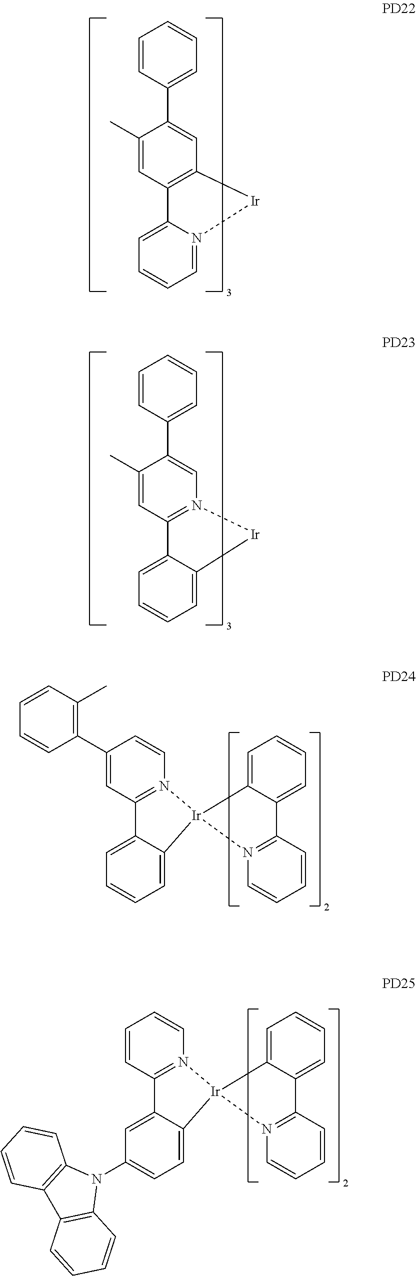

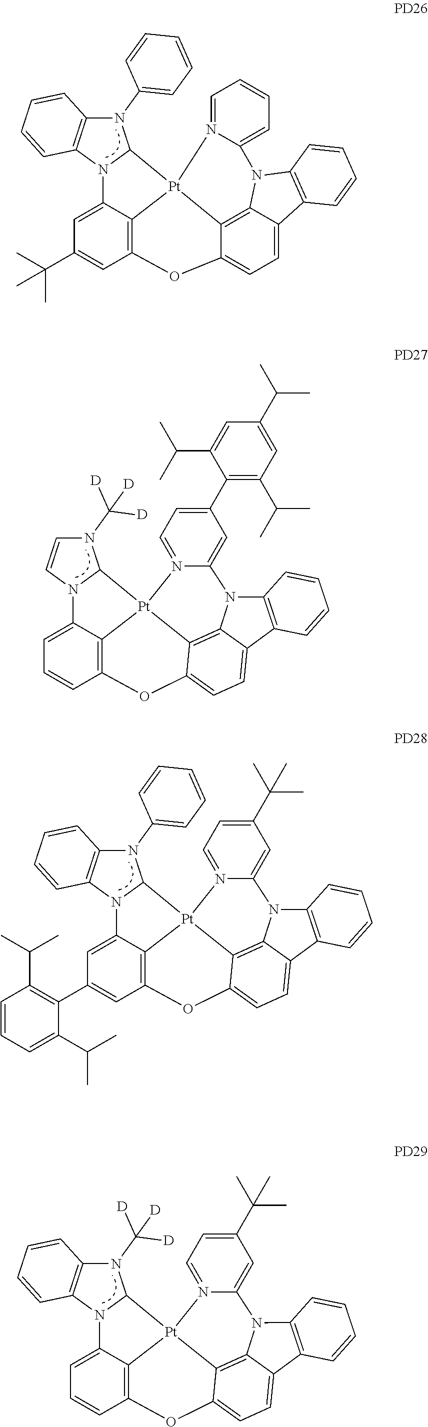

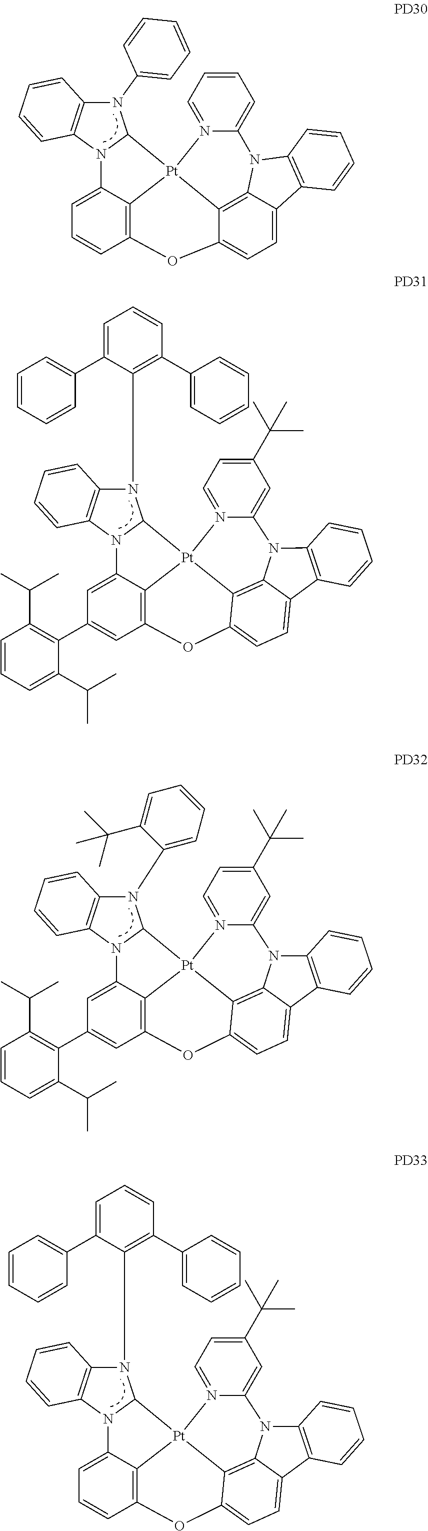

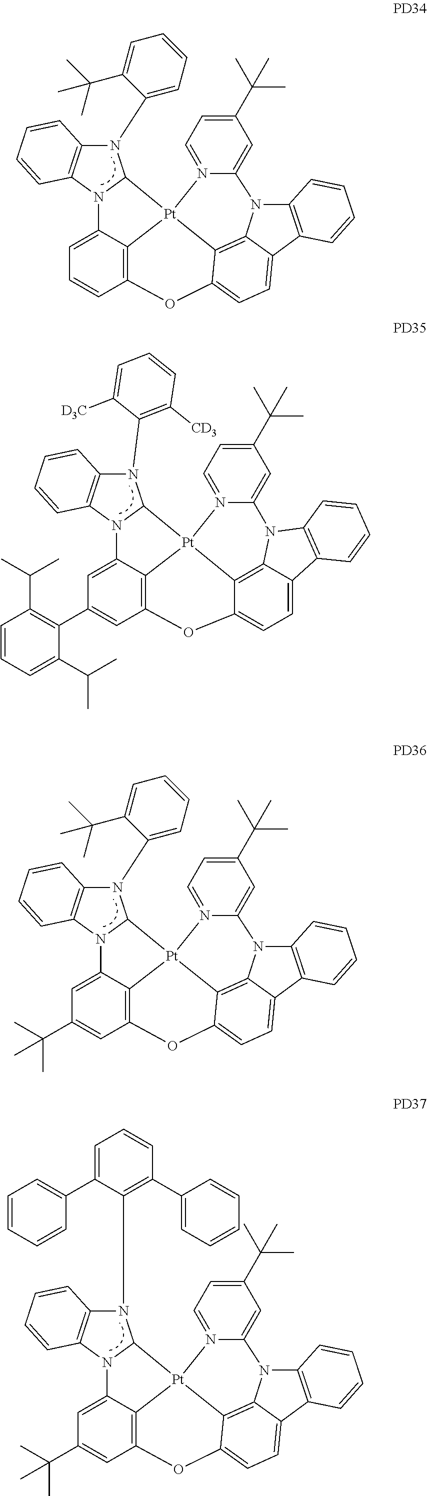

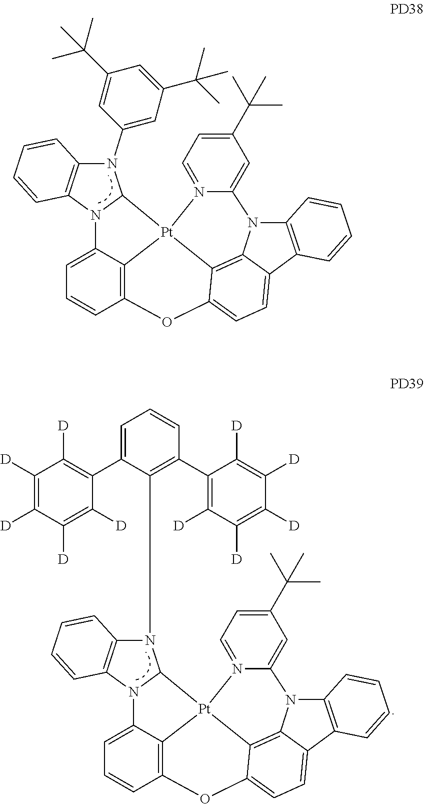

### [Fluorescent Dopant]

The fluorescent dopant may include an amine group-containing compound, a styryl group-containing compound, or any combination thereof.

In an embodiment, the fluorescent dopant may include a compound represented by Formula 501:

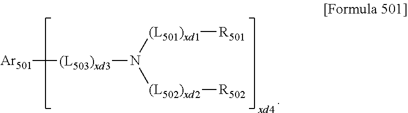

In Formula 501,
Ar₅₀₁, L₅₀₁ to L₅₀₃, R₅₀₁ and R₅₀₂ may each independently be a C₃-C₆₀ carbocyclic group substituted or unsubstituted with at least one R₁₀ₐ or a C₁-C₆₀ heterocyclic group substituted or unsubstituted with at least one R₁₀ₐ,
xd1 to xd3 may each independently be 0, 1, 2, or 3,
xd4 may be 1, 2, 3, 4, 5, or 6.

In an embodiment, in Formula 501, Ar₅₀₁ may include a condensed cyclic group (for example, an anthracene group, a chrysene group, a pyrene group, etc.) in which three or more monocyclic groups are condensed with each other.

In an embodiment, in Formula 501, xd4 may be 2.

In an embodiment, the fluorescent dopant may include one of Compounds FD1 to FD37, DPVBi, DPAVBi, or any combination thereof:

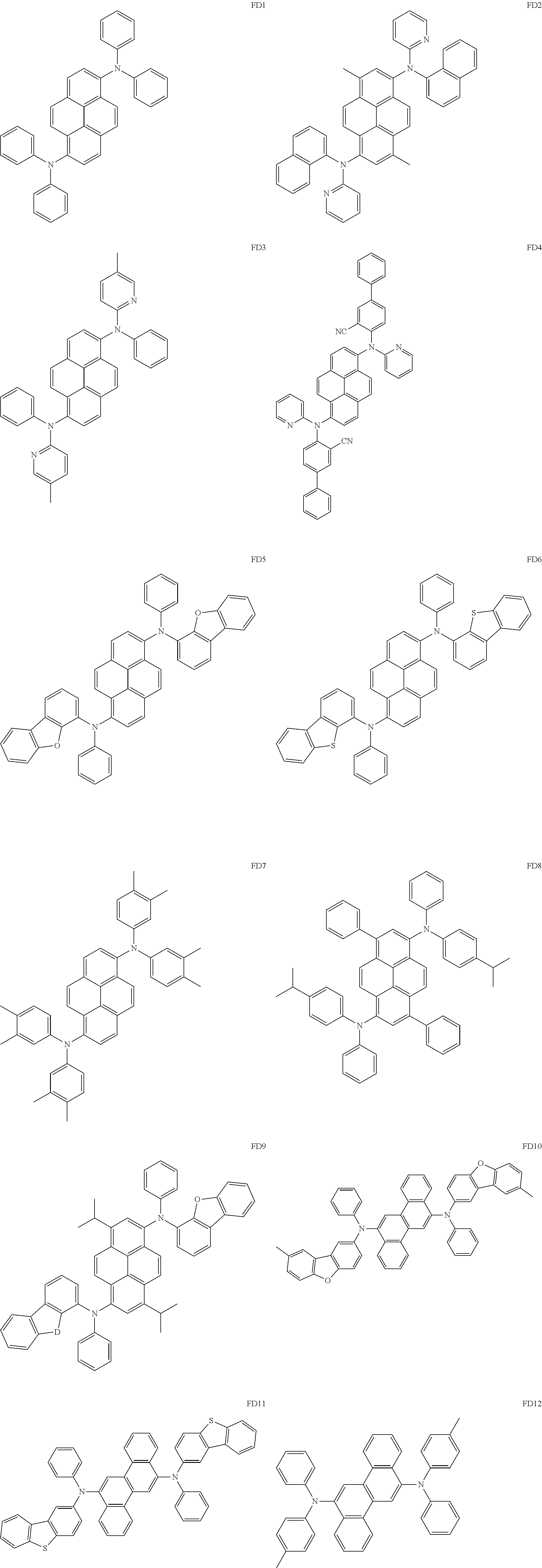

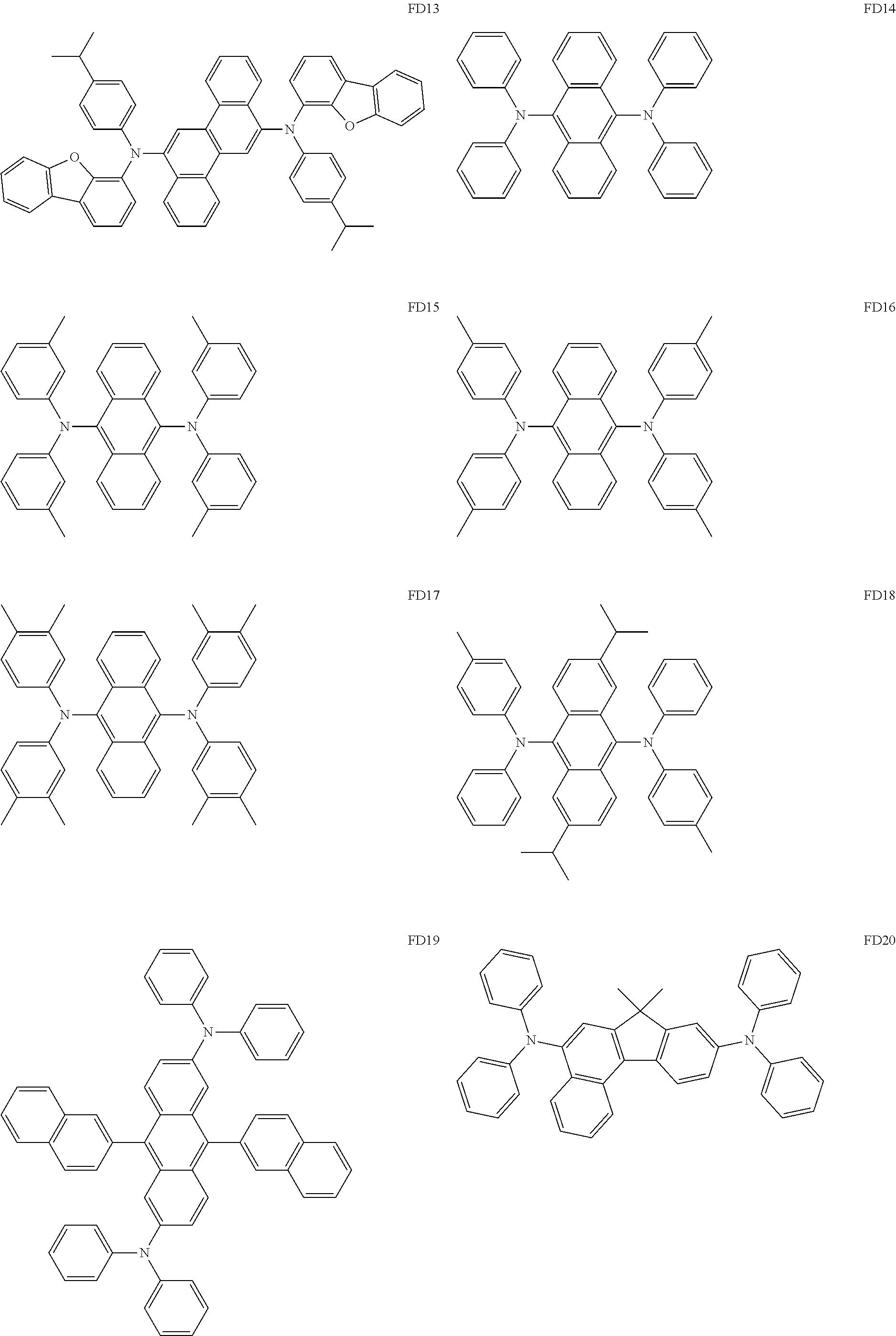

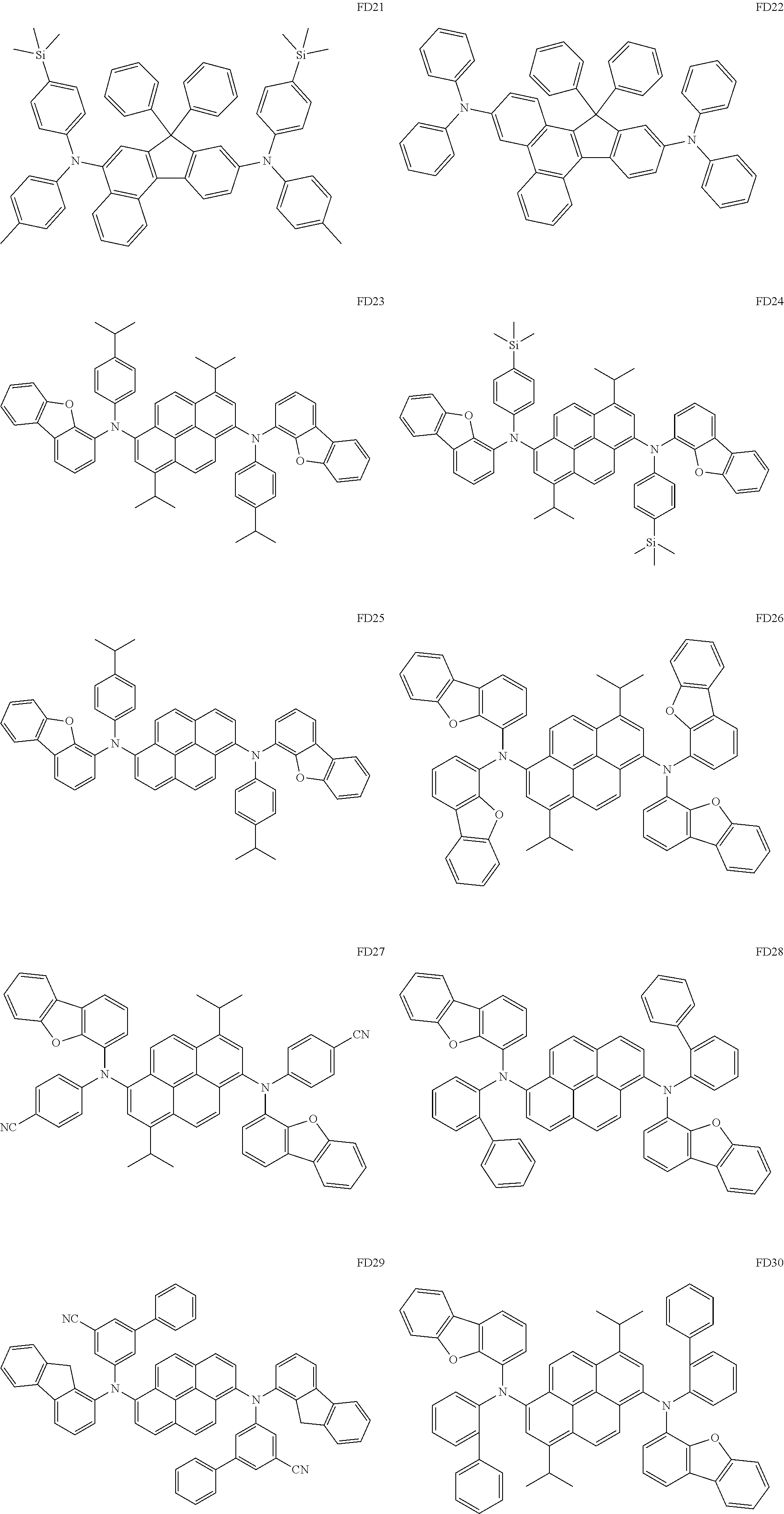

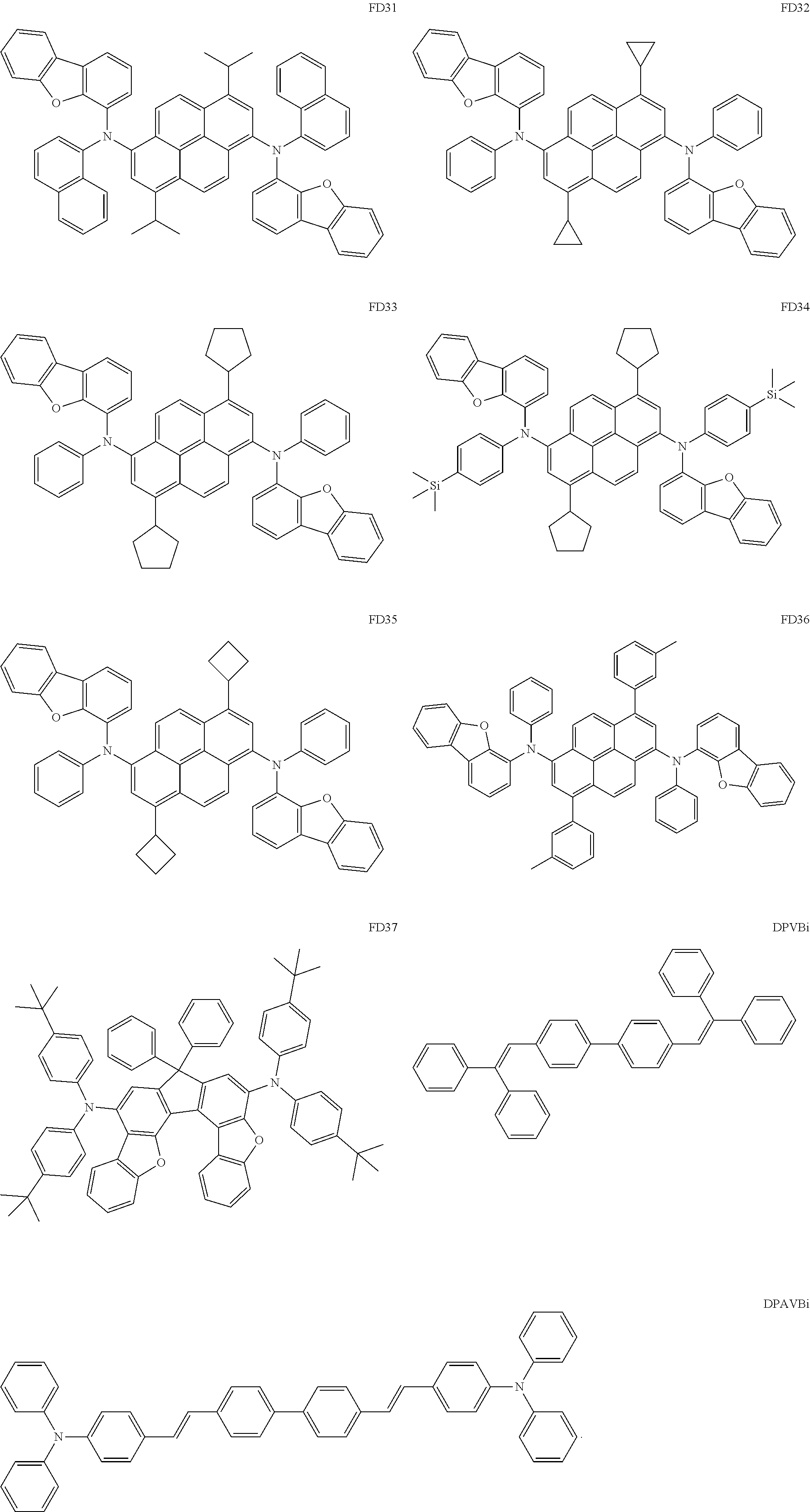

### [Delayed Fluorescent Material]

In an embodiment, the emission layer may include a delayed fluorescent material.

In the specification, a delayed fluorescent material may be selected from any compound that may emit delayed fluorescence, based on a delayed fluorescence emission mechanism.

The delayed fluorescent material included in the emission layer may serve as a host or as a dopant, depending on the types of other material included in the emission layer.

According to an embodiment, a difference between a triplet energy level (eV) of the delayed fluorescent material and a singlet energy level (eV) of the delayed fluorescent material may be in a range of about 0 eV to about 0.5 eV. When a difference between a triplet energy level (eV) of the delayed fluorescent material and a singlet energy level (eV) of the delayed fluorescent material satisfies the range described above, up-conversion from a triplet state to singlet state in the delayed fluorescent material may be effectively achieved, so that luminescence efficiency of the light-emitting element 1A, etc. may be enhanced.

In an embodiment, the delayed fluorescent material may include: a material including at least one electron donor (for example, a π electron-rich C₃-C₆₀ cyclic group such as a carbazole group, etc.) and at least one electron acceptor (for example, a sulfoxide group, a cyano group, a π electron-deficient nitrogen-containing C₁-C₆₀ cyclic group, etc.); a material including a C₈-C₆₀ polycyclic group including two or more cyclic groups that are condensed with each other while sharing boron (B); etc.

In an embodiment, the delayed fluorescent material may include, for example, at least one of Compounds DF1 to DF14:

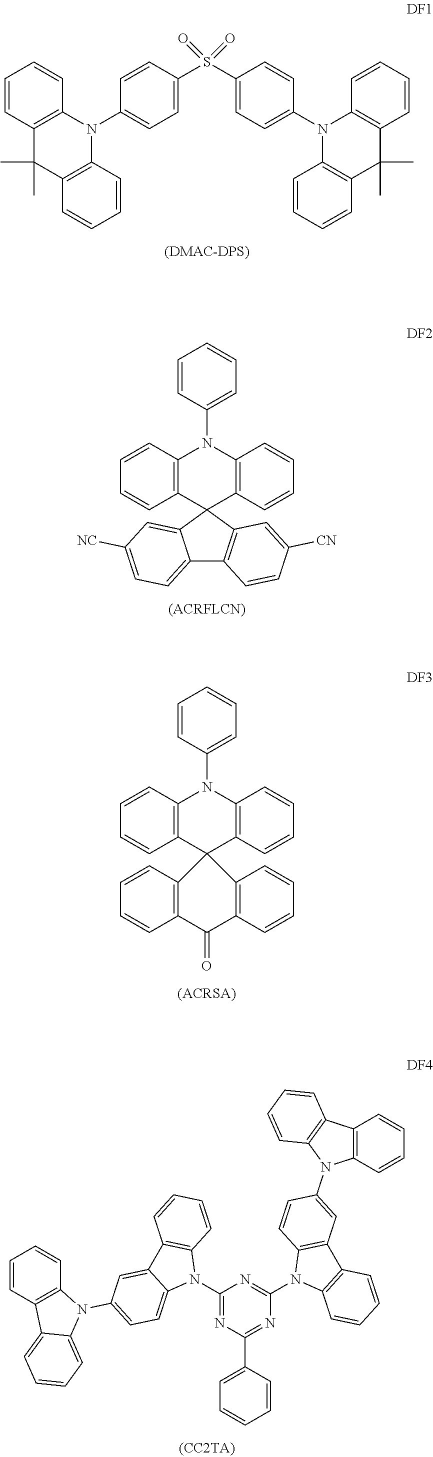

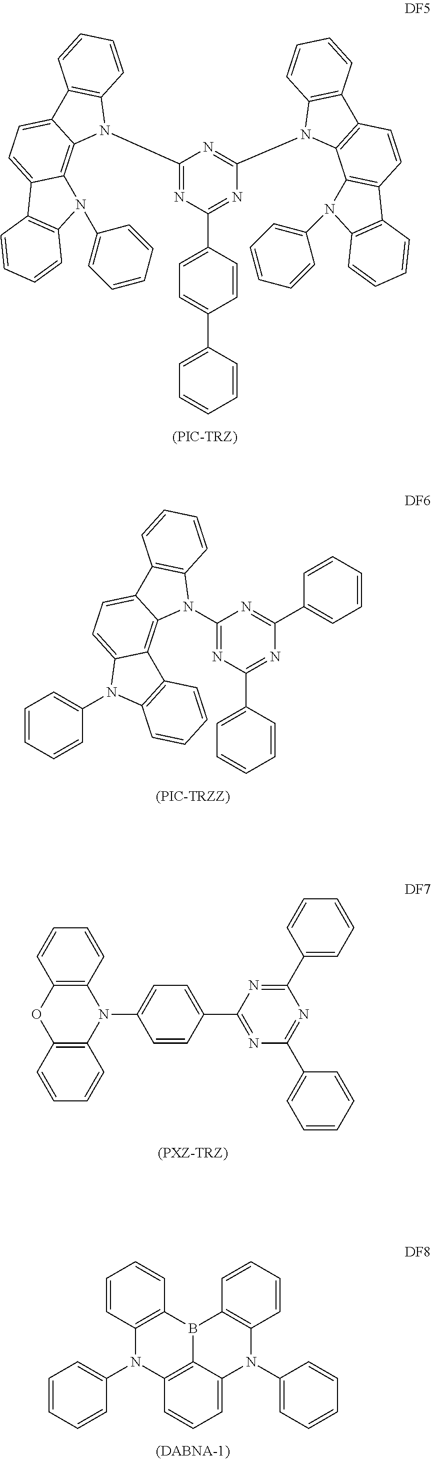

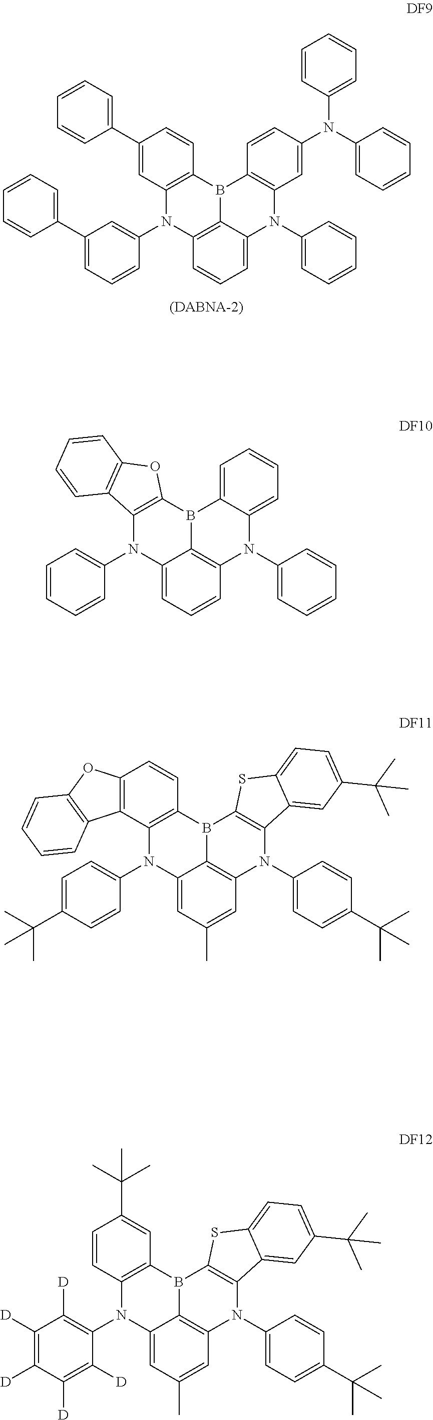

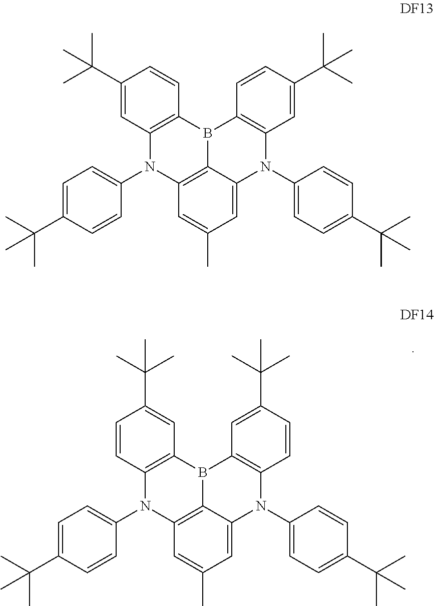

[Electron Transport Region within Intermediate Layer 130]

The electron transport region may have a structure consisting of a layer consisting of a single material, a structure consisting of a layer including different materials, or a structure including multiple layers including different materials.

The electron transport region may include a buffer layer, a hole blocking layer, an electron control layer, an electron transport layer, an electron injection layer, or any combination thereof.

In an embodiment, the electron transport region may have a multilayered structure, such as an electron transport layer/electron injection layer structure, a hole blocking layer/electron transport layer/electron injection layer structure, an electron control layer/electron transport layer/electron injection layer structure, or a buffer layer/electron transport layer/electron injection layer structure, in which the layers of each structure may be stacked from an emission layer in its respective stated order, but the structure of the electron transport region is not limited thereto.

The electron transport region (for example, a buffer layer, a hole blocking layer, an electron control layer, or an electron transport layer in the electron transport region) may include a metal-free compound including at least one π electron-deficient nitrogen-containing C₁-C₆₀ cyclic group.

In an embodiment, the electron transport region may include a compound represented by Formula 601.

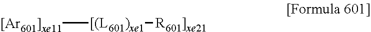

In Formula 601,
Ar₆₀₁ to L₆₀₁ may each independently be a C₃-C₆₀ carbocyclic group substituted or unsubstituted with at least one R₁₀ₐ or a C₁-C₆₀ heterocyclic group substituted or unsubstituted with at least one R₁₀ₐ,
xe11 may be 1, 2 or 3,
xe1 may be 0, 1, 2, 3, 4, or 5,
R₆₀₁ may be a C₃-C₆₀ carbocyclic group substituted or unsubstituted with at least one R₁₀ₐ, a C₁-C₆₀ heterocyclic group substituted or unsubstituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5,

At least one of the Ar₆₀₁, L₆₀₁ and R₆₀₁ may each independently be a π electron-deficient nitrogen-containing C₁-C₆₀ cyclic group substituted or unsubstituted with at least one R₁₀ₐ.

In an embodiment, in Formula 601, when xe11 is two or more, two or more Ar₆₀₁ may be connected to each other through a single bond.

In an embodiment, in Formula 601, Ar₆₀₁ may be an anthracene group substituted or unsubstituted with at least one R₁₀ₐ.

In an embodiment, the electron transport region may include a compound represented by Formula 601-1:

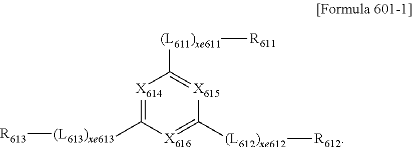

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be a hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group substituted or unsubstituted with at least one R₁₀ₐ, or a C₁-C₆₀ heterocyclic group substituted or unsubstituted with at least one R₁₀ₐ.

In an embodiment, in Formulae 601 and 601-1, xe1 and xe611 to xe613 may each independently be 0, 1, or 2.

In an embodiment, the electron transport region may include one of Compounds ET1 to ET45, BCP (2,9-Dimethyl-4,7-diphenyl-1,10-phenanthroline), Bphen (4,7-Diphenyl-1,10-phenanthroline), Alq3, BAIq, TAZ, NTAZ, or any combination thereof:

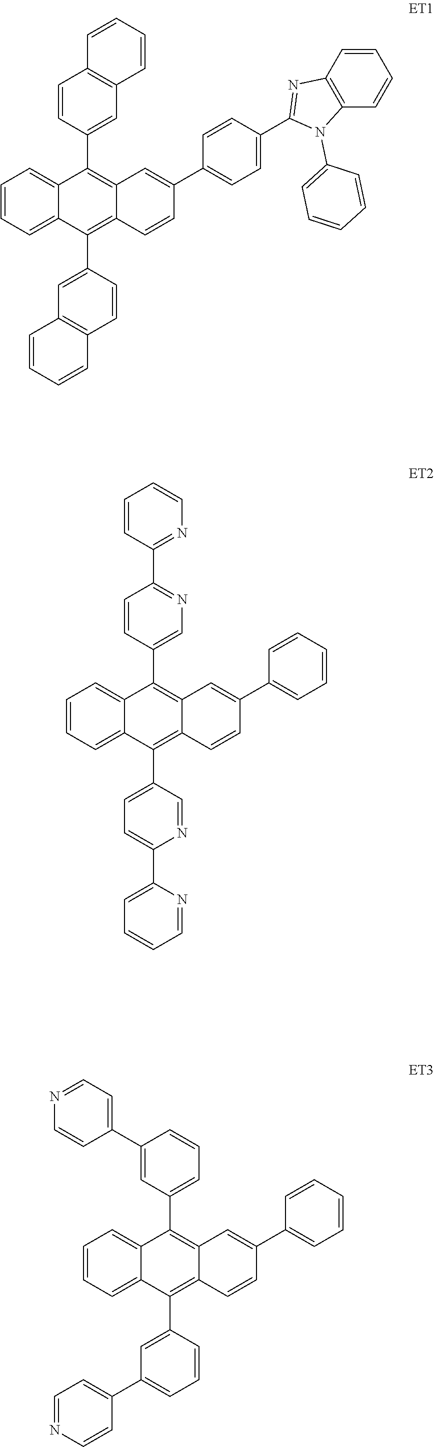 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

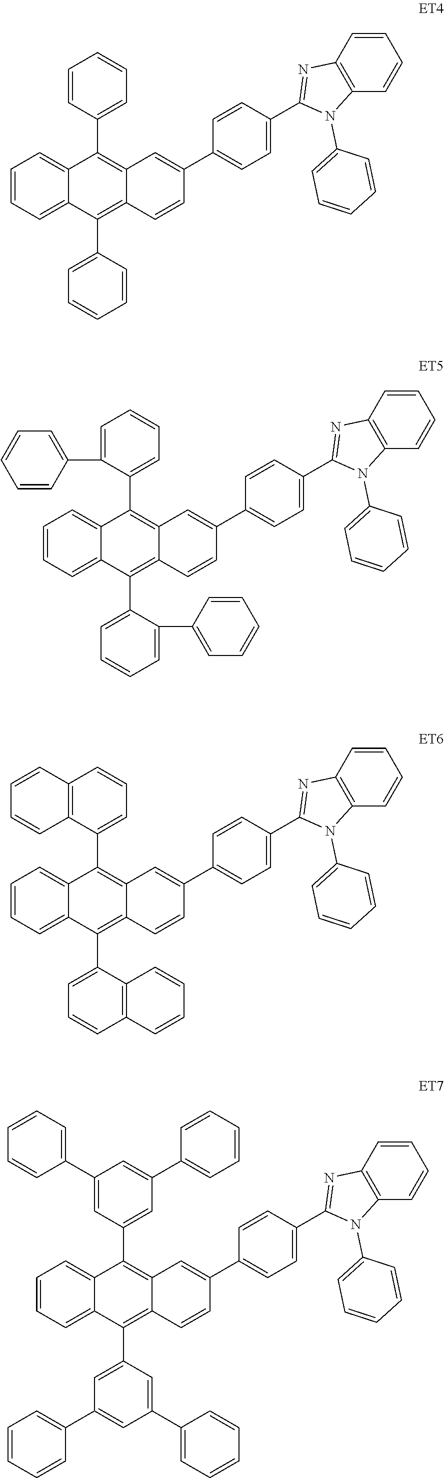 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

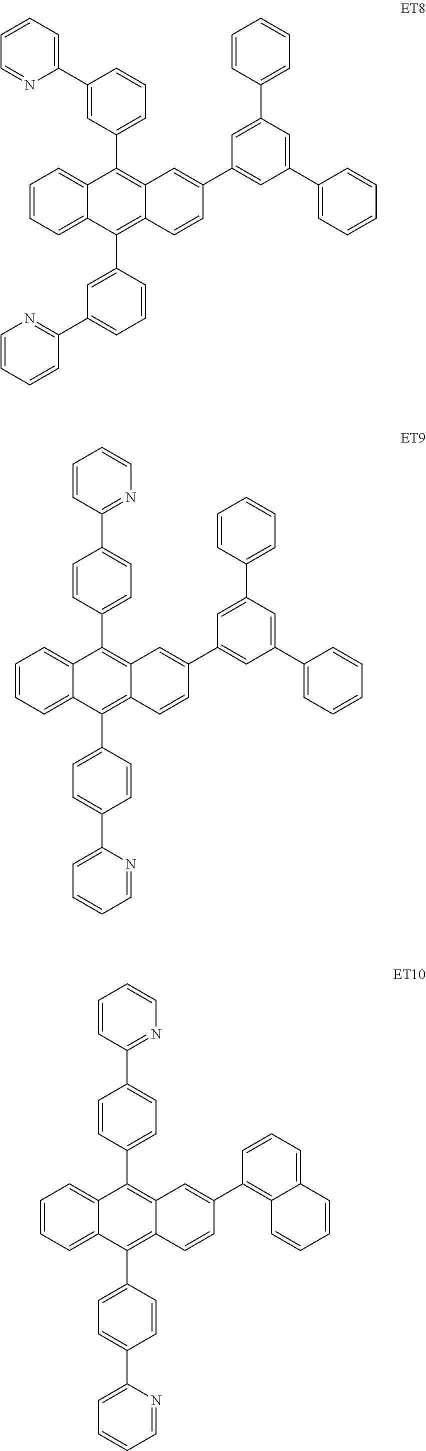 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

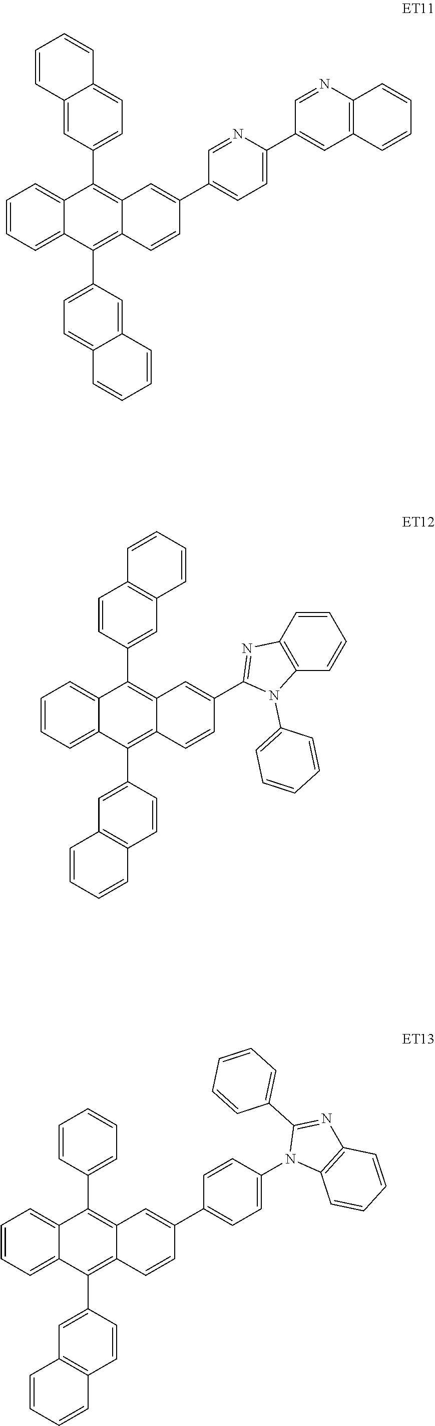 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

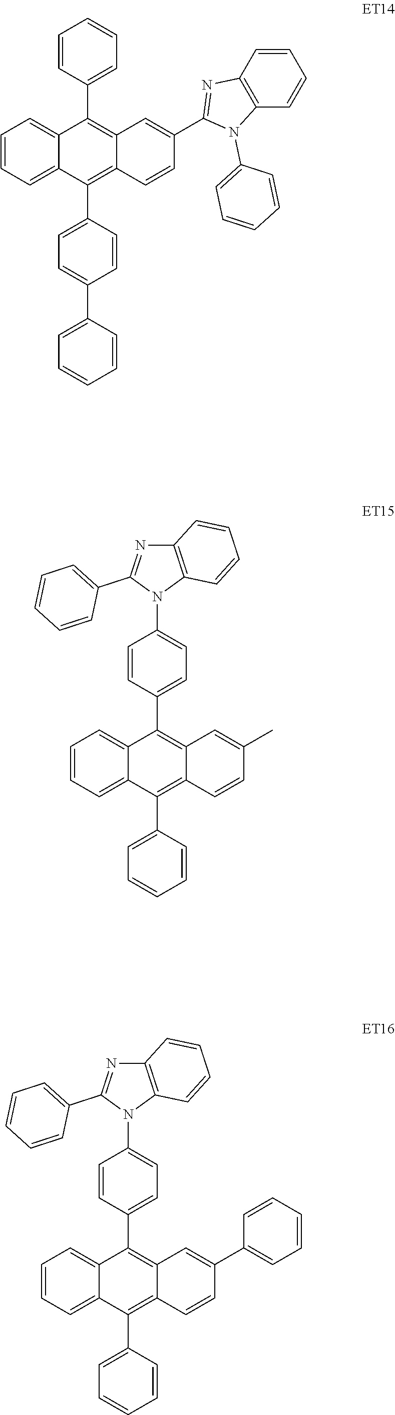 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

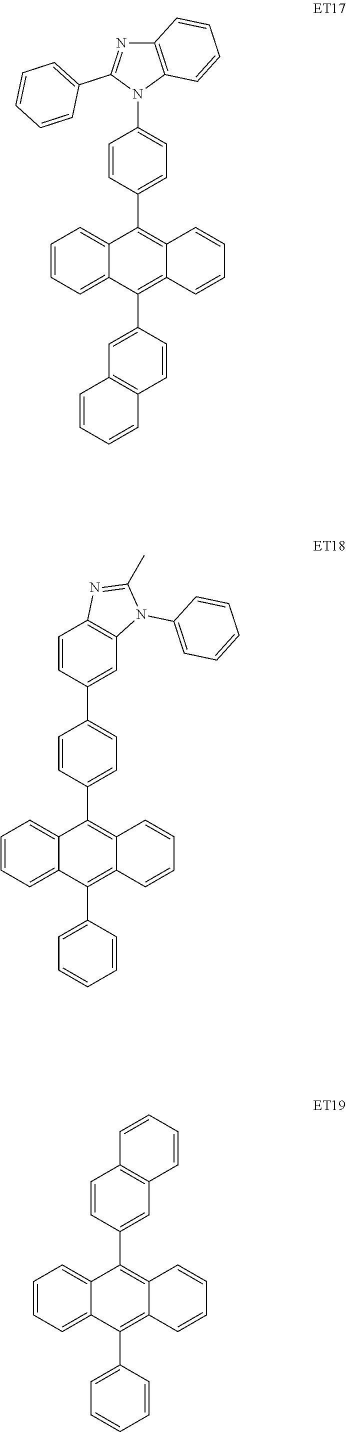

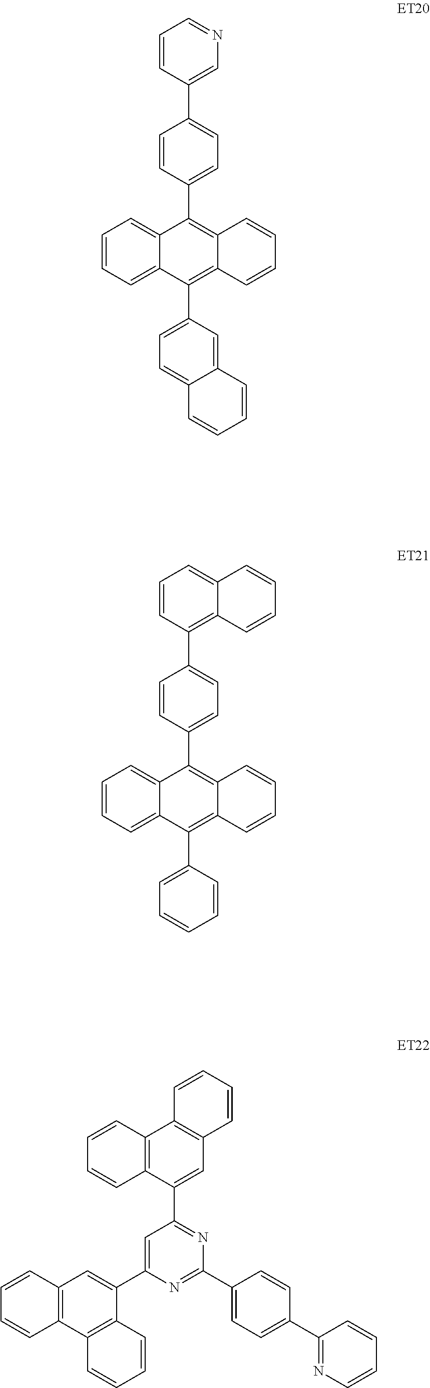

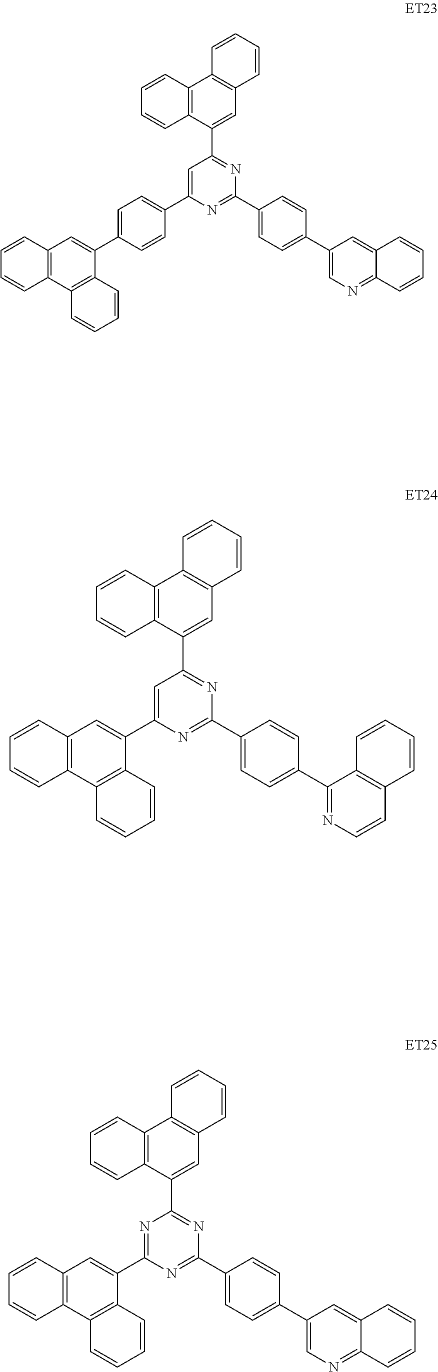 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

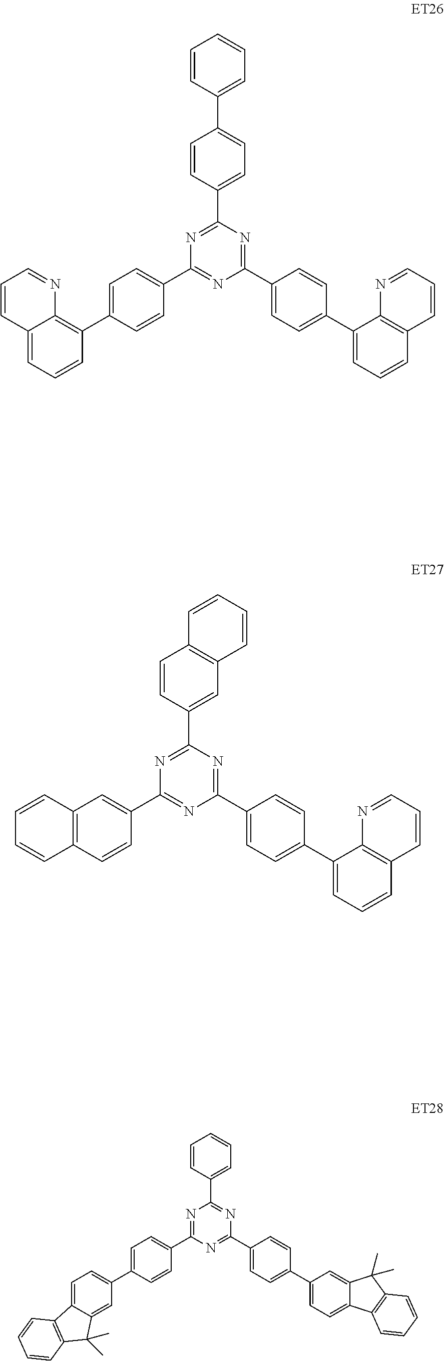 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

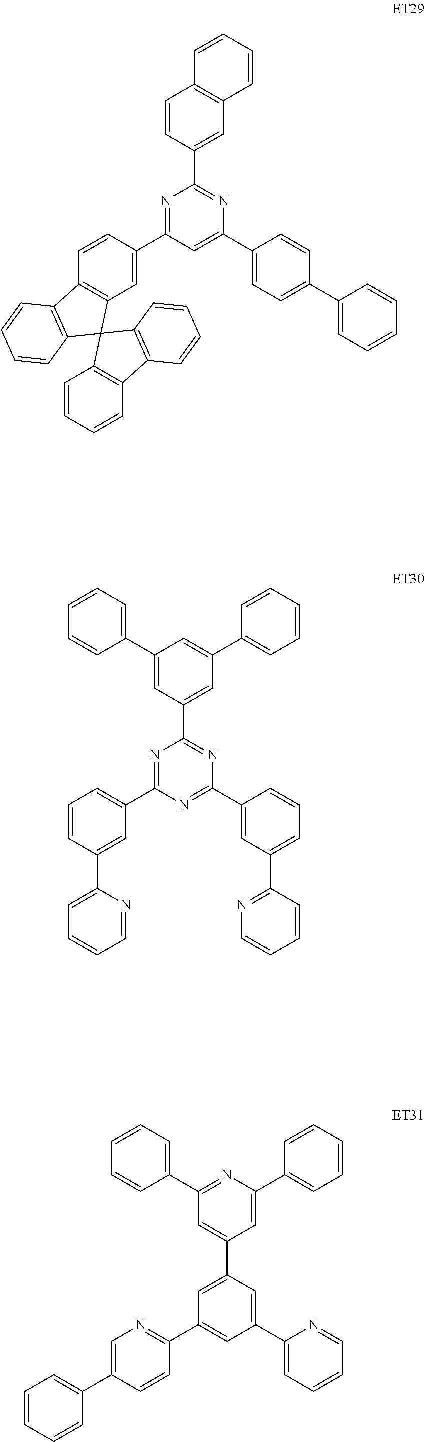 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

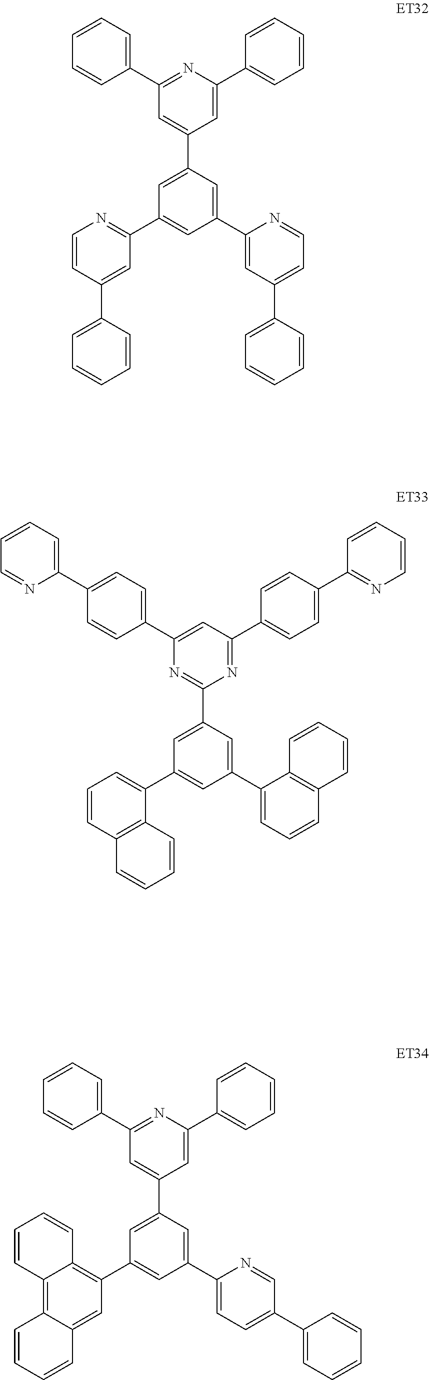 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

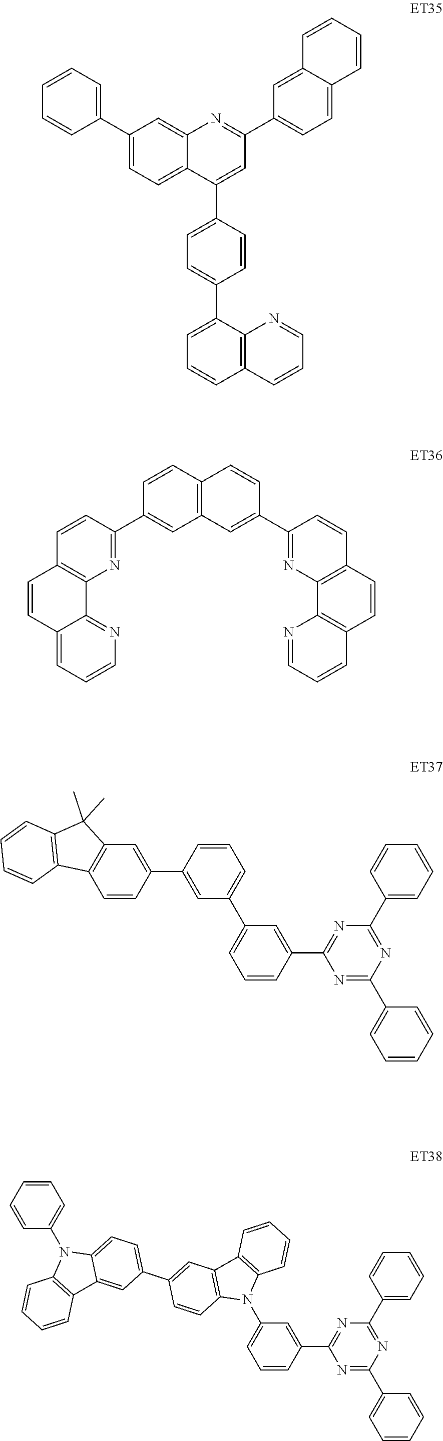 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

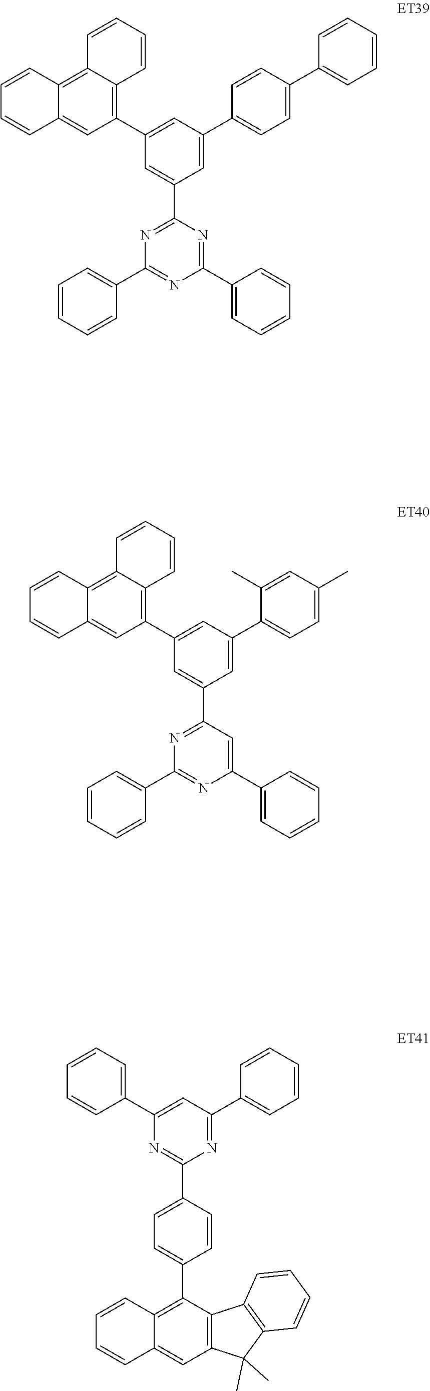 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

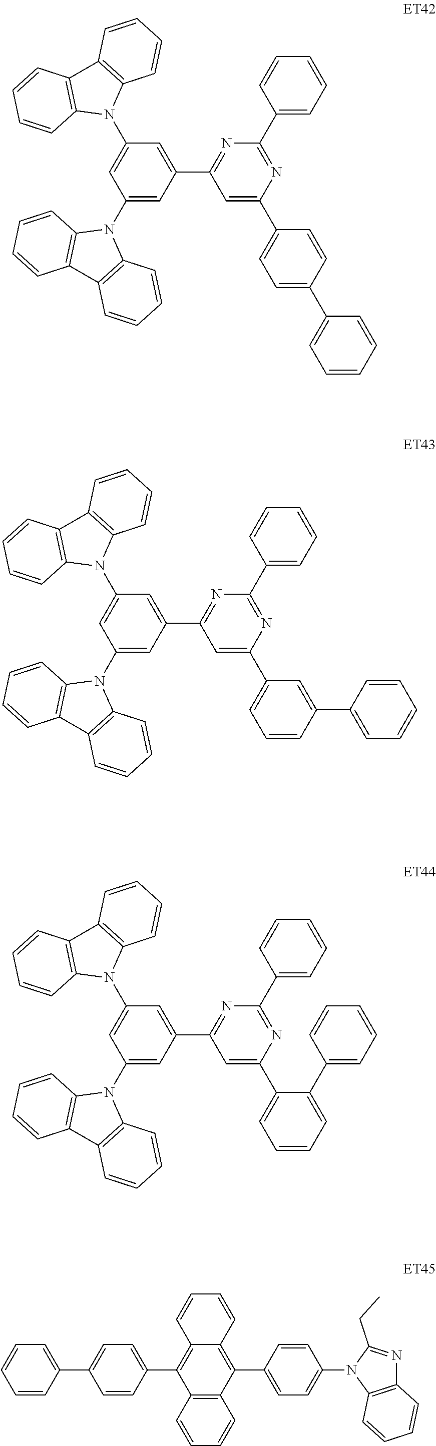 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

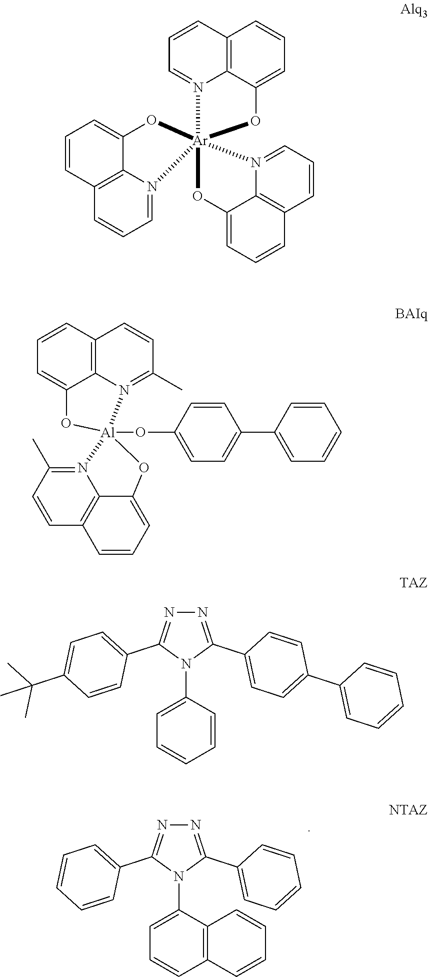

A thickness of the electron transport region may be in a range of about 100 Å to about 5,000 Å. For example, the thickness of the electron transport region may be in a range of about 160 Å to about 4,000 Å. When the electron transport region includes a buffer layer, a hole blocking layer, an electron control layer, an electron transport layer or any combination thereof, a thickness of the buffer layer, the hole blocking layer, or the electron control layer may each independently be in a range of about 20 Å to about 1,000 Å, and a thickness of the electron transport layer may be in a range of about 100 Å to about 1,000 Å. For example, the thickness of the buffer layer, the hole blocking layer, or the electron control layer may each independently be in a range of about 30 Å to about 300 Å. For example, the thickness of the electron transport layer may be in a range of about 150 Å to about 500 Å. When the thickness of the buffer layer, hole blocking layer, electron control layer, electron transport layer and/or electron transport region satisfy the aforementioned ranges, satisfactory electron transport characteristics may be obtained without a substantial increase in driving voltage.

The electron transport region (for example, the electron transport layer in the electron transport region) may further include a metal-containing material in addition to the materials described above.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. The ligand coordinated with a metal ion of an alkali metal complex or with a metal ion of an alkaline earth metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzoimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

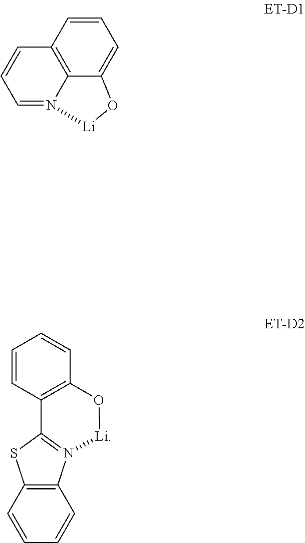

The electron transport region may include an electron injection layer that facilitates electron injection from the second electrode 150. The electron injection layer may contact (e.g., directly contact) the second electrode 150.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound and the rare earth metal-containing compound may include an oxide, a halide (for example, a fluoride, a chloride, a bromide, an iodide, etc.), a telluride the alkali metal, the alkaline earth metal and the rare earth metal, or any combination thereof.

The alkali metal-containing compound may include: an alkali metal oxide such as Li₂O, Cs₂O, K₂O, etc.; an alkali metal halide such as LiF, NaF, CsF, KF, LiI, NaI, CsI, KI, etc.; or any combination thereof. The alkaline earth metal-containing compound may include an alkaline earth metal oxide such as BaO, SrO, CaO, BaₓSr₁₋ₓO (wherein x is a real number satisfying 0<x<1), BaₓCa₁₋ₓO (wherein x is a real number satisfying 0<x<1), etc. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, etc.

The alkali metal complex, the alkaline earth metal complex and the rare earth metal complex may include an alkali metal ion, an alkaline earth metal ion, or a rare earth metal ion as described above; and a ligand bonded to the metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzoimidazole, a hydroxyphenylbenzothiazole, a bipyridine, a phenanthroline, a cyclopentadiene, or any combination thereof).

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof as described above. In an embodiment, the electron injection layer may further include an organic material (for example, a compound represented by the Formula 601).

According to an embodiment, the electron injection layer may consist of an alkali metal-containing compound (for example, an alkali metal halide); or the electron injection layer may consist of an alkali metal-containing compound (for example, an alkali metal halide), and an alkali metal, an alkaline earth metal, a rare earth metal, or any combination thereof. In an embodiment, the electron injection layer may be a KI:Yb co-deposited layer, a RbI:Yb co-deposited layer, a LiF:Yb co-deposited layer, etc.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof may be uniformly or non-uniformly dispersed in the matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer satisfies any of the aforementioned ranges, satisfactory electron injection characteristics may be obtained without a substantial increase in driving voltage.

### [Second Electrode 150]

A second electrode 150 may be disposed on the intermediate layer 130 as described above. The second electrode 150 may be a cathode, which is an electron injection electrode. When the second electrode is a cathode, a material for forming the second electrode 150 may include a material having a low-work function, such as a metal, an alloy, an electrically conductive compound, or any combination thereof.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transflective electrode, a semi-transflective electrode, or a reflective electrode.

The second electrode 150 may have a single-layered structure or a multi-layered structure.

### [Capping Layer]

The light emitting element 1A may include a first capping layer outside the first electrode 110, and/or a second capping layer outside the second electrode 150. In an embodiment, the light-emitting element 1A may have a structure in which the first capping layer, the first electrode 110, the intermediate layer 130, and the second electrode 150 are stacked in this stated order, a structure in which the first electrode 110, the intermediate layer 130, the second electrode 150, and the second capping layer are stacked in this stated order, or a structure in which the first capping layer, the first electrode 110, the intermediate layer 130, the second electrode 150, and the second capping layer are stacked in this stated order.

Light generated in the emission layer of the intermediate layer 130 of the light-emitting element 1A may pass through the first electrode 110, which may be a semi-transflective electrode or a transflective electrode, and through the first capping layer to the outside. Light generated in the emission layer of the intermediate layer 130 of the light-emitting element 1A may pass through the second electrode 150, which may be a semi-transflective electrode or a transflective electrode, and through the second capping layer to the outside.

The first capping layer and second capping layer may each enhance an external luminescence efficiency by the principle of constructive interference. Thereby, the light extraction efficiency of the light-emitting element 1A increases, so that the luminescence efficiency of the light-emitting element 1A may be enhanced.

The first capping layer and the second capping layer may each include a material that has a refractive index greater than or equal to about 1.6 (with respect to a wavelength of about 589 nm).

The first capping layer and the second capping layer may each independently be, a capping layer including a quantum dot, an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, heterocyclic compound and amine group-containing compound may each optionally be substituted with substituents including O, N, S, Se, Si, F, Cl, Br, I, or any combination thereof. According to an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

According to another embodiment, at least one of the first capping layer and the second capping layer may each independently include one of Compounds HT28 to HT33, one of the compounds CP1 to CP6, β-NPB, or any compound thereof:

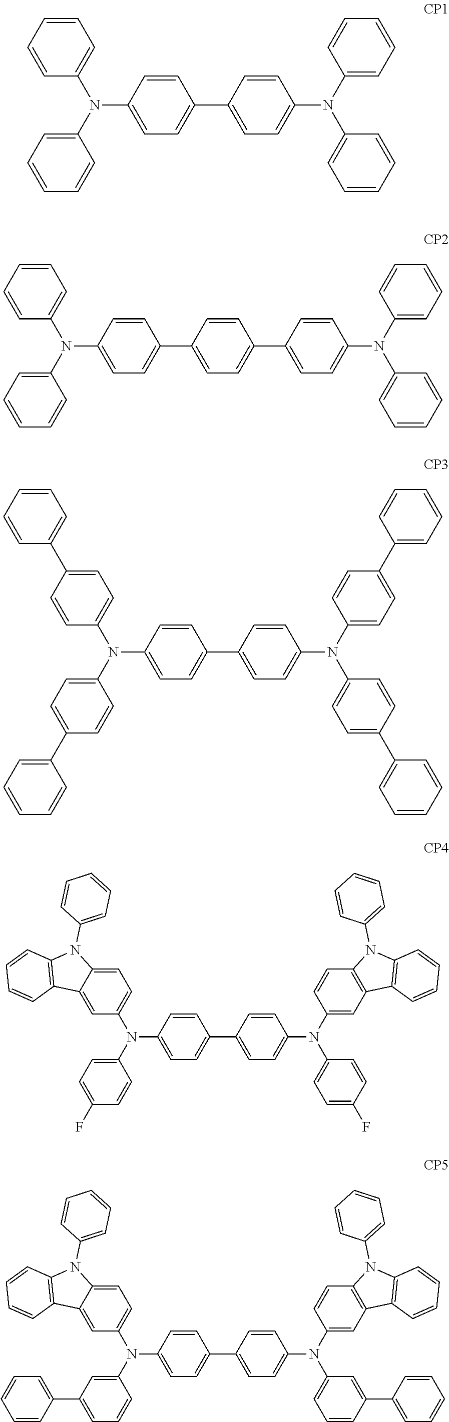 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

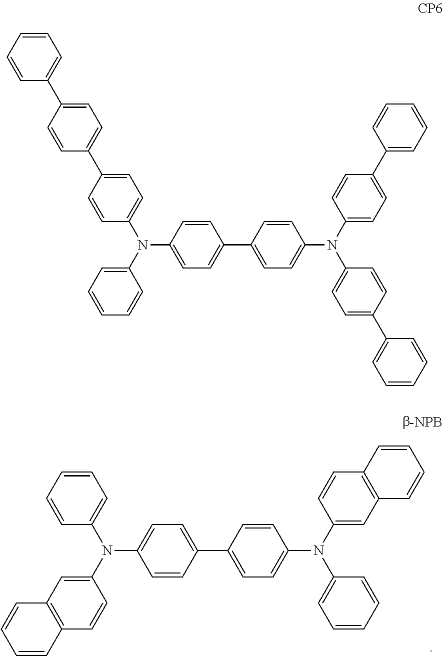 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Film]

The quantum dots may be included in various films. In an embodiment, a film may include the quantum dot. The film may be, for example, an optical member (or means of light control) (for example, a color filter, a color conversion member, a capping layer, a light extraction efficiency enhancing layer, a selective light absorption layer, a polarizing layer, a quantum dot-containing layer, etc.), a light-shielding member (for example, a light reflective layer, a light absorption layer, etc.), a protective member (for example, an insulation layer, a dielectric layer, etc.), etc.

### [Optical Member]

The quantum dot may be used in various optical members. Therefore, according to another embodiment, an optical member may include the quantum dot.

According to an embodiment, the optical member may be a means of light control.

According to another embodiment, the optical member may be a color filter, a color conversion member, a capping layer, a light extraction efficiency enhancement layer, a selective light absorption layer, or a polarization layer.

The optical member may be a color conversion member.

The color conversion member may include a substrate and a pattern layer formed on the substrate.

The substrate may be the substrate of the color conversion member itself, or may be an area in which the color conversion member is disposed among various apparatuses (for example, a display apparatus). The substrate may be glass, silicon (Si), silicon oxide (SiOₓ) or a polymer substrate, and the polymer substrate may be polyethersulfone (PES) or polycarbonate (PC).

The patterned layer may include a quantum dot in the form of a thin-film. For example, the pattern layer may be a quantum dot in a form of a thin film.

The color conversion member including the substrate and pattern layer may further include a partition wall or black matrix formed between each pattern layer. In an embodiment, the color conversion member may further include a color filter to further enhance light conversion efficiency.

The color conversion member may include a red pattern layer that emits red light, a green pattern layer that emits green light, a blue pattern layer that emits blue light, or any combination thereof. The red pattern layer, green pattern layer, and/or blue pattern layer may be implemented by adjusting the components, the composition, and/or the structure of the quantum dot.

According to another embodiment, an apparatus may include the quantum dot (or an optical member including the quantum dot).

The apparatus may further include a light source, and the quantum dot (or optical members including the quantum dots) may be disposed in a path of light emitted from the light source.

The light source may emit blue light, red light, green light or white light. For example, the light source may emit blue light or red light. In an embodiment, light emitted from the light source may be absorbed and converted by the quantum dot.

The light source may be an organic light-emitting element (OLED) or a light-emitting element (LED).

Light emitted from a light source as described above may be photoconverted by the quantum dot while passing through the quantum dot, and light that has a wavelength different from the wavelength of the light emitted from the light source may be emitted by the quantum dot.

For example, the quantum dot may absorb and convert light emitted from the light source to emit light that has a maximum emission wavelength in a range of about 400 nm to about 2500 nm.

### [Electronic Apparatus]

The quantum dot and the light-emitting element including the quantum dot may be included in various electronic apparatuses. For example, an electronic apparatus including the quantum dot and the light-emitting element including the quantum dot may be a light-emitting apparatus, an authentication apparatus, etc.

The electronic apparatus (for example, light-emitting apparatus) may further include, in addition to the light-emitting element, a color filter, a color conversion layer, or a color filter and a color conversion layer. The color filter and/or color conversion layer may be disposed on at least one propagation direction of light emitted from the light-emitting element. For example, the light emitted from the light-emitting element may be red light, blue light, or white light. The light-emitting element may be the same as described above. According to an embodiment, the color conversion layer may include a quantum dot. The quantum dot may be, for example, a quantum dot as disclosed herein.

The electronic apparatus may include a first substrate. The first substrate may include subpixels, the color filter may include color filter regions respectively corresponding to the subpixels, and the color conversion layer may include color conversion regions respectively corresponding to the subpixels.

A pixel defining layer may be disposed between the subpixels, defining each subpixel.

The color filter may further include color filter regions and light-shielding patterns disposed between the color filter regions, the color conversion layer may further include color conversion regions and light-shielding patterns disposed between the color conversion regions.

The color filter regions (or the color conversion regions) may include, a first region emitting first-colored light; a second region emitting second-colored light; and/or a 3rd region emitting 3rd-colored light, wherein the first-colored light, second-colored light, and/or 3rd-colored light may have different maximum emission wavelengths from one another. For example, the first-colored light may be a red light, the second-colored light may be a green light, and the 3rd-colored light may be a blue light. In an embodiment, the color filter regions (or the color conversion regions) may include quantum dots. In an embodiment, the first region may include a red quantum dot, the second region may include a green quantum dot, and the 3rd region may not include a quantum dot. The quantum dot may be the same as described herein. The first region, the second region, and/or the 3rd region may each further include a scatterer.

In an embodiment, the light-emitting element may emit a first light, and the first region may absorb the first light and emit a first-first colored light, the second region may absorb the first light and emit a second-first colored light, and the third region may absorb the first light and emit a third-first colored light. In an embodiment, the first-first colored light, the second-first colored light, and the third-first colored light may have different maximum emission wavelengths. For example, the first light may be a blue light, the first-1-colored light may be a red light, the second-first colored light may be a green light, and the third-first colored light may be a blue light.

The electronic apparatus may further include a thin-film transistor in addition to the light-emitting element as described above. The thin-film transistor may include a source electrode, a drain electrode, and an active layer, and either the source electrode or the drain electrode may be electrically connected to either the first electrode or the second electrode of the light-emitting element.

The thin-film transistor may further include a gate electrode, a gate insulating layer, etc.

The active layer may include crystalline silicon, amorphous silicon, an organic semiconductor, an oxide semiconductor, etc.

The electronic apparatus may further include a sealing portion that seals the light-emitting element. The sealing portion may be disposed between the color filter and/or the color conversion layer and the light-emitting element. The sealing portion may allow light from the light-emitting element to be extracted externally and may block external air and/or moisture from infiltrating into the light-emitting element. The sealing portion may be a sealing substrate including a transparent glass substrate or a plastic substrate. The sealing portion may be a thin-film encapsulation layer including one or more organic layers and/or inorganic layers. When the sealing portion is a thin-film encapsulation layer, the electronic apparatus may be flexible.

On the sealing portion, in addition to the color filter and/or color conversion layer, various functional layers may be further included, depending on a use of the electronic apparatus. Examples of a functional layer may include a touch screen layer, a polarizing layer, etc. The touch screen layer may be a pressure-sensitive touch screen layer, a capacitive touch screen layer, or an infrared touch screen layer. The authentication apparatus may be, for example, a biometric authentication apparatus that authenticates an individual using biometric information (for example, fingertips, pupils, etc.).

The authentication apparatus may further include a means for collecting biometric information in addition to the light-emitting element as described above.

The electronic apparatus may be applied to various displays, light sources, lighting apparatus, personal computers (for example, mobile personal computers), mobile phones, digital cameras, electronic notepads, electronic dictionaries, electronic game consoles, medical devices (for example, electronic thermometers, blood pressure monitors, blood glucose meters, pulse measurement apparatuses, pulse wave measurement apparatuses, electrocardiograph display apparatuses, ultrasound diagnostic apparatuses, endoscopic display apparatuses), fish finders, various measurement instruments, gauges (for example, instruments for vehicles, aircraft, or ships), projectors, etc.

### [Electronic Devices]

The quantum dot and the light-emitting element including the quantum dot may be included in various electronic devices.

For example, an electronic device including the light-emitting element may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

Since the light-emitting element has excellent luminescence efficiency, long-life effect, etc., the electronic device including the light-emitting element may have characteristics such as high brightness, high resolution, and low power consumption, etc.

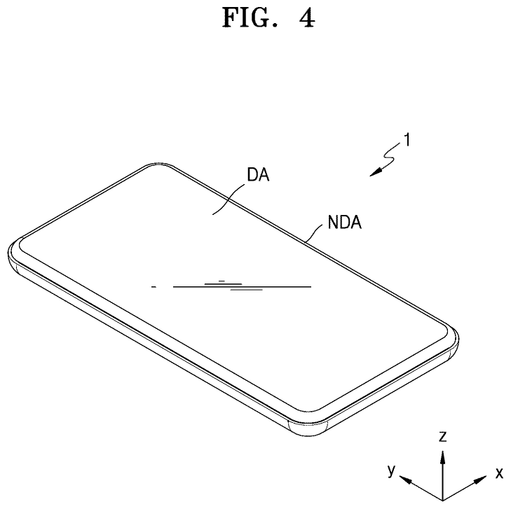

### [Description of FIG. 4]

FIG. 4 is a schematic perspective view of an electronic device 1 including a light-emitting element according to an embodiment.

The electronic device 1, which may be an apparatus that displays a moving image or still image, may not only be a mobile phone, a smart phone, a tablet computer, a mobile communication terminal, an electronic notebook, an e-book, a portable multimedia player (PMP), a navigation device, an ultra-mobile personal computer (UMPC), or other portable electronic devices, but may also be various products or parts thereof, such as a television, a laptop, a monitor, a billboard, or an Internet of Things (IOT), etc.

In an embodiment, the electronic device 1 may be a wearable device such as a smart watch, a watch phone, an eyewear display, or a head mounted display (HMD), or a part thereof. However, embodiments are not limited thereto.

In an embodiment, examples of, the electronic device 1 may include a dashboard of a vehicle, a center information display (CID) disposed on a center fascia or dashboard of a vehicle, a room mirror display that replaces a side mirror of a vehicle, an entertainment display disposed on a rear seat of a vehicle or a display disposed on the back of the front seat, a head-up display (HUD) installed at the front of a vehicle or projected on a front window glass, or a computer-generated hologram augmented reality head-up display (CGH AR HUD). For convenience of explanation, FIG. 4 illustrates an embodiment where the electronic device 1 is a smart phone.

The electronic device 1 may include a display area DA and a non-display area NDA outside the display area DA. The display apparatus may implement an image through a two-dimensional array of pixels that are arranged in the display area DA.

The non-display area NDA may be an area that does not display an image, and may surround (e.g., completely surround) the display area DA. A driver, which provides electrical signals or power to display devices disposed in the display area DA, may be disposed in the non-display area NDA. Pads, which are areas where electronic elements or printed circuit boards, etc. may be electrically connected, may be disposed in the non-display area NDA.

The electronic device 1 may have different lengths in an x-axis direction and in a y-axis direction. For example, as shown in FIG. 4, a length in the x-axis direction may be shorter than a length in the y-axis direction. In another example, a length in the x-axis direction and a length in the y-axis direction may be the same. In another example, a length in the x-axis direction may be longer than a length in the y-axis direction.

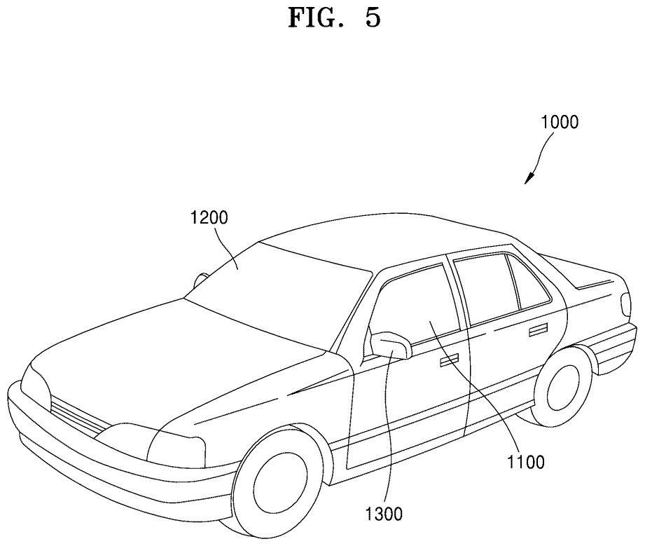

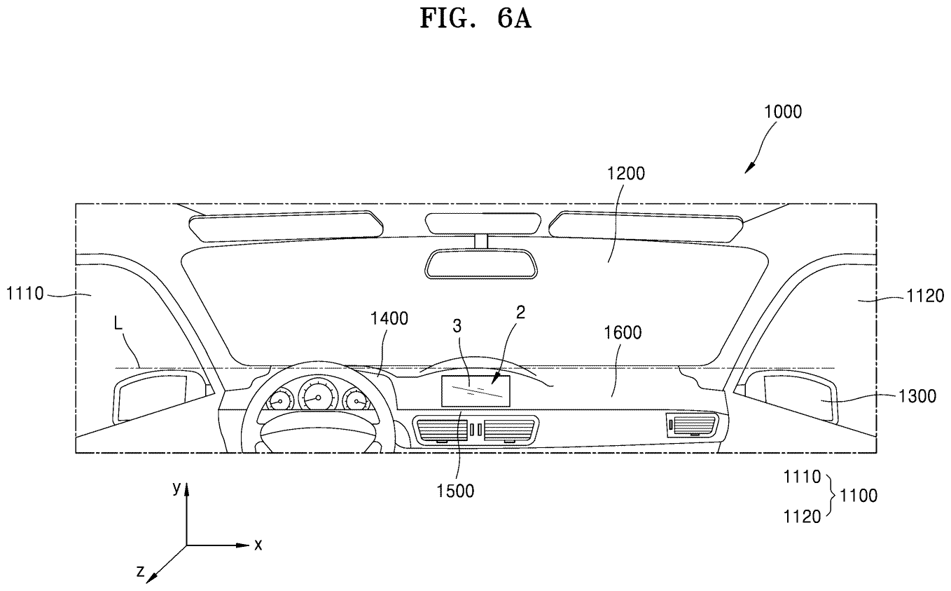

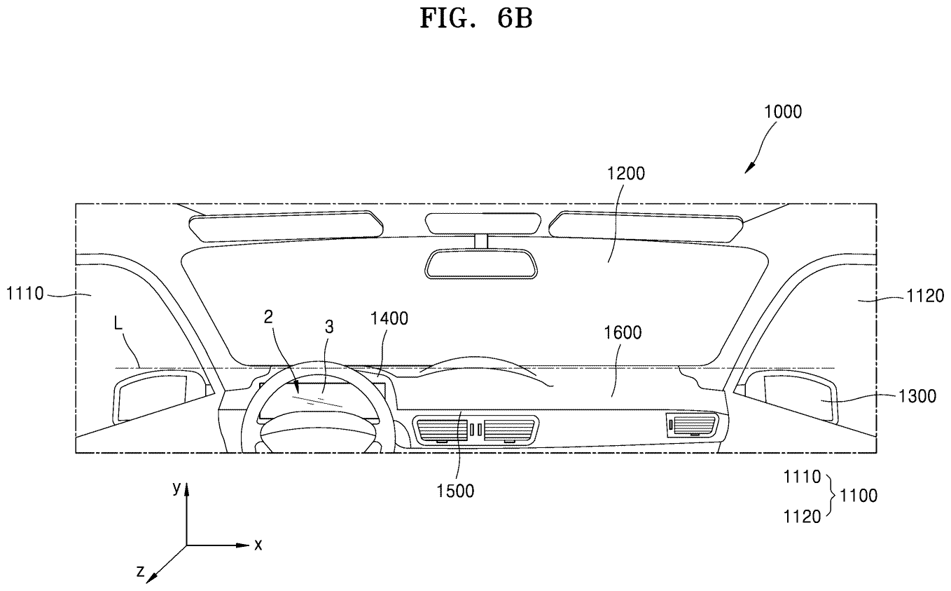

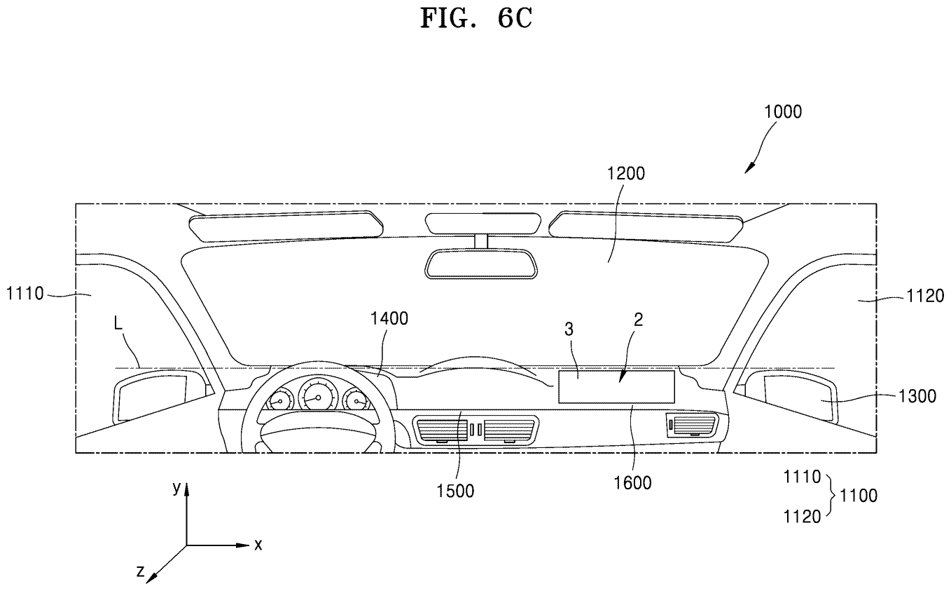

### [Description of FIG. 5 and FIG. 6A to FIG. 6C]

FIG. 5 is a schematic perspective view of an exterior of a vehicle 1000 as an electronic device including a light-emitting element according to an embodiment. FIG. 6A to FIG. 6C are each a schematic diagram of an interior of the vehicle 1000 according to embodiments.

Referring to FIG. 5, FIG. 6A, FIG. 6B, and FIG. 6C, embodiments of the vehicle 1000 may include various apparatuses for moving a subject to be transported, such as a person, an object, an animal, etc., from a starting point to a destination. Examples of a vehicle 1000 may include a vehicle running on a road or a rail, a ship moving on a sea or a river, and an airplane flying in the sky utilizing the action of the air.

The vehicle 1000 may drive on a road or a track. The vehicle 1000 may move in a selectable direction according to the rotation of at least one wheel. Examples of the vehicle 1000 may include a three-wheeled or four-wheeled automobile, construction machinery, a two-wheeled automobile, a motorized apparatus, a bicycle, and a train running on a track.

The vehicle 1000 may include a body that has an interior and an exterior, and a chassis that is a portion excluding the body in which mechanical apparatuses necessary for driving are installed. The body may include a front panel, a bonnet, a roof panel, a rear panel, a trunk, and pillars provided at boundaries between doors.

The chassis of the vehicle 1000 may include a power generation apparatus, a power transmission apparatus, a driving apparatus, a steering apparatus, a braking apparatus, a suspension apparatus, a transmission apparatus, a fuel apparatus, front, rear, left, and right wheels, etc.

The vehicle 1000 may include a side window glass 1100, a front window glass 1200, a side mirror 1300, a cluster 1400, a center fascia 1500, a passenger dashboard 1600, and a display apparatus 2.

The side window glass 1100 and the front window glass 1200 may be partitioned by a pillar disposed between the side window glass 1100 and front window glass 1200.

The side window glass 1100 may be installed on a side of the vehicle 1000. In an embodiment, the side window glass 1100 may be installed on a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be disposed adjacent to the cluster 1400, and the second side window glass 1120 may be disposed adjacent to the passenger dashboard 1600.

In an embodiment, the side window glasses 1100 may be spaced apart from each other in an x direction or a −x direction. For example, the first side window glass 1110 and the second side window glass 1120 may be spaced apart from each other in the x direction or the −x direction. For example, a virtual straight line L connecting the side window glasses 1100 may extend in the x direction or the −x direction. For example, a virtual straight line L connecting the first side window glass 1110 and the second side window glass 1120 may extend in the x direction or the −x direction.

The front window glass 1200 may be installed at the front of the vehicle 1000. The front window glass 1200 may be disposed between the side window glasses 1100 facing each other.

The side mirror 1300 may provide a rearward field of view of the vehicle 1000. The side mirror 1300 may be installed on the exterior of the vehicle body. In an embodiment, multiple side mirrors 1300 may be provided. For example, one of the side mirrors 1300 may be disposed outside of the first side window glass 1110, and another one of the side mirrors 1300 may be disposed outside of the second side window glass 1120.

The cluster 1400 may be located in front of a steering wheel. The cluster 1400 may include a tachometer, a speedometer, a coolant temperature gauge, a fuel gauge, a turn signal indicator, a high beam indicator, a warning light, a seat belt warning light, an odometer, a trip meter, an automatic transmission selector indicator, a door open warning light, an engine oil warning light, and/or a low fuel warning light.

The center fascia 1500 may include a control panel on which buttons for adjusting an audio apparatus, an air conditioning apparatus, and a seat heater are disposed. The center fascia 1500 may be disposed on a side of the cluster 1400.

The passenger dashboard 1600 may be spaced apart from the cluster 1400, and the center fascia 1500 may be between the cluster 1400 and the passenger seat dashboard 1600. In an embodiment, the cluster 1400 may be disposed corresponding to the driver's seat (not shown), and the passenger dashboard 1600 may be disposed corresponding to the passenger seat (not shown). In an embodiment, the cluster 1400 may be adjacent to the first side window glass 1110, and the passenger dashboard 1600 may be adjacent to the second side window glass 1120.

In an embodiment, the display apparatus 2 may include a display panel 3, wherein the display panel 3 may display an image. The display apparatus 2 may be disposed inside the vehicle 1000. In an embodiment, the display apparatus 2 may be disposed between side window glasses 1100 facing each other. The display apparatus 2 may be disposed on at least one of the cluster 1400, the center fascia 1500, and the passenger dashboard 1600.

The display apparatus 2 may include an organic light emitting display, an inorganic light emitting display, a quantum dot display, etc. Hereinafter, an organic light emitting display including a light-emitting element according to an embodiment will be described as an example of a display apparatus 2. However, various types of display apparatuses as described above may be used in the embodiments.

Referring to FIG. 6A, the display apparatus 2 may be disposed on the center fascia 1500. In an embodiment, the display apparatus 2 may display navigation information. In an embodiment, the display apparatus 2 may display information regarding audio, video, or vehicle settings.

Referring to FIG. 6b, the display device 2 may be disposed on the cluster 1400. In an embodiment, the cluster 1400 may display driving information, etc. through the display apparatus 2. For example, the cluster 1400 may digitally implement driving information and the like. A digital cluster 1400 may display vehicle information and driving information as images. For example, a needle and gauge of the tachometer and various warning lights or icons may be displayed through digital signals.

Referring to FIG. 6C, the display apparatus 2 may be disposed on the passenger dashboard 1600. The display apparatus 2 may be embedded in the passenger dashboard 1600 or located on the passenger dashboard 1600. In an embodiment, a display apparatus 2 disposed on the passenger dashboard 1600 may display an image that is related to information displayed on the cluster 1400 and/or information displayed on the center fascia 1500. In another embodiment, the display apparatus 2 disposed on the passenger dashboard 1600 may display information that is different from the information displayed on the cluster 1400 and/or the information displayed on the center fascia 1500.

### [Method of Preparation]

Layers included in the hole transport region, layers included in the emission layer and layers included in the electron transport region may be formed in a selected region using various methods, such as vacuum deposition, spin coating, casting, Langmuir-Blodgett (LB), inkjet printing, laser printing, and laser induced thermal imaging (LITI), etc.

When the layers included in the hole transport region, the emission layer, and the layers included in the electron transport region are each formed by vacuum deposition, the deposition conditions may be selected. For example, the deposition may be performed at a deposition temperature range in a range of about 100° C. to about 500° C., a vacuum degree in a range of about 10⁻⁸ torr to about 10⁻³ torr, and a deposition rate in a range of about 0.01 Å/sec to about 100 Å/sec, depending on a material to be included in the layer to be formed and the structure of the layer to be formed.

### Definitions of Terms

In the specification, a C₃-C₆₀ carbocyclic group may be a cyclic group that has 3 to 60 carbon atoms and consisting of carbon atoms as the only ring-forming atoms, and a C₁-C₆₀ heterocyclic group may be a cyclic group that has 1 to 60 carbon atoms that further includes at least one heteroatom as a ring-forming atom, in addition to carbon atoms. The C₃-C₆₀ carbocyclic group and C₁-C₆₀ heterocyclic group may each be a monocyclic group consisting of one ring or a polycyclic group in which two or more rings are condensed together. For example, the number of ring-forming atoms in a C₁-C₆₀ heterocyclic group may be from 3 to 61.

In the specification, the term “cyclic group” may be a C₃-C₆₀ carbocyclic group or a C₁-C₆₀ heterocyclic group.

In the specification, a π electron-rich C₃-C₆₀ cyclic group may be a cyclic group that has 3 to 60 carbon atoms and may not include *—N═*′ as a ring-forming moiety, and a π electron-deficient nitrogen-containing C₁-C₆₀ cyclic group may be a heterocyclic group that has 1 to 60 carbon atoms and may include *—N═*′ as a ring-forming moiety.

In embodiments,
a C₃-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which two or more T2 groups are condensed with each other, or a group in which one or more T2 groups and one or more T1 groups are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
a π electron-rich C₃-C₆₀ cyclic group may be a T1 group, a group in which two or more T1 groups are condensed with each other, a T3 group, a group in which two or more T3 groups are condensed with each other, or a group in which one or more T3 groups and one or more T1 groups are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, (indenocarbazole group, indolocarbazole group, benzofurocarbazole group, benzothienocarbazole group, benzosilolocarbazole group, benzoindolocarbazole group, benzocarbazole group, benzonaphthofuran group, benzonaphthothiophene group, benzonaphthosilole group, benzofurodibenzofuran group, benzofurodibenzothiophene group, benzothienodibenzothiophene group, etc.), and
a π electron-deficient nitrogen-containing C₁-C₆₀ cyclic group may be a group in which two or more T4 groups are condensed with each other, a group in which one or more T4 groups and one or more T1 groups are condensed with each other, a group in which one or more T4 groups and one or more T3 groups are condensed with each other, or a group in which one or more T4 groups, one or more T1 groups, and one or more T3 groups are condensed with each other (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.).

A T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or, bicyclo[2.2.1]heptane) group, a norbornene group, a bicyclo[1.1.1]pentane group, a bicyclo[2.1.1]hexane group, a bicyclo[2.2.2]octane group, or a benzene group,
a T₂ group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
a T3 group may be a furan group, a thiophene group, a 1H-pyrrole group, a silole group, or a borole group, and
a T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group or a tetrazine group.

As used herein, the terms “cyclic group,” “C₃-C₆₀ carbocyclic group,” “C₁-C₆₀ heterocyclic group,” “π electron-rich C₃-C₆₀ cyclic group” and “π electron-deficient nitrogen-containing C₁-C₆₀ cyclic group” may, depending on the structure of the formula in which the term is used, each be a group condensed to any cyclic group, a monovalent group, or a polyvalent group (for example, a divalent group, a trivalent group, a tetravalent group, etc.). For example, a “benzene group” may be a benzo group, a phenyl group, a phenylene group, etc., which may be readily understood by those skilled in the art depending on the structure of the formula including the “benzene group”.

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

As used herein, the term “C₁-C₆₀ alkyl group” may be a linear or branched monovalent aliphatic hydrocarbon group that has 1 to 60 carbon atoms, and examples of which may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, etc. As used herein, the term “C₁-C₆₀ alkylene group” may be a divalent group that has a same structure as the C₁-C₆₀ alkyl group.

As used herein, the term “C₂-C₆₀ alkenyl group” may be a monovalent hydrocarbon group including one or more carbon-carbon double bonds in the middle or at terminus of a C₂-C₆₀ alkyl group, and examples thereof may include an ethenyl group, a propenyl group, a butenyl group, etc. As used herein, the term “C₂-C₆₀ alkenylene group” may be a divalent group that has a same structure as the C₂-C₆₀ alkenyl group.

As used herein, the term “C₂-C₆₀ alkynyl group” may be a monovalent hydrocarbon group including one or more carbon-carbon triple bonds in the middle or at a terminus of a C₂-C₆₀ alkyl group, and examples thereof may include an ethynyl group, a propynyl group, etc. As used herein, the term “C₂-C₆₀ alkynylene group” may be a divalent group that has a same structure as the C₂-C₆₀ alkynyl group.

As used herein, the term “C₁-C₆₀ alkoxy group” may be a monovalent group that has the formula of —O(A₁₀₁) (wherein A₁₁ may be a C₁-C₆₀ alkyl group), and examples thereof may include a methoxy group, an ethoxy group, an isopropyloxy group, etc.

As used herein, the term “C₃-C₁₀ cycloalkyl group” may be a monovalent saturated hydrocarbon cyclic group that has 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or, a bicyclo[2.2.1]heptyl group), a bicyclo[1.1.1]pentyl group, a bicyclo[2.1.1]hexyl group, a bicyclo[2.2.2]octyl group, etc. As used herein, the term “C₃-C₁₀ cycloalkylene group” may be a divalent group that has a same structure as the C₃-C₁₀ cycloalkyl group.

As used herein, the term “C₁-C₁₀ heterocycloalkyl group” may be a monovalent cyclic group that has 1 to 10 carbon atoms and further includes at least one heteroatom as a ring-forming atom in addition to carbon atoms, and examples thereof may include a 1,2,3,4-oxatriazolidinyl group, a tetrahydrofuranyl group, a tetrahydrothiophenyl group, etc. As used herein, the term “C₁-C₁₀ heterocycloalkylene group” may be a divalent group that has a same structure as the C₁-C₁₀ heterocycloalkyl group.

As used herein, the term “C₃-C₁₀ cycloalkenyl group” may be a monovalent cyclic group that has 3 to 10 carbon atoms, with at least one carbon-carbon double bond in the cyclic structure thereof, and has no aromaticity, and examples thereof may include a cyclopentenyl group, a cyclohexenyl group, a cycloheptenyl group, etc. As used herein, the term “C₃-C₁₀ cycloalkenylene group” may be a divalent group that has a same structure as the C₃-C₁₀ cycloalkenyl group.

As used herein, the term “C₁-C₁₀ heterocycloalkenyl group” may be a monovalent cyclic group that has 1 to 10 carbon atoms, which further includes at least one heteroatom as a ring-forming atom in addition to carbon atoms, and has at least one double bond within the cyclic structure thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, etc. As used herein, the term “C₁-C₁₀ heterocycloalkenylene group” may be a divalent group that has a same structure as the C₁-C₁₀ heterocycloalkenyl group.

As used herein, the term “C₆-C₆₀ aryl group” may be a monovalent group that has a carbocyclic aromatic system which has 6 to 60 carbon atoms, and the term “C₆-C₆₀ arylene group” may be a divalent group that has a carbocyclic aromatic system which has 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, etc. When the C₆-C₆₀ aryl group and C₆-C₆₀ arylene group include two or more rings, the respective two or more rings may be condensed with each other.

As used herein, the term “C₁-C₆₀ heteroaryl group” may be a monovalent group which, in addition to carbon atoms, further includes at least one heteroatom as a ring-forming atom and has a heterocyclic aromatic system that has 1 to 60 carbon atoms. The term “C₁-C₆₀ heteroarylene group” may be a divalent group which, in addition to carbon atoms, further includes at least one heteroatom as a ring-forming atom and has a heterocyclic aromatic system that has 1 to 60 carbon atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, etc. When the C₁-C₆₀ heteroaryl group and the C₁-C₆₀ heteroarylene group include two or more rings, the respective two or more rings may be condensed with each other.

As used herein, the term “monovalent non-aromatic condensed polycyclic group” may be a monovalent group (for example, that has 8 to 60 carbon atoms) in which two or more rings are condensed with each other, includes only carbon as a ring-forming atom, and has no aromaticity in its molecular structure when considered as a whole. Examples of a monovalent non-aromatic condensed polycyclic group may include an indenyl group, a fluorenyl group, a spiro-bifluorenyl group, a benzofluorenyl group, an indenophenanthrenyl group, an indenoanthracenyl group, etc. As used herein, the term “divalent non-aromatic condensed polycyclic group” may be a divalent group that has a same structure as the monovalent non-aromatic condensed polycyclic group.

As used herein, the term “monovalent non-aromatic condensed heteropolycyclic group” may be a monovalent group (for example, that has 1 to 60 carbon atoms) in which two or more rings are condensed with each other, which further includes at least one heteroatom as a ring-forming atom in addition to a carbon atom, and has no aromaticity in its molecular structure when considered as a whole. Examples of a non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzoimidazolyl group, a benzooxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, etc. As used herein, the term “divalent non-aromatic condensed heteropolycyclic group” may be a divalent group that has a same structure as the monovalent non-aromatic condensed heteropolycyclic group.

As used herein, the term “C₆-C₆₀ aryloxy group” may be a group represented by —O(A₁₀₂) (wherein A₁₀₂ may be a C₆-C₆₀ aryl group), and the term “C₆-C₆₀ arylthio group” may be a group represented by —S(A₁₀₃) (wherein A₁₀₃ may be a C₆-C₆₀ aryl group).

As used herein, the term “C₇-C₆₀ arylalkyl group” may be a group represented by -(A₁₀₄)(A₁₀₅) (wherein A₁₀₄ may be a C₁-C₅₄ alkylene group and A₁₀₅ may be a C₆-C₅₉ aryl group), and as used herein, the term “C₂-C₆₀ heteroarylalkyl group” may be a group represented by -(A₁₀₆)(A₁₀₇) (wherein A₁₀₆ may be a C₁-C₅₉ alkylene group and A₁₀₇ may be a C₁-C₅₉ heteroaryl group).

In the specification, the term “R₁₀ₐ” may be:
deuterium (-D), —F, —CI, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each substituted or unsubstituted with deuterium, —F, —CI, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₃₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each substituted or unsubstituted with deuterium, —F, a cyano group, a C₁-C₆₀ alkyl group, a C₁-C₆₀ alkoxy group, a phenyl group, a biphenyl group, or any combination thereof.

As used herein, a heteroatom may be any atom other than a carbon atom or a hydrogen atom. Examples of a heteroatom may include O, S, N, P, Si, B, Ge, Se, or any combination thereof.

As used herein, examples of a transition metal may include hafnium (Hf), tantalum (Ta), tungsten (W), rhenium (Re), osmium (Os), iridium (Ir), platinum (Pt), and gold (Au), etc.

As used herein, the term “Ph” refers to a phenyl group, the term “Me” refers to a methyl group, the term “Et” refers to an ethyl group, the terms “tert-Bu” and “But” each refer to a tert-butyl group, and “OMe” refers to a methoxy group.

As used herein, the term “biphenyl group” may be a “phenyl group substituted with a phenyl group”. The term “biphenyl group” may be a “substituted phenyl group” having a “C₆-C₆₀ aryl group”.

As used herein, the term “terphenyl group” may be a “phenyl group substituted with a biphenyl group”. The term “terphenyl group” may be a “substituted phenyl group” of which a substituent is a “C₆-C₆₀ aryl group substituted with a C₆-C₆₀ aryl group”.

As used herein, the symbols * and *′, unless otherwise defined, each refer to a binding site with an adjacent atom in a corresponding formula or moiety.

In the specification, the terms “x-axis,” “y-axis,” and “z-axis” are not limited to three axes in an orthogonal coordinate system (for example, a Cartesian coordinate system) and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, the compound and the light-emitting element according to an embodiment will be described in more detail with reference to Examples and Comparative Examples. In the Synthesis Examples below, the expression “B was used instead of A,” may be interpreted to mean that the molar equivalents of A and B are the same.

### Examples and Comparative Examples

### Example: Preparation of CuInGaS₂/ZnS Quantum Dot

### (Synthesis of CuInGaS₂ Core)

In a 300-ml flask, 200 ml of a solvent of oleylamine and 1-octadecene (volume ratio=1:1) were added, followed by 1.5 mmol of CuBr3, 1.0 mmol of GaBr3, and 4.0 mmol of InBr₃, and stirred at 100° C. for 60 minutes. 5 mmol of a sulfur precursor (S-oleylamine) was added and reacted for 10 minutes, the temperature was raised to 300° C. over 10 minutes, and the reaction was terminated by cooling the temperature to room temperature, thus preparing a quantum dot core.

### (Synthesis of ZnS Shell)

### (Preparation of Sulfur-Containing Precursor)

Oleylamine was degassed at 120° C. for 1 hour and cooled to 50° C. Sulfur (S) was added to oleylamine under a nitrogen atmosphere and stirred sufficiently at less than or equal to 50° C. to form a sulfur-containing precursor, sulfur-oleylamine.

### (Synthesis of ZnS Shell)

The synthesized CuInGaS₂ core was diluted in toluene and purified by precipitation with ethanol. The purified CuInGaS₂ core was dispersed in 5 ml of toluene and added into 15 ml of trioctylamine, followed by degassing at 120° C. 1 mmol of the sulfur-oleylamine maintained at a low temperature (50° C.) was added to the purified CuInGaS₂ core at 75° C. under a nitrogen atmosphere, forming a first composition for ZnS shell formation, and stirred for 10 minutes. 0.5 mmol of zinc-oleylamine and 0.5 mmol of trioctyl phosphine sulfide were added to the stirred first composition, forming a second composition for ZnS shell formation, and reacted at a temperature of 200° C. or higher for 20 minutes to form the ZnS shell.

### Comparative Example: Preparation of CuInGaS₂/ZnS Quantum Dot

### (Synthesis of CuInGaS₂ Core)

In a 300-ml flask, 200 ml of a solvent of oleylamine and octadecene (volume ratio=1:1) were added, followed by 1.5 mmol of CuBr3, 1.0 mmol of GaBr3, and 4.0 mmol of InBr₃, and stirred at 100° C. for 60 minutes. 5 mmol of a sulfur precursor (S-oleylamine) was added and reacted for 10 minutes, the temperature was raised to 300° C. over 10 minutes, and the reaction was terminated by cooling the temperature to room temperature, thus preparing a quantum dot core.

### (Synthesis of ZnS Shell)

The synthesized CuInGaS₂ core was diluted in toluene and purified by precipitation with ethanol. The purified CuInGaS₂ core was dispersed in 5 ml of toluene and added into 15 ml of trioctylamine, followed by degassing at 120° C. 0.5 mmol of zinc oleate and 0.5 mmol of trioctyl phosphine sulfide were added to the stirred first composition, forming a second composition for ZnS shell formation, and reacted at a temperature greater than or equal to 200° C. for 20 minutes to form the ZnS shell.

### Evaluation Example 1: Evaluation of Quantum Dot Characteristics

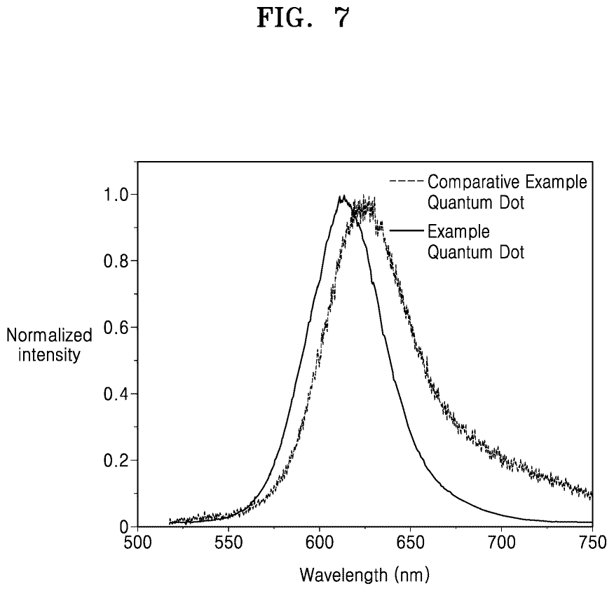

The maximum emission wavelength, full width at half maximum (FWHM), and quantum yield (QY) of each of the cores and quantum dots prepared for the Examples and Comparative Examples were evaluated, and the results are shown in Table 1, and the PL spectra of the quantum dots of the Examples and Comparative Examples are shown in FIG. 7.

2.8 ml of toluene and 0.2 ml of quantum dots were dispersed in a quartz cuvette, and the maximum emission wavelength and full width at half maximum were evaluated by analyzing the PL spectrum measured using a PL spectrometer and a UV-vis spectrometer. The quantum yield was evaluated using an absolute quantum efficiency measurement equipment.

TABLE 1

| | Maximum Emission | FWHM | QY |
|---|---|---|---|
| | Wavelength (nm) | (nm) | (%) |
| Core | 617 | 47 | — |
| Example Quantum Dot | 608 | 50 | 87 |
| Comparative Example | 625 | 57 | 81 |
| Quantum Dot | | | |

Referring to Table 1 and FIG. 7, it was confirmed that the quantum dot according to the Example may enhance color reproducibility by reducing the full width at half maximum of the PL spectrum by 10% or more compared to the quantum dot of the Comparative Example. It was confirmed that the quantum dot according to the example had superior quantum yield (QY) compared to the quantum dot according to the comparative example.

Therefore, since the quantum dot prepared according to the method of preparing the quantum dot according to an embodiment may have a narrow full width at half maximum and an excellent quantum yield (QY), it may be possible to prepare high-quality optical members and electronic apparatuses by incorporating the quantum dot.

### Evaluation Example 2: Evaluation of Quantum Dot Light-Resistance Characteristics

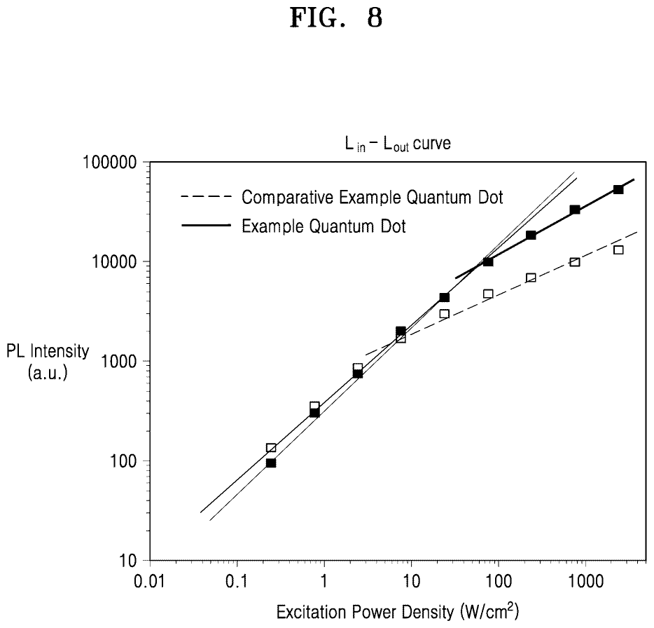

A PL intensity curve of each of the quantum dots prepared for the Examples and Comparative Examples were evaluated, and the results are shown in FIG. 8.

Referring to FIG. 8, it was confirmed that the quantum dot according to the Example have high light resistance characteristics by maintaining a high PL intensity even at high light levels compared to the quantum dot according to the Comparative Example.

### Evaluation Example 3: Evaluation of Quantum Dot Element Weight Ratio

For each of the quantum dots prepared in the Examples and Comparative Examples, the weight ratio of elements within the quantum dots was confirmed through ICP analysis, and is shown in Table 2.

TABLE 2

| | CIGS/ZnS(wt %) | | | | | |
|---|---|---|---|---|---|---|
| | Cu | Ga | In | S | Zn | SUM |
| Comparative | 0.08 | 0.06 | 0.10 | 0.32 | 0.44 | 1.00 |
| Example 1 | | | | | | |
| Example 1 | 0.09 | 0.08 | 0.06 | 0.44 | 0.33 | 1.00 |

Referring to Table 2, it may be confirmed that the weight ratio of the Example quantum dot is different from the weight ratio of the Comparative Example quantum dot.

The method of preparing a quantum dot according to embodiments includes reacting the core with a sulfur-containing precursor during the formation of the first shell to stabilize the core, so that the quantum dot minimizes changes in the atomic ratio of sulfur (S) even during a high-temperature reaction for shell formation, thereby minimizing increases in the full width at half maximum, and thus the quantum dot may achieve a narrow full width at half maximum and excellent quantum yield. A high-quality optical member and an electronic apparatus may be provided by using the quantum dot.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A method of preparing a quantum dot, comprising:
preparing a core comprising copper (Cu), a Group III element, and a Group VI element; and
preparing a first shell covering the core and comprising a Group II element and a Group VI element, wherein
the preparation of the first shell comprises:
preparing a first composition for forming the first shell by mixing the core with a Group VI element-containing precursor; and
preparing a second composition for preparing the first shell by adding a Group II element-containing precursor to the first composition for forming the first shell.

2. The method of claim 1, wherein in the preparing of the first composition for forming the first shell by mixing the core and the Group VI element-containing precursor, the core and the Group VI element-containing precursor are each mixed at a temperature of less than or equal to about 100° C.

3. The method of claim 1, further comprising, after the preparing of the second composition for forming the first shell:
heat-treating the second composition for forming the first shell.

4. The method of claim 1, wherein
the Group VI element comprised in the core comprises B¹,
the Group VI element comprised in the first shell comprises B²,
the Group VI element-containing precursor is a B²-containing precursor,
the B²-containing precursor comprises B² and an amine-based compound, and
B¹ and B² are each independently a Group VI element.

5. The method of claim 1, wherein the Group III element is aluminum (Al), gallium (Ga), indium (In), thallium (TI), nihonium (Nh), or a combination thereof.

6. The method of claim 1, wherein the Group VI element is oxygen (O), sulfur (S), selenium (Se), tellurium (Te), or a combination thereof.

7. The method of claim 1, wherein the Group II element is magnesium (Mg), calcium (Ca), zinc (Zn), cadmium (Cd), mercury (Hg), or a combination thereof.

8. The method of claim 1, wherein the core comprises copper (Cu), indium (In), gallium (Ga), and sulfur (S).

9. The method of claim 1, wherein the first shell comprises a Group II-VI semiconductor compound, a Group III-VI semiconductor compound, a Group III-V semiconductor compound, or a combination thereof.

10. The method of claim 9, wherein the Group II-VI semiconductor compound is CdS, CdSe, CdTe, ZnS, ZnSe, ZnTe, ZnO, ZnMg, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or a combination thereof.

11. The method of claim 9, wherein the Group III-VI semiconductor compound is GaS, GaSe, Ga₂Se₃, GaTe, InS, InSe, In₂S₃, In₂Se₃, InTe, InGaS₃, InGaSe₃, or a combination thereof.

12. The method of claim 9, wherein the Group III-V semiconductor compound is GaN, GaP, GaAs, GaSb, AlN, AIP, AIAs, AISb, InN, InP, InAs, InSb, GaNP, GaNAs, GaNSb, GaPAs, GaPSb, AlNP, AlNAs, AlNSb, AIPAs, AIPSb, InGaP, InNP, InAIP, InNAs, InNSb, InPAs, InPSb, GaAINP, GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb, or a combination thereof.

13. The method of claim 1, wherein the first shell comprises zinc (Zn) and sulfur (S).

14. A quantum dot, prepared by the method of claim 1, the quantum dot comprising, based on a total of 100 weight percent (wt %) of the quantum dot:
an amount of copper (Cu) in a range of about 5 wt % to about 15 wt %;
an amount of a Group III element in a range of about 10 wt % to about 20 wt %;
an amount of a Group VI element in a range of about 40 wt % to about 50 wt %; and
an amount of a Group II element in a range of about 25 wt % to about 35 wt %.

15. The quantum dot of claim 14, wherein the quantum dot emits light with a peak emission wavelength in a range of about 500 nm to about 650 nm.

16. The quantum dot of claim 14, wherein a quantum yield (QY) of the quantum dot is in a range of about 70% to about 98%.

17. The quantum dot of claim 14, wherein a full width at half maximum (FWHM) of an emission wavelength spectrum of the quantum dot is less than or equal to about 55 nm.

18. An optical member comprising:
the quantum dot of claim 14.

19. An electronic apparatus comprising:
the quantum dot of claim 14.

20. The electronic apparatus of claim 19, comprising:
a light source; and
a color conversion member disposed in a path of light emitted from the light source, wherein
the color conversion member comprises the quantum dot.
